(19) United States
(12) Patent Application Publication
(10) Pub. No.: US 2024/0365631 A1
(43) Pub. Date: Oct. 31, 2024

(54) DISPLAY PANEL AND DISPLAY DEVICE

(71) Applicant: Wuhan Tianma Microelectronics Co., Ltd., Wuhan (CN)

(72) Inventors: Yangzhao MA, Wuhan (CN); Qin YUE, Wuhan (CN); Wei HUANG, Wuhan (CN); Enxia WANG, Wuhan (CN); Shengxiong CHEN, Wuhan (CN); Qiang CHEN, Wuhan (CN); Huifang ZHOU, Wuhan (CN); Gaojun HUANG, Wuhan (CN); Zhongjie ZHANG, Wuhan (CN)

(73) Assignee: Wuhan Tianma Microelectronics Co., Ltd., Wuhan (CN)

(21) Appl. No.: 18/768,123

(22) Filed: Jul. 10, 2024

(30) Foreign Application Priority Data
Dec. 29, 2023 (CN) 202311872806.5

(51) Int. Cl. H10K 59/35; H10K 59/122; H10K 59/131

(52) U.S. Cl. CPC H10K 59/353; H10K 59/122; H10K 59/131; H10K 59/352

(57) ABSTRACT

Provided are a display panel and a display device. The display panel includes a first sub-pixel, a second sub-pixel and a third sub-pixel. Two first sub-pixels and two second sub-pixels form a first virtual quadrilateral. Four third sub-pixels form a second virtual quadrilateral, and the first sub-pixel or the second sub-pixel is located within the second virtual quadrilateral. Each of the first sub-pixel and the second sub-pixel includes a third side, the third side includes a first sub-segment and a second sub-segment. Each of the first sub-pixel and the second sub-pixel include a corresponding circumscribed virtual parallelogram, and a line connecting a center of the circumscribed virtual parallelogram corresponding to the first sub-pixel and a center of the circumscribed virtual parallelogram corresponding to the second sub-pixel at least intersects with a third side of one of the first sub-pixel or the second sub-pixel.

### CROSS-REFERENCE TO RELATED APPLICATION

This application claims priority to Chinese Patent Application No. 202311872806.5 filed with the China National Intellectual Property Administration (CNIPA) on Dec. 29, 2023, the disclosure of which is incorporated herein by reference in its entirety.

### TECHNICAL FIELD

The present disclosure relates to the field of display technologies, and in particular, to a display panel and a display device.

### BACKGROUND

Organic light-emitting diodes (OLEDs) are widely spotlighted due to their characteristics of self-luminous, low power consumption, high brightness, and fast response. Organic self-luminous display technologies have become the focus of research in the display field at present.

Multiple sub-pixels with different light emission colors, such as a red sub-pixel, a green sub-pixel, and a blue sub-pixel, are generally disposed in an organic self-luminous display panel.

At present, with the development of display technologies, users have increasingly high requirements for the display effect of display devices, and therefore, the current urgent technical problem to be solved is how to improve the display effect of the organic self-luminous display panel.

### SUMMARY

The present disclosure provides a display panel and a display device, so as to improve the display effect of the display panel.

The present disclosure provides a display panel. The display panel includes multiple sub-pixels, and the multiple sub-pixels include a first sub-pixel, a second sub-pixel and a third sub-pixel. Two first sub-pixels and two second sub-pixels form a first virtual quadrilateral, a center of gravity of the first sub-pixel is located at a first vertex of the first virtual quadrilateral, a center of gravity of the second sub-pixel is located at a second vertex of the first virtual quadrilateral, the first vertex and the second vertex in the first virtual quadrilateral are alternately disposed at intervals, and the third sub-pixel is located inside the first virtual quadrilateral. Four third sub-pixels form a second virtual quadrilateral, a center of gravity of the third sub-pixel is located at a vertex of the second virtual quadrilateral, and the first sub-pixel or the second sub-pixel is located inside the second virtual quadrilateral. Each of the first sub-pixel and the second sub-pixel includes a first side, a second side and a third side, where the first side and the second side are parallel to each other, the third side is connected to the first side and the second side on the same side of the first side and the second side, the third side includes a first sub-segment and a second sub-segment, the first sub-segment is connected to the first side, and the second sub-segment is connected to the second side. Each of the first sub-pixel and the second sub-pixel includes a corresponding circumscribed virtual parallelogram, where the circumscribed virtual parallelogram includes a first virtual side, a second virtual side and a third virtual side, the third virtual side is connected to the first virtual side and the second virtual side on the same side of the first virtual side and the second virtual side, the first virtual side partially coincides with the first side, the second virtual side partially coincides with the second side, and at least one point of the third side is located on the third virtual side; and in a thickness direction of the display panel, the first sub-pixel is located within the circumscribed virtual parallelogram corresponding to the first sub-pixel, and the second sub-pixel is located within the circumscribed virtual parallelogram corresponding to the second sub-pixel. 0.05*La≤Xa≤0.3*La, where Xa is a first distance denoting a vertical distance between an intersection point of the first side and the first sub-segment and the third virtual side, and La denotes a length of the first virtual side. 0.05*Lb≤Xb≤0.3*Lb, wherein Xb is a second distance denoting a vertical distance between an intersection point of the second side and the second sub-segment and the third virtual side is, and Lb denotes a length of the second virtual side. In a direction in which the first sub-pixel and the second sub-pixel are arranged alternately, a line connecting a center of the circumscribed virtual parallelogram corresponding to the first sub-pixel and a center of the circumscribed virtual parallelogram corresponding to the second sub-pixel at least intersects with a third side of one of the first sub-pixel or the second sub-pixel.

The present disclosure further provides a display device. The display device includes the display panel described above.

According to another aspect of the present disclosure, a display panel is provided. The display panel includes multiple sub-pixels. The multiple sub-pixels include a first sub-pixel, a second sub-pixel and a third sub-pixel. Two first sub-pixels and two second sub-pixels form a first virtual quadrilateral, a center of gravity of the first sub-pixel is located at a first vertex of the first virtual quadrilateral, a center of gravity of the second sub-pixel is located at a second vertex of the first virtual quadrilateral, the first vertex and the second vertex in the first virtual quadrilateral are alternately disposed at intervals, and the third sub-pixel is located inside the first virtual quadrilateral. Four third sub-pixels form a second virtual quadrilateral, a center of gravity of the third sub-pixel is located at a vertex of the second virtual quadrilateral, and the first sub-pixel or the second sub-pixel is located inside the second virtual quadrilateral. Each of the first sub-pixel and the second sub-pixel includes a first side, a second side and a third side, where the first side and the second side are parallel to each other, the third side is connected to the first side and the second side on the same side of the first side and the second side, the third side includes a first sub-segment and a second sub-segment, the first sub-segment is connected to the first side, and the second sub-segment is connected to the second side, a maximum included angle between the first side and the first sub-segment and towards the second side is α_{b1}, and a maximum included angle between the second side and the second sub-segment and towards the first side is α_{b2}, and 90°<α_{b1}<180°, and 90°<α_{b2}<180°.

It should be understood that the contents described in this section are not intended to identify key or critical features of the embodiments of the present disclosure, nor intended to limit the scope of the present disclosure. Other features of the present disclosure will be readily understood from the following description.

### BRIEF DESCRIPTION OF DRAWINGS

In order to describe technical schemes in embodiments of the present disclosure more clearly, the drawings used for describing the embodiments will be briefly introduced below. Apparently, the drawings in the following description are merely some embodiments of the present disclosure, and for those of ordinary skill in the art, other drawings may also be obtained based on these drawings without any creative efforts.

FIG. 1A is a schematic diagram of a display panel according to an embodiment of the present disclosure;

FIG. 1B is a schematic diagram of a display panel in the related art;

FIG. 1C is a schematic comparison diagram between a display panel according to an embodiment of the present disclosure and a display panel in FIG. 1B;

FIG. 1D is a schematic comparison diagram between another display panel according to an embodiment of the present disclosure and another display panel in the related art;

FIG. 2 is a schematic diagram of a sub-pixel according to an embodiment of the present disclosure;

FIG. 3 is a schematic diagram of another sub-pixel according to an embodiment of the present disclosure;

FIG. 4 is a schematic diagram of a pixel defining layer according to an embodiment of the present disclosure;

FIG. 5 is a sectional view taken along A1-A2 in FIG. 4;

FIG. 6 is a schematic diagram of another display panel according to an embodiment of the present disclosure;

FIG. 7 is a schematic diagram of AA1 in FIG. 1A;

FIG. 8 is a schematic diagram of another sub-pixel according to an embodiment of the present disclosure;

FIG. 9 is a schematic diagram of another sub-pixel according to an embodiment of the present disclosure;

FIG. 10 is a schematic diagram of another sub-pixel according to an embodiment of the present disclosure;

FIG. 11 is a schematic diagram of another sub-pixel according to an embodiment of the present disclosure;

FIG. 12 is a schematic diagram of another sub-pixel according to an embodiment of the present disclosure;

FIG. 13 is a schematic diagram of another sub-pixel according to an embodiment of the present disclosure;

FIG. 14 is a schematic diagram of another sub-pixel according to an embodiment of the present disclosure;

FIG. 15 is a schematic diagram of a first sub-pixel and a second sub-pixel adjacent to each other in a direction S2 according to an embodiment of the present disclosure;

FIG. 16 is another schematic diagram of a first sub-pixel and a second sub-pixel adjacent to each other in a direction S2 according to an embodiment of the present disclosure;

FIG. 17 is a schematic diagram of another sub-pixel according to an embodiment of the present disclosure;

FIG. 18 is a schematic diagram of another sub-pixel according to an embodiment of the present disclosure;

FIG. 19 is a schematic diagram of another sub-pixel according to an embodiment of the present disclosure;

FIG. 20 is a schematic diagram of another sub-pixel according to an embodiment of the present disclosure;

FIG. 21 is a schematic diagram of another sub-pixel according to an embodiment of the present disclosure;

FIG. 22 is a schematic diagram of another display panel according to an embodiment of the present disclosure;

FIG. 23 is another schematic diagram of a first sub-pixel and a second sub-pixel adjacent to each other in a direction S2 according to an embodiment of the present disclosure;

FIG. 24 is a schematic diagram of another display panel according to an embodiment of the present disclosure;

FIG. 25 is a schematic diagram of another display panel according to an embodiment of the present disclosure;

FIG. 26 is a schematic diagram of a first sub-group and a second sub-group adjacent to each other in FIG. 25;

FIG. 27 is a schematic diagram of another display panel according to an embodiment of the present disclosure;

FIG. 28 is a schematic diagram of another display panel according to an embodiment of the present disclosure;

FIG. 29 is a schematic diagram of another display panel according to an embodiment of the present disclosure;

FIG. 30 is a schematic diagram of another display panel according to an embodiment of the present disclosure;

FIG. 31 is a schematic diagram of another sub-pixel according to an embodiment of the present disclosure;

FIG. 32 is a schematic diagram of another sub-pixel according to an embodiment of the present disclosure;

FIG. 33 is a schematic diagram of another sub-pixel according to an embodiment of the present disclosure;

FIG. 34 is a schematic diagram of another sub-pixel according to an embodiment of the present disclosure;

FIG. 35 is a schematic diagram of another display panel according to an embodiment of the present disclosure;

FIG. 36 is a schematic diagram of another display panel according to an embodiment of the present disclosure;

FIG. 37 is a schematic diagram of another display panel according to an embodiment of the present disclosure;

FIG. 38 is a schematic diagram of another display panel according to an embodiment of the present disclosure;

FIG. 39 is a schematic diagram of another display panel according to an embodiment of the present disclosure;

FIG. 40 is a schematic diagram of another display panel according to an embodiment of the present disclosure;

FIG. 41 is a schematic diagram of another display panel according to an embodiment of the present disclosure;

FIG. 42 is a schematic diagram of a first electrode and a pixel opening in FIG. 41;

FIG. 43 is a schematic diagram of another sub-pixel according to an embodiment of the present disclosure;

FIG. 44 is a schematic diagram of another display panel according to an embodiment of the present disclosure;

FIG. 45 is a schematic diagram of another sub-pixel according to an embodiment of the present disclosure;

FIG. 46 is a schematic diagram of another sub-pixel according to an embodiment of the present disclosure;

FIG. 47 is a schematic diagram of another sub-pixel according to an embodiment of the present disclosure;

FIG. 48 is a schematic diagram of another display panel according to an embodiment of the present disclosure;

FIG. 49 is a schematic diagram of another display panel according to an embodiment of the present disclosure;

FIG. 50 is a schematic diagram of a touch electrode layer in FIG. 49;

FIG. 51 is a schematic diagram of another display panel according to an embodiment of the present disclosure;

FIG. 52 is a partial enlarged schematic diagram of a region Qa in FIG. 51; and

FIG. 53 is a schematic diagram of a display device according to an embodiment of the present disclosure.

### DETAILED DESCRIPTION

In order that those skilled in the art will better understand the schemes of the present disclosure, the technical schemes of embodiments of the present disclosure will be clearly and completely described below in conjunction with the accompanying drawings of the embodiments of the present disclosure. Apparently, the described embodiments are merely some embodiments of the present disclosure, rather than all of the embodiments. All other embodiments obtained by those of ordinary skill in the art based on the embodiments of the present disclosure without needing creative efforts shall all fall in the scope of protection of the present disclosure.

It should be noted that the terms “first”, “second” and the like in the Description and claims of the present disclosure, and in the foregoing drawings, are used for distinguishing between similar objects and not necessarily for describing a particular order or sequential order. It should be understood that the data so used are interchangeable as appropriate so that the embodiments of the present disclosure described herein can be implemented in an order other than those illustrated or described herein. Moreover, the terms “include” and “have” as well as any variations thereof, are intended to cover a non-exclusive inclusion, for example, a process, a method, a system, a product, or an apparatus that includes a series of steps or units is not necessarily limited to those steps or units expressly listed, but may include other steps or units not expressly listed or inherent to such process, method, product, or apparatus.

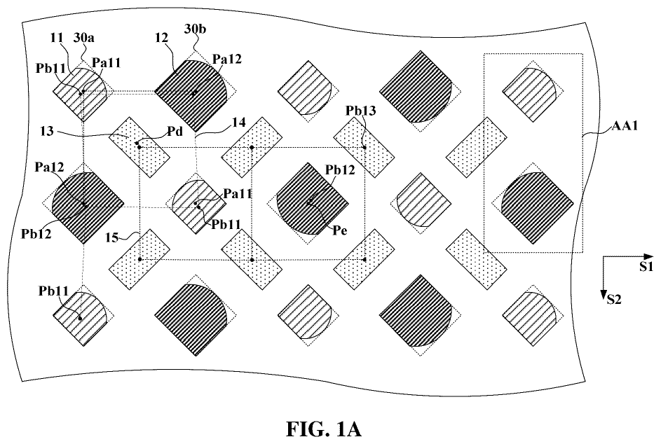

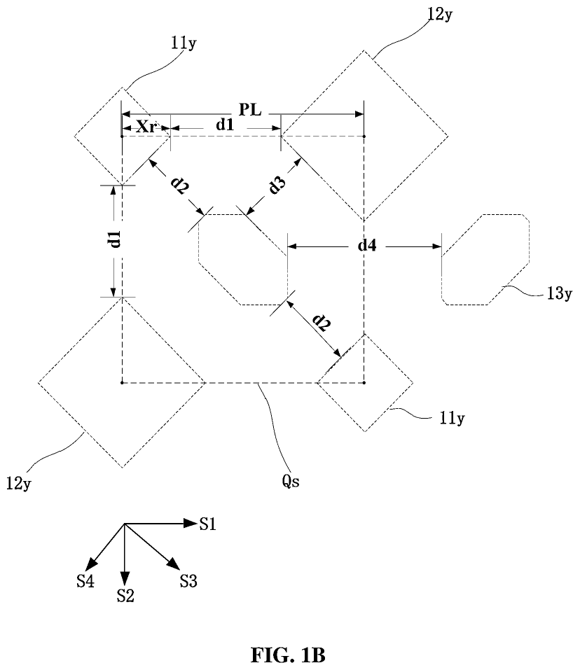

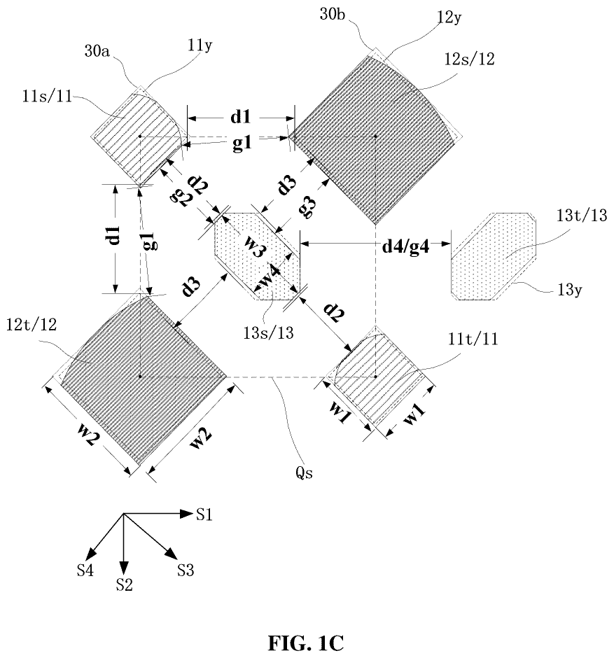

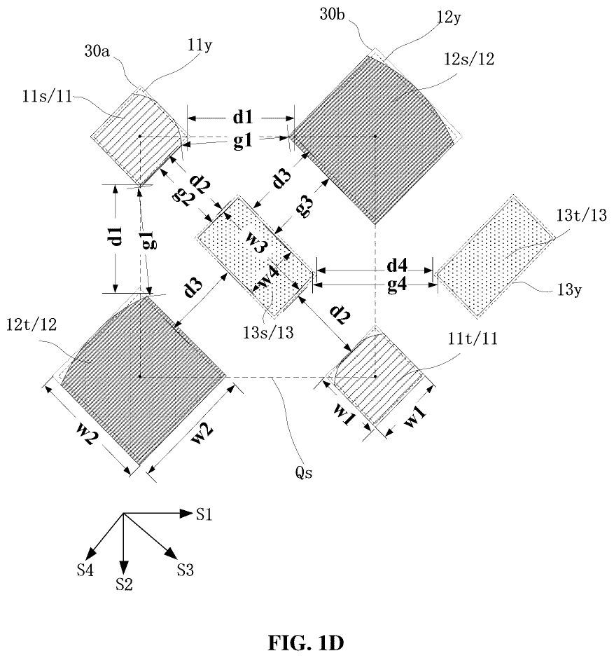

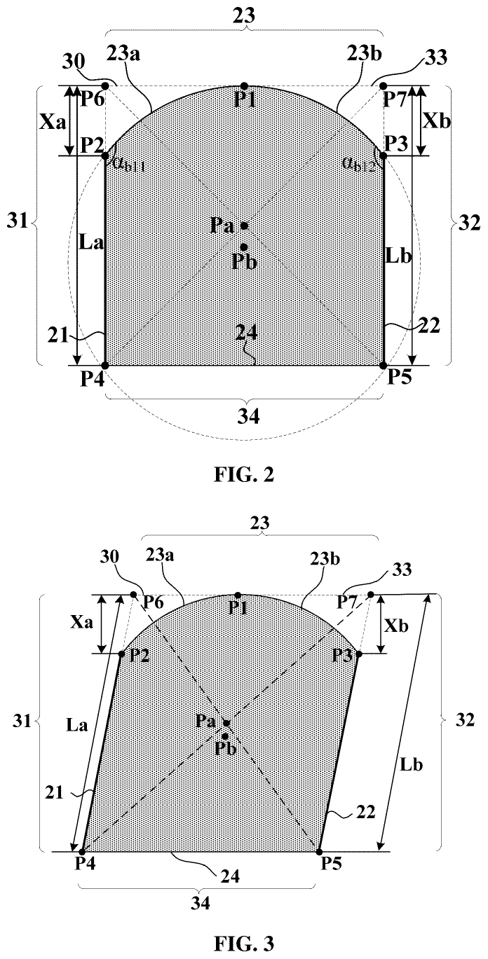

FIG. 1A is a schematic diagram of a display panel according to an embodiment of the present disclosure. FIG. 2 is a schematic diagram of a sub-pixel according to an embodiment of the present disclosure. FIG. 3 is a schematic diagram of another sub-pixel according to an embodiment of the present disclosure. As shown in FIGS. 1A, 2 and 3, the display panel includes multiple sub-pixels, and the multiple sub-pixels include a first sub-pixel 11, a second sub-pixel 12 and a third sub-pixel 13. Two first sub-pixels 11 and two second sub-pixels 12 form a first virtual quadrilateral 14, a center of gravity of the first sub-pixel 11 is located at a first vertex of the first virtual quadrilateral 14, a center of gravity of the second sub-pixel 12 is located at a second vertex of the first virtual quadrilateral 14, the first vertex and the second vertex in the first virtual quadrilateral 14 are alternately disposed at intervals, and the third sub-pixel 13 is located inside the first virtual quadrilateral 14. Four third sub-pixels 13 form a second virtual quadrilateral 15, a center of gravity of the third sub-pixel 13 is located at a vertex of the second virtual quadrilateral 15, and the first sub-pixel 11 or the second sub-pixel 12 is located inside the second virtual quadrilateral 15. Each of the first sub-pixel 11 and the second sub-pixel 12 includes a first side 21 and a second side 22 and a third side 23, the first side 21 and the second side 22 are parallel to each other, the third side 23 is connected to the first side 21 and the second side 22 on the same side of the first side 21 and the second side 22, the third side 23 includes a first sub-segment 23a and a second sub-segment 23b, the first sub-segment 23a is connected to the first side 21, and the second sub-segment 23b is connected to the second side 22. Each of the first sub-pixel 11 and the second sub-pixel 12 includes a corresponding circumscribed virtual parallelogram 30, the circumscribed virtual parallelogram 30 includes a first virtual side 31, a second virtual side 32 and a third virtual side 33, the third virtual side 33 is connected to the first virtual side 31 and the second virtual side 32 on the same side of the first virtual side 31 and the second virtual side 32, the first virtual side 31 partially coincides with the first side 21, the second virtual side 32 partially coincides with the second side 22, and at least one point P1 of the third side 23 is located on the third virtual side 33; and in a thickness direction of the display panel, the first sub-pixel 11 is located within the circumscribed virtual parallelogram 30 corresponding to the first sub-pixel 11, and the second sub-pixel 12 is located within the circumscribed virtual parallelogram 30 corresponding to the second sub-pixel 12. Where, 0.05*La≤Xa≤0.3*La, Xa is a first distance denoting a vertical distance between an intersection point P2 of the first side 21 and the first sub-segment 23a and the third virtual side 33, and La denotes a length of the first virtual side 31. Where, 0.05*Lb≤Xb≤0.3*Lb, Xb is a second distance denoting a vertical distance between an intersection point P3 of the second side 22 and the second sub-segment 23b and the third virtual side 33, and Lb denotes a length of the second virtual side 32. In a direction in which the first sub-pixel 11 and the second sub-pixel 12 are arranged alternately, a line connecting a center of the circumscribed virtual parallelogram 30 corresponding to the first sub-pixel 11 and a center of the circumscribed virtual parallelogram 30 corresponding to the second sub-pixel 12 at least intersect with the third side 23 of one of the first sub-pixel 11 or the second sub-pixel 12.

It should be noted that the circumscribed virtual parallelogram 30 corresponding to the sub-pixel in FIG. 2 is rectangular, and the circumscribed virtual parallelogram 30 corresponding to the sub-pixel in FIG. 3 is non-rectangular. A shape of the first sub-pixel and a shape of the second sub-pixel may be independently selected as a shape of the sub-pixel shown in FIG. 2 or a shape of the sub-pixel shown in FIG. 3. Exemplarily, the first sub-pixel and the second sub-pixel in the display panel may select the shape of the sub-pixel shown in FIG. 2, or the first sub-pixel in the display panel may select the shape of the sub-pixel shown in FIG. 2, and the second sub-pixel may select the shape of the sub-pixel shown in FIG. 3.

In the embodiment of the present application, the display panel includes multiple sub-pixels. The multiple sub-pixels may be classified into three types, i.e., multiple first sub-pixels 11, multiple second sub-pixels 12 and multiple third sub-pixels 13. Colors configured for the first sub-pixel 11, the second sub-pixel 12 and the third sub-pixel 13 may be different. Exemplarily, the first sub-pixel 11 may be a red sub-pixel, the second sub-pixel 12 may be a blue sub-pixel, and the third sub-pixel 13 may be a green sub-pixel. However, this is not limited thereto, the color of the first sub-pixel, the color of the second sub-pixel, and the color of the third sub-pixel may be properly configured by those skilled in the art according to the product requirement, the color of the first sub-pixel, the color of the second sub-pixel, and the color of the third sub-pixel may be the same, may be not exactly the same, may be completely different, and the like.

The multiple first sub-pixels 11 and the multiple second sub-pixels 12 of the display panel may be arranged in the following manner. Two first sub-pixels 11 and two second sub-pixels 12 form one first virtual quadrilateral 14, centers of gravity Pb11 of the first sub-pixels 11 are located at first vertexes of the first virtual quadrilateral 14, centers of gravity Pb12 of the second sub-pixels 12 are located at second vertexes of the first virtual quadrilateral 14, and the first vertexes and the second vertexes of the first virtual quadrilateral 14 are alternately disposed. That is, the two first sub-pixels 11 and the two second sub-pixels 12 are arranged in a 2*2 manner. After the four sub-pixels are arranged, lines connecting centers of gravity of the four sub-pixels may form one quadrilateral, and the quadrilateral is defined as the first virtual quadrilateral 14. The two first sub-pixels 11 are disposed opposite to each other along one diagonal line of the first virtual quadrilateral 14 and are located at two opposite vertex positions of the first virtual quadrilateral 14, and the two second sub-pixels 12 are disposed opposite to each other along another diagonal line of the first virtual quadrilateral 14 and are located at two other opposite vertex positions of the first virtual quadrilateral 14. The two first sub-pixels 11 and the two second sub-pixels 12 form the first virtual quadrilateral 14, and one third sub-pixel 13 is disposed inside the first virtual quadrilateral 14.

The multiple third sub-pixels 13 of the display panel may be arranged in the following manner. One third sub-pixel 13 is disposed inside the first virtual quadrilateral 14, four third sub-pixels 13 arranged in the 2*2 manner form the second virtual quadrilateral 15, and the centers of gravity Pb13 of the third sub-pixels 13 are located at vertexes of the second virtual quadrilateral 15. That is, after the four third sub-pixels 13 are arranged in a 2*2 manner, lines connecting centers of gravity of the four third sub-pixels 13 may form one quadrilateral, and the quadrilateral is defined as the second virtual quadrilateral 15. Based on the pixel arrangement manners of the first sub-pixels 11, the second sub-pixels 12, and the third sub-pixels 13, one first sub-pixel 11 is disposed inside each of some second virtual quadrilaterals 15, and one second sub-pixel 12 is disposed inside each of some second virtual quadrilaterals 15.

It should be noted that, the center of the sub-pixel described above may be defined as a center point of the geometric shape of the sub-pixel, that is, a geometric center, and the center of gravity of the sub-pixel may be defined as a mass distribution center point of the geometric shape of the sub-pixel, that is, a center of mass. If the geometric shape of the sub-pixel is a regular geometric shape, then the geometric center of the sub-pixel coincides with the center of gravity of the sub-pixel, for example, a shape of the sub-pixel is a parallelogram, and an intersection point of two diagonal lines of the parallelogram is the geometric center of the sub-pixel and the center of gravity of the sub-pixel. If the geometric shape of the sub-pixel is an asymmetric irregular geometric shape, then the gravity center of the sub-pixel may be determined by using the related technology, however, the geometric center of the sub-pixel is relatively difficult to be determined, in this case, a relative position relationship between the geometric center of the sub-pixel and the gravity center of the sub-pixel is relatively difficult to be determined.

It should be noted that a regular shape (a regular geometric shape) in the present disclosure satisfies at least one of the following conditions: 1) a center-symmetric shape; or 2) an axisymmetric pattern with more than two symmetric axes. For example, an ellipse, a parallelogram (non-rectangular and non-rhombic), a circle, a rounded rectangle, a regular polygon, a rectangle, and a rhombus are all regular shapes. For the center-symmetric shape, a center-symmetric point of the center symmetric shape is a center (center of gravity); and for the axisymmetric pattern with more than two symmetric axes, an intersection point of two symmetric axes of the axisymmetric pattern with more than two symmetric axes is a center (center of gravity). A shape other than a corresponding regular shape is an irregular shape.

The third sub-pixel 13 is used as an example, the shape of the third sub-pixel 13 in FIG. 1A is rectangular, the geometric center and the center of gravity Pb12 of the third sub-pixel 13 overlap, which is specifically an intersection point (that is, a center-symmetric point) of two diagonal lines of the rectangle. However, in practice, the shape of the third sub-pixel is not limited to a rectangle, and the shape of the third sub-pixel may be a regular geometric shape of another shape, such as a circle, a parallelogram, a rhombus, or a regular polygon. The shape of the third sub-pixel may also be an irregular shape.

As shown in FIG. 1A, the direction in which the first sub-pixel 11 and the second sub-pixel 12 are arranged alternately includes a direction S1 and a direction S2, and the direction S1 intersects with the direction S2. In the direction S1, the first sub-pixel 11 and the second sub-pixel 12 are arranged alternately to form a row of sub-pixels. In the direction S2, the first sub-pixel 11 and the second sub-pixel 12 are arranged alternately to form a column of sub-pixels. Based on this, a plane formed by the direction S1 and the direction S2 is parallel to a display surface of the display panel, and the thickness direction of the display panel is perpendicular to the display surface of the display panel, that is, the thickness direction of the display panel is perpendicular to the direction S1 and the direction S2.

A shape of any one of the first sub-pixel 11 or the second sub-pixel 12 may refer to FIGS. 2 and 3. As shown in FIGS. 2 and 3, a shape of the sub-pixel is a geometric shape surrounded by the first side 21, the second side 22, the third side 23, and the fourth side 24. The first side 21 and the second side 22 are disposed in parallel, the third side 23 is located on the same side of the first side 21 and the second side 22, and the third side 23 is connected to the first side 21 and the second side 22 on the same side of the first side 21 and the second side 22. Each of the first side 21 and the second side 22 is a straight line segment. In an embodiment, the first side 21 is a straight line segment from a point P4 to a point P2, and the second side 22 is a straight line segment from a point P5 to a point P3. The third side 23 is a side formed by connecting multiple sub-segments, and the multiple sub-segments of the third side 23 include a first sub-segment 23a and a second sub-segment 23b. One end of the first sub-segment 23a is connected to the first side 21, and one end of the second sub-segment 23b is connected to the second side 22, that is, the third side 23 is formed by connecting the first sub-segment 23a, the second sub-segment 23b, and Ka sub-segments located between the first sub-segment 23a and the second sub-segment 23b. A value of Ka is an integer greater than or equal to 0, and one sub-segment is essentially one line segment. Any one of the first sub-segment 23a, the second sub-segment 23b, or Ka sub-segments located between the first sub-segment 23a and the second sub-segment 23b may be a straight line segment, or may be an arc segment. In FIGS. 2 and 3, only an example in which each of the first sub-segment 23a and the second sub-segment 23b is the arc segment and Ka=0 is used for description. The fourth side 24 and the third side 23 are disposed opposite to each other. The fourth side 24 may be a straight line segment, may be an arc segment, or may be a side formed by connecting the multiple sub-segments. In FIGS. 2 and 3, in an embodiment, the fourth side 24 is a straight line segment. A length relationship between the first side 21 and the second side 22 is not specifically limited. In FIGS. 2 and 3, in an embodiment, a length of the optional first side 21 is equal to a length of the second side 22.

Exemplarily, the third side 23 may include only the first sub-segment 23a and the second sub-segment 23b. In this case, one end of the first sub-segment 23a is connected to the first side 21 and another end of the first sub-segment 23a is connected to the second sub-segment 23b, and one end of the second sub-segment 23b is connected to the second side 22 and another end of the second sub-segment 23b is connected to the first sub-segment 23a. As shown in FIGS. 2 and 3, the first sub-segment 23a is an arc segment from a point P2 to a point P1, and the second sub-segment 23b is an arc segment from a point P3 to a point P1. However, this is not limited thereto. In other embodiments, the third side may include three or more sub-segments, and the three or more sub-segments are respectively the first sub-segment, the second sub-segment, and one or more sub-segments located between the first sub-segment and the second sub-segment and connected to the first sub-segment and the second sub-segment, which is not specifically limited.

As shown in FIGS. 2 and 3, the sub-pixel includes a corresponding circumscribed virtual parallelogram 30, and the circumscribed virtual parallelogram 30 is a circumscribed parallelogram corresponding to the sub-pixel. The circumscribed virtual parallelogram 30 includes a first virtual side 31, a second virtual side 32, a third virtual side 33, and a fourth virtual side 34. Each of the first virtual side 31, the second virtual side 32, the third virtual side 33, and the fourth virtual side 34 is a straight line segment. The first virtual side 31 and the second virtual side 32 are disposed in parallel and are equal in length, the third virtual side 33 and the fourth virtual side 34 are disposed in parallel and are equal in length, the third virtual side 33 is located on the same side of the first virtual side 31 and the second virtual side 32, and the third virtual side 33 is connected to the first virtual side 31 and the second virtual side 32 on the same side of the first virtual side 31 and the second virtual side 32. The fourth virtual side 34 is located on the side opposite to the third virtual side 33, and the fourth virtual side 34 is connected to the first virtual side 31 and the second virtual side 32 on the same side of the first virtual side 31 and the second virtual side 32. As shown in FIGS. 2 and 3, in the circumscribed virtual parallelogram 30, the first virtual side 31 is a straight line segment from the point P4 to a point P6, the second virtual side 32 is a straight line segment from the point P5 to a point P7, the third virtual side 33 is a straight line segment from the point P6 to the point P7, and the fourth virtual side 34 is a straight line segment from the point P4 to the point P5.

For the sub-pixel and the circumscribed virtual parallelogram corresponding to the sub-pixel, the first virtual side 31 partially coincides with a corresponding first side 21, and in an embodiment, at least one point of the first side 21 is located on the first virtual side 31. The second virtual side 32 partially coincides with a corresponding second side 22, and in an embodiment, at least one point of the second side 22 is located on the second virtual side 32. In an embodiment, at least one point of the third side 23 is located on a corresponding third virtual side 33.

In an embodiment, in the thickness direction of the display panel, the first sub-pixel 11 is located in the circumscribed virtual parallelogram 30 corresponding to the first sub-pixel 11. It should be understood that points on each side of the first sub-pixel 11 are located inside or on a corresponding side of the circumscribed virtual parallelogram 30, and are not located outside the circumscribed virtual parallelogram 30. In the thickness direction of the display panel, the second sub-pixel 12 is located in the circumscribed virtual parallelogram 30 corresponding to the second sub-pixel 12. It should be understood that points on each side of the second sub-pixel 12 are located inside or on a corresponding side of the circumscribed virtual parallelogram 30, and are not located outside the circumscribed virtual parallelogram 30. As shown in FIGS. 2 and 3, points of the first side 21 may be all located on the first virtual side 31, that is, an overlapping portion exists between the first virtual side 31 and the first side 21, and the overlapping portion is a straight line segment from the point P4 to the point P2. Points of the second side 22 may be all located on the second virtual side 32, that is, an overlapping portion exists between the second virtual side 32 and the second side 22, and the overlapping portion is a straight line segment from the point P5 to the point P3. A point (P1) in the third side 23 may be located on the third virtual side 33, that is, the third virtual side 33 is tangent to the third side 23. If the shape of the sub-pixel changes, a shape of the circumscribed virtual parallelogram corresponding to the sub-pixel may change accordingly.

The display panel may include pixel openings corresponding to the multiple sub-pixels. FIG. 4 is a schematic diagram of a pixel defining layer according to an embodiment of the present disclosure. As shown in FIG. 4, the display panel includes a pixel defining layer 110, the pixel defining layer 110 has pixel openings corresponding to the multiple sub-pixels, an inner side wall of the pixel opening has an inclined structure, and the pixel opening may limit a light-emitting region of a corresponding sub-pixel. The pixel defining layer 110 includes a first pixel opening 111 correspondingly defining the first sub-pixel 11, a second pixel opening 112 correspondingly defining the second sub-pixel 12, and a third pixel opening 113 correspondingly defining the third sub-pixel 13. The first pixel opening 111 includes an upper opening 111a, a lower opening 111b, and an inner side wall 111c connected between the upper opening 111a and the lower opening 111b. The second pixel opening 112 includes an upper opening 112a, a lower opening 112b, and an inner side wall 112c connected between the upper opening 112a and the lower opening 112b. The third pixel opening 113 includes an upper opening 113a, a lower opening 113b, and an inner side wall 113c connected between the upper opening 113a and the lower opening 113b.

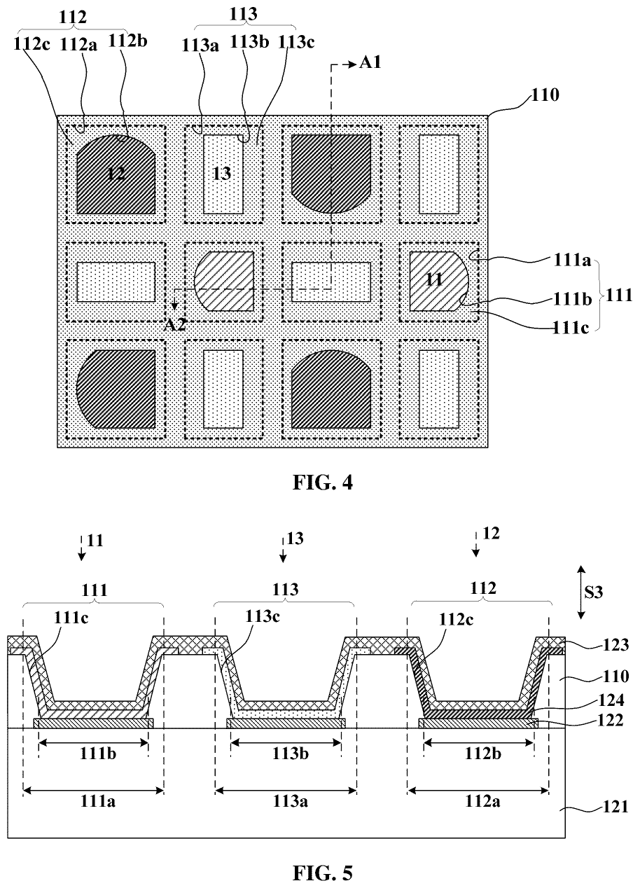

It should be understood that a region of the sub-pixel surrounded by solid lines shown in FIGS. 2 and 3 is substantially the light-emitting region of the sub-pixel. In the display panel, the pixel opening corresponding to the sub-pixel includes an upper opening and a lower opening, an inner side wall of the pixel opening has an inclined structure, and a cross-sectional shape of the sub-pixel opening in the thickness direction of the display panel is an inverted trapezoid shape, that is, an upper opening dimension is relatively large, and a lower opening dimension is relatively small. FIG. 5 is a sectional view taken along A1-A2 in FIG. 4. With reference to FIGS. 5 and 4, a cross-sectional shape of the pixel opening along the thickness direction S3 of the display panel is an inverted trapezoid. Based on this, an area of the upper opening 111a of the first pixel opening 111 is greater than an area of the lower opening 111b, an area of the upper opening 112a of the second pixel opening 112 is greater than an area of the lower opening 112b, and an area of the upper opening 113a of the third pixel opening 113 is greater than an area of the lower opening 113b.

The display panel includes an anode 122 located on an substrate 121, a cathode 123, and a light-emitting layer 124 between the anode 122 and the cathode 123. The light-emitting layer 124 is in contact with the anode 122 through the pixel opening of the pixel defining layer 110, and a region of the light-emitting layer 124 that contacts the anode 122 is the light-emitting region, that is, the sub-pixel. It should be understood that, when the light-emitting layer 124 is evaporated, the light-emitting layer 124 is not only bonded to the anode 122, but also evaporated to the pixel defining layer 110. In an embodiment, the light-emitting layer 124 is evaporated to an inner side wall of the pixel opening, and even evaporated to an upper opening of the pixel opening. That is to say, the lower opening region of the pixel opening is the light-emitting region of the sub-pixel. That is, the lower opening 111b of the first pixel opening 111 defines a shape of the first sub-pixel 11, that is, a light-emitting region, so that the first side 21, the second side 22, the third side 23, and the fourth side 24 of the first sub-pixel 11 correspond to respective sides of the lower opening 111b of the first pixel opening 111. The lower opening 112b of the second pixel opening 112 defines a shape of the second sub-pixel 12, that is, a light-emitting region, so that the first side 21, the second side 22, the third side 23, and the fourth side 24 of the second sub-pixel 12 correspond to respective sides of the lower opening 112b of the second pixel opening 112. The lower opening 113b of the third pixel opening 113 defines a shape of the third sub-pixel 13, that is, a light-emitting region, so that sides of the third sub-pixel 13 correspond to respective sides of the lower opening 113b of the third pixel opening 113.

Apparently, the circumscribed virtual parallelogram 30 corresponding to the first sub-pixel 11 may be defined as an external quadrilateral of the lower opening 111b of the first pixel opening 111 corresponding to the first sub-pixel 11, and the circumscribed virtual parallelogram 30 corresponding to the second sub-pixel 12 is defined as an external quadrilateral of the lower opening 112b of the second pixel opening 112 corresponding to the second sub-pixel 12.

Hereinafter, a region represented by the shape of the sub-pixel specifically refers to a region surrounded by a lower opening edge of the pixel opening corresponding to the sub-pixel, that is, the region of the light-emitting layer that contacts the anode, that is, the light-emitting region of the sub-pixel, and a circumscribed virtual parallelogram of a corresponding sub-pixel is a circumscribed quadrilateral of the lower opening edge of the pixel opening, which is not described one by one.

Referring to FIGS. 2 and 3, for the sub-pixel and the circumscribed virtual parallelogram corresponding to the sub-pixel, a vertical distance between an intersection point P2 of the first side 21 and the first sub-segment 23a and the third virtual side 33 is a first distance Xa, a length of the first virtual side 31 is La, and La in FIGS. 2 and 3 is a straight line segment length from the point P4 to the point P6. Xa and La satisfy the following relationship: 0.05*La≤Xa≤0.3*La. A vertical distance between the intersection point P3 of the second side 22 and the second sub-segment 23b and the third virtual side 33 is a second distance Xb, and a length of the second virtual side 32 is Lb. Xb and Lb satisfy the following relationship: 0.05*Lb≤Xb≤0.3*Lb.

It should be understood that, the sub-pixels shown in FIGS. 2 and 3 and the circumscribed virtual parallelogram corresponding to the sub-pixels are merely an example, and represent a relative relationship between the sub-pixels and the circumscribed virtual parallelogram corresponding to the sub-pixels. In the display panel, parameters such as a shape and an area of the first sub-pixel 11 and the second sub-pixel 12 may be different, and based on this, the circumscribed virtual parallelogram corresponding to the first sub-pixel 11 is different from the circumscribed virtual parallelogram corresponding to the second sub-pixel 12. For example, as shown in FIG. 1A, the circumscribed virtual parallelogram 30a corresponding to the first sub-pixel 11 differs from the circumscribed virtual parallelogram 30b corresponding to the second sub-pixel 12 in at least one parameter, such as an area, a side length, an interior angle, and the like.

As shown in FIGS. 2 and 3, the circumscribed virtual parallelogram 30 corresponding to the sub-pixel is a centrally symmetric regular geometric shape. Therefore, a geometric center of the circumscribed virtual parallelogram 30 coincides with a center of gravity of the circumscribed virtual parallelogram 30, and the geometric center of the circumscribed virtual parallelogram 30 is an intersection point Pa of two diagonal lines. The center of gravity of the sub-pixel is Pb. Depending on the change of the geometric shape of the sub-pixel, the center Pa of the circumscribed virtual parallelogram 30 may overlap with or may not overlap with the center of gravity Pb of the sub-pixel inside thereof. FIGS. 2 and 3 both show a condition that the center Pa of the circumscribed virtual parallelogram 30 does not overlap with the center of gravity Pb of the sub-pixel inside thereof.

With reference to FIGS. 1A, 2, and 3, a center of the circumscribed virtual parallelogram 30a corresponding to the first sub-pixel 11 is Pa11, and a center of the circumscribed virtual parallelogram 30b corresponding to the second sub-pixel 12 is Pa12.

In the direction S1, the first sub-pixel 11 and the second sub-pixel 12 adjacent to each other satisfy at least one of the following conditions: (1) a line Pa11-Pa12 connecting the center of the circumscribed virtual parallelogram 30a corresponding to the first sub-pixel 11 and the center of the circumscribed virtual parallelogram 30b corresponding to the second sub-pixel 12 intersects with the third side of the first sub-pixel 11; or (2) a line Pa11-Pa12 connecting the center of the circumscribed virtual parallelogram 30a corresponding to the first sub-pixel 11 and a center of the circumscribed virtual parallelogram 30b corresponding to the second sub-pixel 12 intersects with the third side of the second sub-pixel 12. A center of gravity of the first sub-pixel 11 is Pb11, and a center of gravity of the second sub-pixel 12 is Pb12.

In the direction S2, the first sub-pixel 11 and the second sub-pixel 12 adjacent to each other satisfy at least one of the following conditions: (1) a line Pa11-Pa12 connecting the center of the circumscribed virtual parallelogram 30a corresponding to the first sub-pixel 11 and the center of the circumscribed virtual parallelogram 30b corresponding to the second sub-pixel 12 intersects with the third side of the first sub-pixel 11; or (2) a line Pa11-Pa12 connecting the center of the circumscribed virtual parallelogram 30a corresponding to the first sub-pixel 11 and a center of the circumscribed virtual parallelogram 30b corresponding to the second sub-pixel 12 intersects with the third side of the second sub-pixel 12.

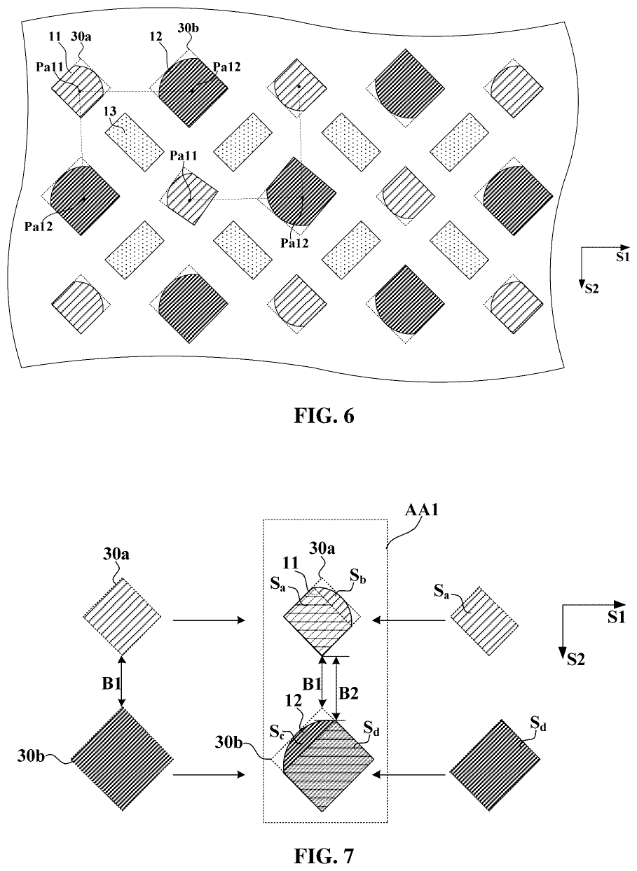

FIG. 6 is a schematic diagram of another display panel according to an embodiment of the present disclosure. As shown in FIG. 6, in the direction S1, there exist the first sub-pixel 11 and the second sub-pixel 12 adjacent to each other satisfy the following conditions: the line Pa11-Pa12 connecting the center of the circumscribed virtual parallelogram 30a corresponding to the first sub-pixel 11 and the center of the circumscribed virtual parallelogram 30b corresponding to the second sub-pixel 12 intersects with the third side of the first sub-pixel 11 and the third side of the second sub-pixel 12. In the direction S2, there exist the first sub-pixel 11 and the second sub-pixel 12 adjacent to each other satisfy the following conditions: the line Pa11-Pa12 connecting the center of the circumscribed virtual parallelogram 30a corresponding to the first sub-pixel 11 and the center of the circumscribed virtual parallelogram 30b corresponding to the second sub-pixel 12 intersects with the third side of the first sub-pixel 11 and the third side of the second sub-pixel 12.

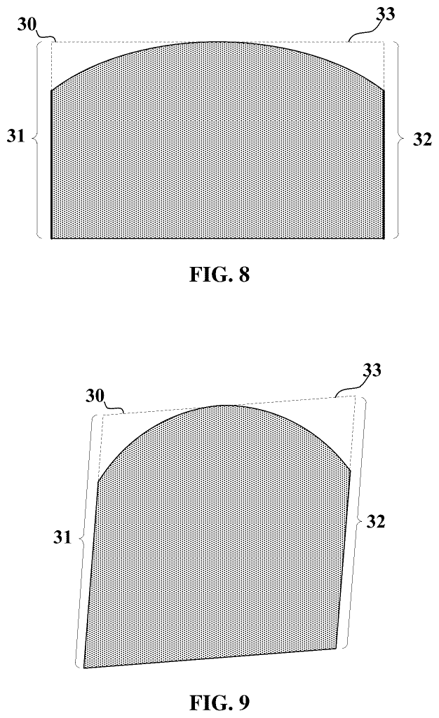

FIG. 7 is a schematic diagram of AA1 in FIG. 1A. With reference to FIGS. 1A and 7, the first sub-pixel 11 and the second sub-pixel 12 are disposed adjacent to each other in the direction S2. It can be seen that the minimum distance between the circumscribed virtual parallelogram 30b of the second sub-pixel 12 and an opening region of the first sub-pixel 11 is B1, and the minimum distance between the third side of the second sub-pixel 12 and the opening region of the first sub-pixel 11 is B2, and B1 is less than B2. It should be understood that B2 is essentially the minimum distance between an opening region of the second sub-pixel 12 and the opening region of the first sub-pixel 11. It can be seen that an area of the opening region of the first sub-pixel 11 is a sum of an area Sₐ and an area S_{b}, where one side of a shape corresponding to the area S_{b} is the third side of the first sub-pixel 11; an opening region area of the second sub-pixel 12 is a sum of an area S_{c} and an area S_{d}, where one side of a shape corresponding to the area S_{c} is the third side of the second sub-pixel 12.

If the circumscribed virtual parallelogram is used as the opening region of the sub-pixel, then the minimum distance between the second sub-pixel and the opening region of the first sub-pixel is B1. In the embodiment of the present application, the opening region of the first sub-pixel 11 may be considered as being formed by cutting off a part of corner regions of the circumscribed virtual parallelogram 30a of the first sub-pixel 11, and the opening region of the second sub-pixel 12 may be considered as being formed by cutting off a part of corner regions of the circumscribed virtual parallelogram 30b of the second sub-pixel 12. The minimum distance between the opening region of the second sub-pixel 12 and the opening region of the first sub-pixel 11 is B2, and B2 is greater than B1. It should be noted that a distance between the opening regions of the two adjacent sub-pixels is positively correlated with a lateral leakage current of the two sub-pixels. The smaller the lateral distance between the two adjacent sub-pixels, the larger the lateral leakage current between the two adjacent sub-pixels, and conversely, the larger distance between the opening regions of the two adjacent sub-pixels, the smaller the lateral leakage current. Based on this, compared with the circumscribed virtual parallelogram being served as the opening region of the sub-pixel, the design of the first sub-pixel 11 and the second sub-pixel 12 in the embodiment of the present application can increase the spacing between the opening region of the second sub-pixel 12 and the opening region of the first sub-pixel 11, therefore, the leakage current between the first sub-pixel 11 and the adjacent second sub-pixel 12 can be reduced, thereby improving the problem of sneaking light of the pixel and improving the display effect.

In addition, if an opening of the first sub-pixel 11 is only a portion corresponding to the area Sₐ, and the opening of the second sub-pixel 12 is only a portion corresponding to the area S_{d}, that is, an area corresponding to the third side is removed from the sub-pixel, by means of this design, a distance between opening regions of two adjacent sub-pixels may be increased, but the opening ratio may be reduced. In the embodiment of the present application, compared with the condition that the opening of the first sub-pixel 11 is only the portion corresponding to the area Sₐ and the opening of the second sub-pixel 12 is only the portion corresponding to the area Sₐ, the third side of the sub-pixel is designed as a portion including multiple sub-segments and coincides with a third virtual side of the circumscribed virtual parallelogram, so that an opening area of the first sub-pixel 11 significantly increases and increases by at least the area S_{b}, and an opening area of the second sub-pixel 12 significantly increases and increases at least the area S_{c}. Compared with the condition that the opening of the first sub-pixel 11 is only the portion corresponding to the area Sₐ and the opening of the second sub-pixel 12 is only the portion corresponding to the area Sₐ, in the embodiment of the present application, an opening ratio of the first sub-pixel 11 and an opening ratio of the second sub-pixel 12 can be increased, thereby improving the display effect.

Referring to FIGS. 1A and 1B, FIG. 1B is a schematic diagram of a display panel in the related art. Each of a first sub-pixel 11y and a second sub-pixel 12y is square, the first sub-pixel 11y and the second sub-pixel 12y are arranged alternately in the first direction S1 and the second direction S2, centers (that is, centers of gravity) of two first sub-pixels 11y and two second sub-pixel 12y adjacent to each other constitute a virtual square Qs, one third sub-pixel 13y is located in the virtual square Qs, and a center (that is, center of gravity) of the third sub-pixel 13y coincides with a center of the virtual square Qs. If the first sub-pixel 11y is a red sub-pixel R, the second sub-pixel 12y is a blue sub-pixel B, the third sub-pixel 13y is a green sub-pixel G, a center-to-center distance (that is, pixel pitch) of the first sub-pixel 11y and the second sub-pixel 12y is PL, an opening spacing (that is, a spacing of the pixel defining layer, for details, refer to the following) of the first sub-pixel 11y and the second sub-pixel 12y is d1, an opening area of the first sub-pixel 11y is S_{Ry}, and an opening area of the second sub-pixel 12y is S_{By}, then the opening area of the first sub-pixel 11y and the opening area of the second sub-pixel 12y in the related art satisfy:

$$\frac{{( \sqrt{2} Xr )}^{2}}{{( \sqrt{2} ( P L - d 1 - Xr ) )}^{2}} = \frac{{S}_{R y}}{{S}_{B y}} = \frac{1}{k} ;$$

where K is a coefficient, and the following is obtained after further conversion:

$$Xr = \frac{P L - d 1}{\sqrt{k} + 1} .$$

In a case where the conventional pixels per inch (PPI) requirement of the display panel is satisfied, PL=55 μm, and k=3 (conforming to a tristimulus value of the white-dot coordinates RGB) is selected, in the related art, the minimum opening spacing between the first sub-pixel 11y and the second sub-pixel 12y is d1=25 μm, Xr=10.98 μm, S_{Ry}=241.12 μm², S_{By}=723.52 μm², the minimum opening spacing between the third sub-pixel 13y and the first sub-pixel 11y is d2=18 μm, the minimum opening spacing between the third sub-pixel 13y and the second sub-pixel 12y is d3=18 μm, the minimum opening spacing between two adjacent third sub-pixels 13y is d4=35 μm, and an opening area of the third sub-pixel 13y is S_{Gy}=308.15 μm². If one pixel unit includes one first sub-pixel 11y, one second sub-pixel 12y, and two third sub-pixels 13y, then a sum of opening areas of one pixel unit is S_{RGBy}=1580.94 μm².

FIG. 1C is a schematic comparison diagram between a display panel according to an embodiment of the present disclosure and a display panel in FIG. 1B. Meanwhile, referring to FIG. 19, FIG. 19 is a schematic diagram of a sub-pixel according to an embodiment of the present disclosure. An example in which each of the first sub-pixel 11 and the second sub-pixel 12 is the sub-pixel in FIG. 19 is used for description. The design of the sub-pixel in FIG. 19 is described in detail below. Referring to FIGS. 1C and 19, in FIG. 1C, an example in which the third side of the first sub-pixel 11 includes two arc segments and one straight line segment, the third side of the second sub-pixel 12 includes two arc segments and one straight line segment, the third sub-pixel 13 is an octagon, the circumscribed virtual parallelogram 30a of the first sub-pixel 11 is a square, the circumscribed virtual parallelogram 30b of the second sub-pixel 12 is a square, and the centers of the two circumscribed virtual parallelogram 30a and the two circumscribed virtual parallelogram 30b adjacent to each other constitute the virtual square Qs is used for description. In the embodiments provided in the present disclosure, it is assumed that the minimum opening spacing between the first sub-pixel 11 and the second sub-pixel 12 is g1=25 μm, the minimum opening spacing between the third sub-pixel 13 and the first sub-pixel 11 is g2=18 μm, the minimum opening spacing between the third sub-pixel 13 and the second sub-pixel 12 is g3=18 μm, and the minimum opening spacing between two adjacent sub-pixels 13 is g4=35 μm, that is, the minimum opening spacing between any two of the first sub-pixel 11, the second sub-pixel 12 and the third sub-pixel 13 and the minimum spacing between two adjacent third sub-pixels 13 in the embodiment of the present disclosure are set to be equal to the corresponding minimum opening spacing in the related art. It should be noted that in the related art, since each of the first sub-pixel 11y and the second sub-pixel 12y is a square, the minimum opening spacing between the first sub-pixel 11y and the second sub-pixel 12y is a distance along a line connecting centers of the sub-pixels (a side of the virtual square Qs). In the embodiment of the present disclosure, the minimum opening spacing g1 between the first sub-pixel 11 and the second sub-pixel 12 is not equal to a distance of the first sub-pixel 11 and the second sub-pixel 12 on the side of the virtual square Qs. For example, for the first sub-pixel 11s and the second sub-pixel 12s, the minimum opening spacing g1 between the first sub-pixel 11s and the second sub-pixel 12s is a distance between a point P24 (refer to an intersection point of the second side 22 and the third side 23 as shown in FIG. 19) of the first sub-pixel 11s and a right-angle vertex of the second sub-pixel 12s. For the first sub-pixel 11s and the second sub-pixel 12t, the minimum opening spacing g1 between the first sub-pixel 11s and the second sub-pixel 12t is a distance between a point P24 of the second sub-pixel 12t (refer to the intersection point of the second side 22 and the third side 23 as shown in FIG. 19) and a right-angle vertex of the first sub-pixel 11s. The minimum opening spacing between any other adjacent first sub-pixel 11 and second sub-pixel 12 is also the same, and details are not described again.

In an embodiment, referring to FIG. 1C, an area of the circumscribed virtual parallelogram 30a of the first sub-pixel 11s (or the first sub-pixel 11t) is greater than an area of the first sub-pixel 11y, and an area of the circumscribed virtual parallelogram 30b of the second sub-pixel 12s is greater than an area of the second sub-pixel 12y, that is, compared with the first sub-pixel 11y, at least a part of outlines of the first sub-pixel 11 is expanded outward. Compared with the second sub-pixel 12y, at least a part of outlines of the second sub-pixel 12 is expanded outward. Referring to FIGS. 2 and 19, it is assumed that Xa corresponding to the first sub-pixel 11=Xb corresponding to the first sub-pixel 11=2.8 μm, a length of a straight line segment from P22 to P23 is 5 μm, and Xa corresponding to the second sub-pixel 12=Xb corresponding to the second sub-pixel 12=2.7 μm, and a length of a straight segment from P22 to P23 is 6 μm, the calculated values are S_{R}=261.56 μm², S_{B}=799.45 μm², S_{G}=279.84 μm², and a sum of opening areas of one pixel unit is S_{RGB}=1620.69 μm².

Through the above calculation, compared with the related art, the total opening ratio of the display panel may be further improved in the embodiment of the present disclosure. In an embodiment, referring to FIG. 1C, although an opening ratio of the third sub-pixel 13 is reduced, the opening ratio of the first sub-pixel 11 and the opening ratio of the second sub-pixel 12 are improved, so that the total opening ratio of the display panel is improved. The second sub-pixel 12s is used as an example, a large arc edge of the circumscribed virtual parallelogram 30b corresponding to the second sub-pixel 12s is cut, that is, an angle of the second sub-pixel 12s away from the first sub-pixel 11S in the first direction S1 and an angle of the second sub-pixel 12s away from the first sub-pixel 11t in the second direction S2 are retracted, thereby reserving a space for externally expanding the first sub-pixel 11 adjacent to the second sub-pixel 12s and keeping the minimum opening spacing g1 between the first sub-pixel 11 and the second sub-pixel 12 ≥d1; and for the second sub-pixel 12s, the remaining portions are expanded externally except that the two angles are retracted, so that the opening area of the second sub-pixel 12s is increased. For the first sub-pixel 11 and the second sub-pixel 12 in one pixel unit (one first sub-pixel 11, one second sub-pixel 12, and two third sub-pixels 13), an increase in the opening area may be obtained. Since the first sub-pixel 11 and the second sub-pixel 12 are externally expanded, in order to ensure that the minimum opening spacing g2 between the third sub-pixel 13 and the first sub-pixel 11 and the minimum opening spacing g3 between the third sub-pixel 13 and the second sub-pixel 12 still satisfy g2≥d2 and g3≥d3, at least a part of sides of the third sub-pixel 13 (13s) located in the virtual square Qs needs to be retracted (that is, two sides opposite to each other in the third direction S3 and two sides opposite to each other in the fourth direction S4 are retracted), which will result in the decrease in the opening area of the third sub-pixel 13. However, the design of the third sub-pixel 13 is not limited to g2 and g3, it is also limited to widths of ribs of evaporated mask plates of two adjacent third sub-pixels 13 in the first direction S1 and the second direction S2. In the display panel, the third sub-pixel 13 is real resolution, and a quantity of the third sub-pixel 13 is twice of the first sub-pixel 11, and is also twice of the second sub-pixel 12. In order to ensure the strength of the fine metal mask (FMM), that is, to ensure the width of the rib of the FMM, a predetermined interval needs to be separated between adjacent openings, a distance between the two adjacent third sub-pixels 13 in the first direction S1 and the second direction S2 is also limited. However, this limitation is not further retracted by the external expansion of the first sub-pixel 11 and the second sub-pixel 12, that is, compared to the related art, in the third sub-pixel 13, two sides opposite to each other in the first direction S1 and two sides opposite to each other in the second direction S2 are not retracted, which makes it unnecessary to set the opening area of the third sub-pixel smaller. Therefore, compared with the related art, the design of the pixels in the embodiment of the present application can improve the total opening ratio (opening area) of the display panel. In addition, related process parameters (such as, the minimum opening spacing between adjacent sub-pixels, and FMM rib) in the present application are equal to or superior to those in the related art. That is, in the case where it is ensured that the minimum opening spacing between adjacent sub-pixels and the width of the FMM rib are consistent with in the related art or still have design redundancy, the total opening ratio of the present application is greater, and the display effect and the display quality are better.

It should be understood that, referring to FIG. 1C, in the embodiment of the present disclosure, when the circumscribed virtual parallelogram 30a corresponding to the first sub-pixel 11 is a square, a side length of the circumscribed virtual parallelogram 30a is w1; when the circumscribed virtual parallelogram 30b corresponding to the second sub-pixel 12 is a square, a side length of the circumscribed virtual parallelogram 30b is w2; the shortest distance between two opposite sides of the third sub-pixel 13 in the third direction S3 is w3, and the shortest distance between two opposite sides of the third sub-pixel 13 in the fourth direction S4 is w4, where w1+w2>w3+w4.

Referring to FIG. 1D, FIG. 1D is a schematic comparison diagram between another display panel according to an embodiment of the present disclosure and another display panel in the related art. Compared with FIGS. 1B and 1C, the difference is that a third sub-pixel 13y in FIG. 1D is a rectangle, and a third sub-pixel 13 in FIG. 1D is a rectangle. Since w1+w2>w3+w4, compared with the related art, in the embodiment of the present application, the total opening ratio of the display panel can still be improved, thereby improving the display effect and the display quality, and details are not described herein again. It should be understood that, in the concept of the present disclosure, the shape of the third sub-pixel 13 may be a rounded rectangle, a capsule shape (runway shape), and the like, and no further example is provided.

It should be noted that, in the various drawings of the present disclosure, the virtual shapes are shown by dashed boxes, and it should be understood that the relevant structures such as the dashed boxes and the connecting lines thereof do not exist actually.

In the present disclosure, the two first sub-pixels and the two second sub-pixels form the first virtual quadrilateral, the third sub-pixel is located inside the first virtual quadrilateral, the four third sub-pixels form the second virtual quadrilateral, and the first sub-pixel or the second sub-pixel is located inside the second virtual quadrilateral, so that the distribution of the sub-pixels in the display panel is uniform, and the display effect of the display panel is better. In the direction in which the first sub-pixel and the second sub-pixel are arranged alternately, the line connecting the center of the circumscribed virtual parallelogram corresponding to the first sub-pixel and the center of the circumscribed virtual parallelogram corresponding to the second sub-pixel at least intersects with the third side of the one of the first sub-pixel or the second sub-pixel. In a case of keeping consistency with existing relevant process parameters (such as, the minimum opening spacing between adjacent sub-pixels, FMM rib), the opening ratios of the first sub-pixel and the second sub-pixel can be increased, the overall opening ratio of the display panel can be improved, and further the display effect can be improved. In addition, compared with the related art, if the total opening ratio of the display panel is kept unchanged, then in the present application, the distance between the opening region of the first sub-pixel and the opening region of the second sub-pixel adjacent to the the first sub-pixel can also be increased, so that the lateral distance between the first sub-pixel and second sub-pixel adjacent to each other is increased, and further the leakage current between the first sub-pixel and second sub-pixel adjacent to each other is reduced, thereby improving the problem of sneaking light of the pixel and improving the display effect.

The foregoing is the core idea of the present disclosure. The technical schemes in the embodiments of the present disclosure will be clearly and completely described below in conjunction with the accompanying drawings in the embodiments of the present disclosure.

In an embodiment, the shape of the circumscribed virtual parallelogram is a rectangle, a square, or a rhombus.

In an embodiment, a shape of the circumscribed virtual parallelogram corresponding to the first sub-pixel is a parallelogram, a rectangle, a square, or a rhombus. A shape of the circumscribed virtual parallelogram corresponding to the second sub-pixel is a parallelogram, a rectangle, a square, or a rhombus. The shape of the circumscribed virtual parallelogram corresponding to the first sub-pixel may be the same as the shape of the circumscribed virtual parallelogram corresponding to the second sub-pixel, or the shape of the circumscribed virtual parallelogram corresponding to the first sub-pixel is different from the shape of the circumscribed virtual parallelogram corresponding to the second sub-pixel.

As shown in FIG. 3, a shape of the circumscribed virtual parallelogram 30 corresponding to the sub-pixel is a parallelogram, and any one interior angle of the parallelogram is not equal to 90°.

As shown in FIG. 2, a shape of the circumscribed virtual parallelogram 30 corresponding to the sub-pixel is a square, four interior angles of the circumscribed virtual parallelogram 30 are all 90°, and a length of the first virtual side 31, a length of the second virtual side 32, a length of the third virtual side 33, and a length of the fourth virtual side 34 are equal.

FIG. 8 is a schematic diagram of another sub-pixel according to an embodiment of the present disclosure. As shown in FIG. 8, a shape of the circumscribed virtual parallelogram 30 corresponding to the sub-pixel is a rectangle, four interior angles of the circumscribed virtual parallelogram 30 are all 90°, and a length of the third virtual side 33 is not equal to a length of the first virtual side 31.

FIG. 9 is a schematic diagram of another sub-pixel according to an embodiment of the present disclosure. As shown in FIG. 9, a shape of the circumscribed virtual parallelogram 30 corresponding to the sub-pixel is a rhombus, any one interior angle of the circumscribed virtual parallelogram 30 is not equal to 90°, and a length of the third virtual side 33 is equal to a length of the first virtual side 31.

As described above, the sub-pixel is located inside the circumscribed virtual parallelogram 30 corresponding to the sub-pixel. As shown in FIG. 1A to FIG. 1D, a shape of the circumscribed virtual parallelogram 30a corresponding to the first sub-pixel 11 may be the same as a shape of the circumscribed virtual parallelogram 30b corresponding to the second sub-pixel 12, for example, both the shape of the circumscribed virtual parallelogram 30a corresponding to the first sub-pixel 11 and the shape of the circumscribed virtual parallelogram 30b corresponding to the second sub-pixel 12 are all squares. Alternatively, a shape of the circumscribed virtual parallelogram corresponding to the first sub-pixel may be different from a shape of the circumscribed virtual parallelogram corresponding to the second sub-pixel, for example, the shape of the circumscribed virtual parallelogram corresponding to the first sub-pixel is a square shown in FIG. 2, and the shape of the circumscribed virtual parallelogram corresponding to the second sub-pixel is a parallelogram shown in FIG. 3.

The circumscribed virtual parallelogram 30 is a regular shape in which the geometric center coincides with the center of gravity. According to this pixel arrangement manner, a pixel array in the display panel may be divided into repetition units arranged in an array, and the resolution of the display panel may be improved.

In addition, the sub-pixel is located inside the circumscribed virtual parallelogram 30 corresponding to the sub-pixel, so that a shape of the sub-pixel can be flexibly adjusted to cause a center of gravity of the sub-pixel to change, and thus a shape of the first virtual quadrilateral changes. The shape of the first virtual quadrilateral affects the color mixing condition between the first sub-pixel, the second sub-pixel, and the third sub-pixel. Therefore, the shape of the sub-pixel is adjusted, so that the brightness distribution of the display panel can be more evenly distributed in the pixel arrangement, thereby improving the display effect.

It should be noted that the sub-pixel is located inside the circumscribed virtual parallelogram 30 corresponding to the sub-pixel, the shape of the sub-pixel is not limited to the foregoing example, and the shape of the sub-pixel may be an irregular shape or may be a regular shape. When the shape of the sub-pixel is the irregular shape, a center of the sub-pixel is difficult to be determined, but a center of gravity of the sub-pixel may be clear. When the shape of the sub-pixel is the regular shape, the center, the geometric center, and the center of gravity of the sub-pixel overlap. Similarly, the virtual parallelogram is used as the regular shape, and a center of the virtual parallelogram is a center of geometry, which is also a center of gravity.

In an embodiment, in a direction in which the first sub-pixel and the second sub-pixel are arranged alternately, a line connecting a center of the circumscribed virtual parallelogram corresponding to the first sub-pixel and a center of the circumscribed virtual parallelogram corresponding to the second sub-pixel does not intersect with the second side.

Referring to FIGS. 1A, 2, and 3, in the embodiment of the present application, the first side and the second side of any one of the first sub-pixel 11 or the second sub-pixel 12 are straight line segments. In the direction S1 or the direction S2, a line Pa11-Pa12 connecting a center of the circumscribed virtual parallelogram 30a corresponding to the first sub-pixel 11 and a center of the circumscribed virtual parallelogram 30b corresponding to the adjacent second sub-pixel 12 does not intersect with the second side of the two sub-pixels, and does not intersect with the first side of the two sub-pixels.

In the case where the center connection line Pa11-Pa12 intersects with the third side of the first sub-pixel 11, as shown in FIG. 1A, the center connection line Pa11-Pa12 further passes through one vertex of the adjacent second sub-pixel 12, where the vertex is an intersection point of the first side (or the second side) of the second sub-pixel 12 and the fourth side of the second sub-pixel 12, that is, the intersection point of the first side (or the second side) of the second sub-pixel 12 and the fourth side of the second sub-pixel 12 is located on the center connection line Pa11-Pa12. Alternatively, as shown in FIG. 6, the center connection line Pa11-Pa12 also intersects with the third side of the adjacent second sub-pixel 12. Alternatively, as shown in FIG. 6, the center connection line Pa11-Pa12 also intersects with the fourth side of the adjacent second sub-pixel 12.

Similarly, in the case where the center connection line Pa11-Pa12 intersects with the third side of the second sub-pixel 12, as shown in FIG. 1A, the center connection line Pa11-Pa12 further passes through one vertex of the adjacent first sub-pixel 11, where the vertex is an intersection point of the first side (or the second side) of the first sub-pixel 11 and the fourth side of the first sub-pixel 11, that is, the intersection point of the first side (or the second side) of the first sub-pixel 11 and the fourth side of the first sub-pixel 11 is located on the center connection line Pa11-Pa12. Alternatively, as shown in FIG. 6, the center connection line Pa11-Pa12 also intersects with a third side of the adjacent first sub-pixel 11. Alternatively, as shown in FIG. 6, the center connection line Pa11-Pa12 also intersects with a fourth side of the adjacent first sub-pixel 11.

In the embodiment of the present application, for the design of the third side of the first sub-pixel 11 and the third side of the second sub-pixel 12, on one hand, in the case of keeping consistency with existing relevant process parameters (such as, the minimum opening spacing between adjacent sub-pixels, FMM rib), the opening ratios of the first sub-pixel 11 and the second sub-pixel 12 can be increased, the overall opening ratio of the display panel can be improved, and thus the display effect can be improved; on the other hand, compared with the related art, in the case of keeping the total opening ratio of the display panel unchanged, in the present application, a distance between the opening region of the first sub-pixel 11 and the opening region of the second sub-pixel 12 can also be increased, so that a lateral distance between the first sub-pixel 11 and the second sub-pixel 12 is increased, the leakage current is reduced, the phenomenon of sneaking light is reduced, and the display effect is improved.

In order to more clearly explain the schemes of the present disclosure, the following embodiments are described in detail based on the case where the shape of the circumscribed virtual parallelogram is the square.

In an embodiment, the first sub-segment is connected to the second sub-segment, a connection point of the first sub-segment and the second sub-segment is located on the third virtual side, the third virtual side is tangent to the third side at the connection point, and each of the first sub-segment and the second sub-segment is an arc segment.

As shown in FIG. 2, the shape of the first sub-pixel may be independently selected as the shape of the sub-pixel, and/or the shape of the second sub-pixel may be independently selected as the shape of the sub-pixel. The third side 23 of the sub-pixel includes only the first sub-segment 23a and the second sub-segment 23b, and each of the first sub-segment 23a and the second sub-segment 23b is an arc segment. The first sub-segment 23a is connected to the second sub-segment 23b, and a connection point P1 of the first sub-segment 23a and the second sub-segment 23b is located on the third virtual side 33. Based on this, the third virtual side 33 is tangent to the third side 23 at the connection point P1 of the first sub-segment 23a and the second sub-segment 23b.

Referring to FIGS. 7 and 2, the third side of the first sub-pixel 11 is formed of two arc segments, the third side of the second sub-pixel 12 is formed of two arc segments, so that the opening ratio of the first sub-pixel 11 can be increased, and the opening ratio of the second sub-pixel 12 can also be increased. In addition, it can be further ensured that a distance between the opening region of the first sub-pixel 11 and the opening region of the second sub-pixel 12 adjacent to the first sub-pixel 11 is relatively large, the leakage flow is reduced, the problem of sneaking light is improved, and thus the display effect is improved.

With reference to the shape of the circumscribed virtual parallelogram 30, the first sub-segment 23a of the third side 23 may be considered as being formed by cutting corner region between a first virtual side 31 of the circumscribed virtual parallelogram 30 and a third virtual side 33 of the circumscribed virtual parallelogram 30, and the second sub-segment 23b of the third side 23 may be considered as being formed by cutting corner region between a second virtual side 32 of the circumscribed virtual parallelogram 30 and the third virtual side 33 of the circumscribed virtual parallelogram 30.

Referring to FIG. 7, compared with a spacing B1 of two adjacent circumscribed virtual parallelograms (the circumscribed virtual parallelogram 30a and the circumscribed virtual parallelogram 30b), the third side 23 of the sub-pixel may be designed to be formed of an arc segment. Therefore, a distance between the opening region of the first sub-pixel 11 and the opening region of the adjacent second sub-pixel 12 may be increased to B2, and B2 is greater than B1. In this way, the leakage current between the first sub-pixel 11 and the adjacent second sub-pixel 12 can be reduced, the problem of sneaking light can be reduced, and the display effect can be improved.

In an embodiment, the first sub-segment and the second sub-segment are located on a circumference of the same virtual circle.

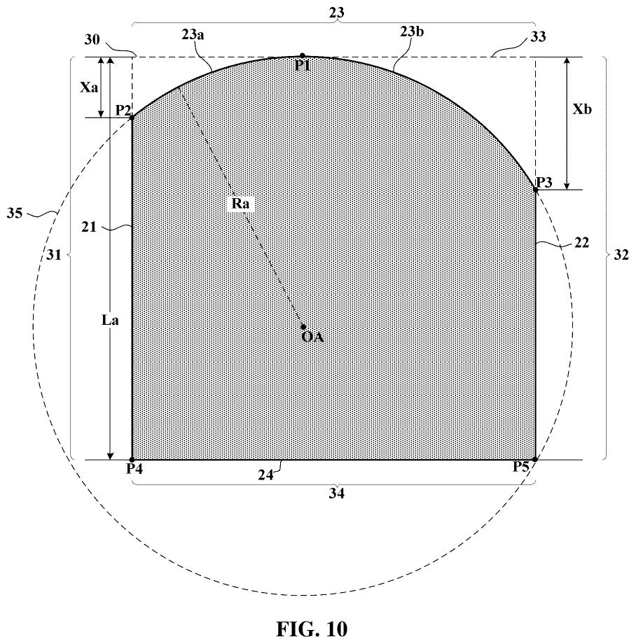

FIG. 10 is a schematic diagram of another sub-pixel according to an embodiment of the present disclosure. As shown in FIG. 10, a point P2 is selected on the first virtual side 31 of the circumscribed virtual parallelogram 30, a point P3 is selected on the second virtual side 32 of the circumscribed virtual parallelogram 30, a point P1 is selected on the third virtual side 33 of the circumscribed virtual parallelogram 30, and a unique virtual circle 35 may be determined according to the points P2, P3, and P1. An arc segment of P2 to P1 on the circumference of the virtual circle 35 is determined as the first sub-segment 23a, and an arc segment of P3 to P1 on the circumference of the virtual circle 35 is determined as the second sub-segment 23b, based on this, the third side 23 of the sub-pixel may be determined. A shape of the sub-pixel in the circumscribed virtual parallelogram 30 may be a non-axisymmetric pattern, where P1 does not overlap with a midpoint of the third virtual side 33, and Xa is not equal to Xb.

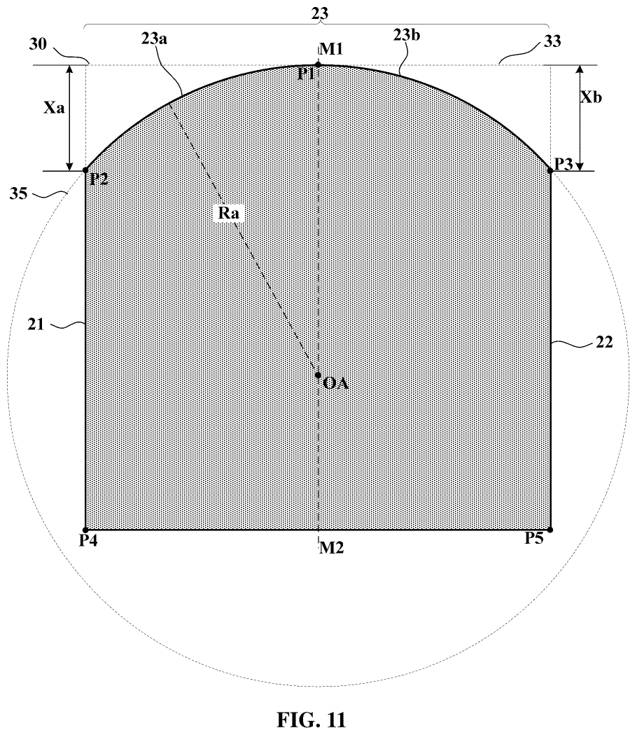

FIG. 11 is a schematic diagram of another sub-pixel according to an embodiment of the present disclosure. The difference from FIG. 10 is that, as shown in FIG. 11, the shape of the sub-pixel in the circumscribed virtual parallelogram 30 may be an axisymmetric pattern, where the midpoint of the third virtual side 33 may be determined as the point P1, and Xa is equal to Xb. The symmetric axis M1-M2 passes through the midpoint (point P1) of the third virtual side 33, and the shape of the sub-pixel may be symmetrical about the symmetric axis M1-M2.

A shape of the first sub-pixel may be selected as the shape of the sub-pixel in FIG. 10 or FIG. 11, and a shape of the second sub-pixel may be selected as a shape of the sub-pixel in FIG. 10 or FIG. 11. The shape of the first sub-pixel may be the same as the shape of the second sub-pixel. However, in other embodiments, the shape of the first sub-pixel may be different from the shape of the second sub-pixel.

In an embodiment, 0.5*La≤Ra≤1.5*La, where Ra denotes a radius of the virtual circle. A length of the first virtual side of the circumscribed virtual parallelogram corresponding to the sub-pixel is La, and the radius Ra of the virtual circle is set to be greater than or equal to 0.5*La and less than or equal to 1.5*La.

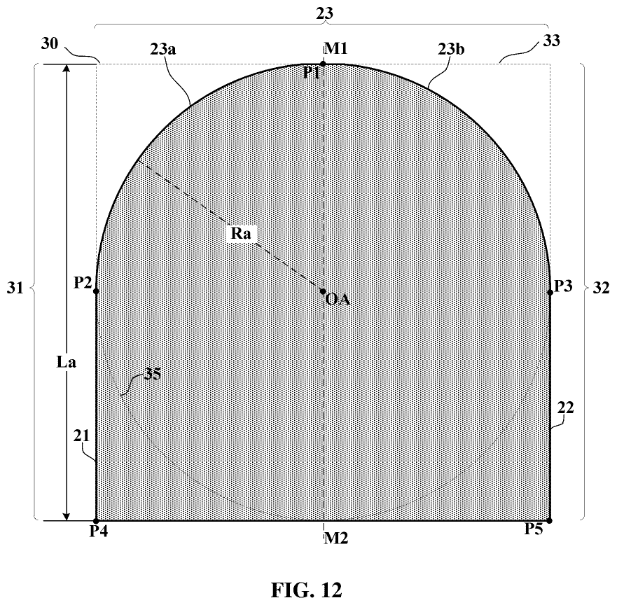

FIG. 12 is a schematic diagram of another sub-pixel according to an embodiment of the present disclosure. As shown in FIG. 12, positions of the points P2, P3 and P1 may be adjusted to obtain different virtual circles 35. The smallest virtual circle 35 corresponding to the points P2, P3 and P1 is an inscribed circle of the circumscribed virtual parallelogram 30, and the inscribed circle is tangent to the first virtual side 31, the second virtual side 32, and the third virtual side 33. A center of the virtual circle 35 is OA, a radius of the virtual circle is Ra, and the inscribed circle is a minimum virtual circle 35. Therefore, the radius Ra of the virtual circle 35 may be greater than or equal to 0.5*La. If the radius Ra of the virtual circle 35 is less than 0.5*La, then the first sub-segment 23a and the second sub-segment 23b cannot be simultaneously obtained by using the same virtual circle, that is, the first sub-segment 23a and the second sub-segment 23b cannot be located on a circumference of the same virtual circle.

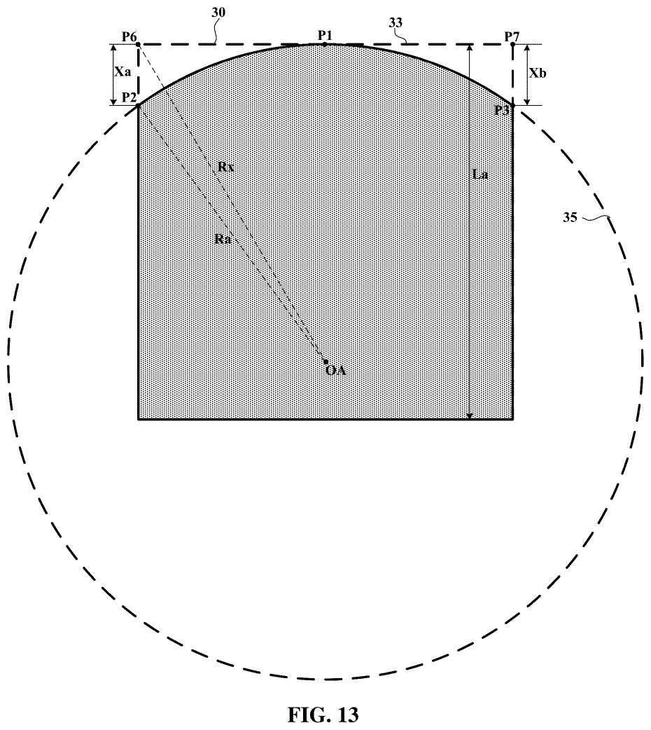

P2, P3, and P1 in different positions are selected, and the obtained virtual circle 35 may partially overlap with the circumscribed virtual parallelogram. In an embodiment, a radius Ra of the virtual circle 35 satisfies 0.5*La≤Ra≤1.5*La. FIG. 13 is a schematic diagram of another sub-pixel according to an embodiment of the present disclosure. As shown in FIG. 13, the radius Ra of the virtual circle 35 is less than or equal to 1.5*La. If P2 approaches the endpoint P6 of the third virtual side 33 and P3 approaches the endpoint P7 of the third virtual side 33, then Xa and Xb gradually decrease, and the radius Ra of the virtual circle 35 determined by P2, P1, and P3 gradually increases. However, the radius Ra of the virtual circle 35 should be less than or equal to 1.5*La, so as to ensure the spacing between opening regions of adjacent sub-pixels, thereby effectively reducing the leakage current and weakening the problem of sneaking light.

Virtual circles 35 of different dimensions are obtained by flexibly designing P1, P2, and P3, and correspondingly, a radian of the first sub-section and a radian of the second sub-section may be adjusted.

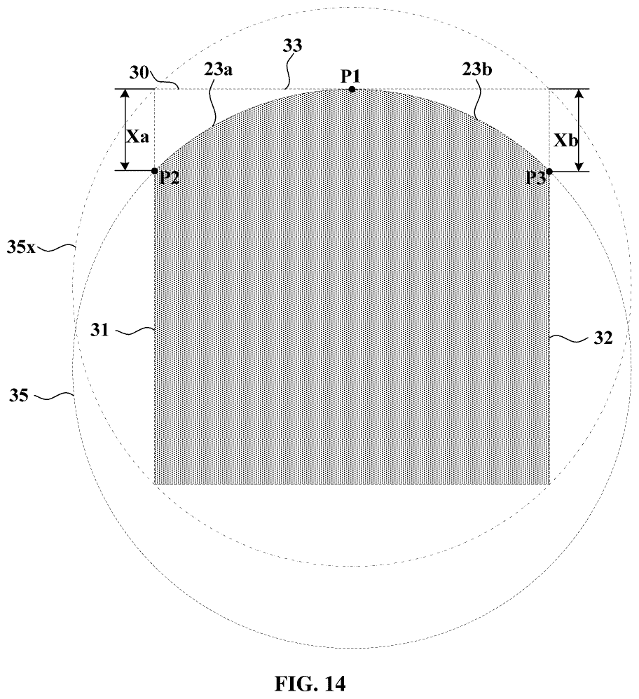

In an embodiment, the virtual circle is a circumscribed circle corresponding to the circumscribed virtual parallelogram of the sub-pixel. FIG. 14 is a schematic diagram of another sub-pixel according to an embodiment of the present disclosure. As shown in FIG. 14, in an embodiment, the first sub-segment 23a and the second sub-segment 23b are located on a circumference of the same virtual circle 35, where the virtual circle 35 is equal in size to the circumscribed circle 35x of the circumscribed virtual parallelogram 30 of the sub-pixel.

Different virtual circles 35 may be obtained by adjusting positions of the points P2, P3, and P1. A size of the virtual circle 35 determined by the points P2, P3, and P1 may be equal to a size of the circumscribed circle 35x of the circumscribed virtual parallelogram 30. The virtual circle 35 is tangent to the third virtual side 33 at the point P1, intersects with the first virtual side 31 at the point P2, and intersects with the second virtual side 32 at the point P3. If P1 may be the midpoint of the third virtual side 33, then the shape of the sub-pixel may be an axisymmetric pattern; or, if P1 is not the midpoint of the third virtual side 33, then the shape of the sub-pixel is a non-axisymmetric pattern.

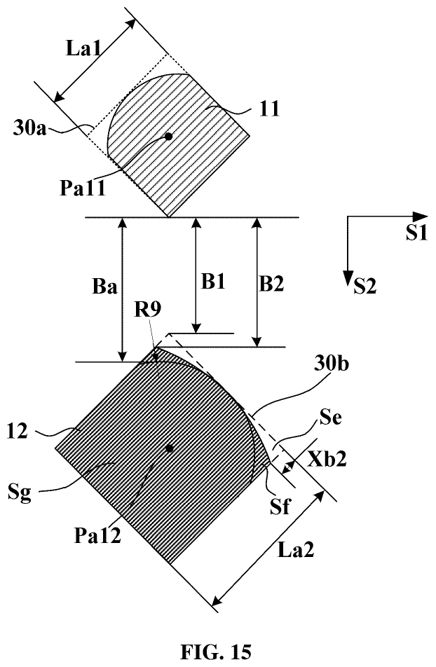

FIG. 15 is a schematic diagram of a first sub-pixel and a second sub-pixel adjacent to each other in a direction S2 according to an embodiment of the present disclosure. As shown in FIG. 15, the circumscribed virtual parallelogram 30a corresponding to the first sub-pixel 11 is designed to be a square, the circumscribed virtual parallelogram 30b corresponding to the second sub-pixel 12 is designed to be a square, a distance (Pa11-Pa12) between the center of the circumscribed virtual parallelogram 30a corresponding to the first sub-pixel 11 and the center of the circumscribed virtual parallelogram 30b corresponding to the adjacent sub-pixel 12 in the direction S2 is 55 μm, and a side length La2 of the circumscribed virtual parallelogram 30b corresponding to the second sub-pixel 12 is 28.28 μm, and a side length La1 of the circumscribed virtual parallelogram 30a corresponding to the first sub-pixel 11 is 21.21 μm, which is used as an example for subsequent description.

In scheme 1, if the circumscribed virtual parallelogram 30b of the second sub-pixel 12 is used as a pixel opening, then a corresponding opening area is 28.28 μm*28.28 μm=800 μm², where 800=(2*Se+Sg), Se=17.38 μm², Sg=765.2345 μm². A spacing B1 between the circumscribed virtual parallelogram 30b of the second sub-pixel 12 and the circumscribed virtual parallelogram 30a of the first sub-pixel 11 in the direction S2 is 20 μm.

In the embodiment of the present disclosure, the opening region of the second sub-pixel 12 is formed by chamfering the circumscribed circle of the circumscribed virtual parallelogram and Xb2=3 μm, a spacing B2 between the opening region of the second sub-pixel 12 and the circumscribed virtual parallelogram 30a of the first sub-pixel 11 in the direction S2 is 22.89 μm, and an opening region area of the second sub-pixel 12 is 765.23 μm². Apparently, compared with using the circumscribed virtual parallelogram 30b of the second sub-pixel 12 as the opening region of the sub-pixel, the opening region spacing between the first sub-pixel 11 and the second sub-pixel 12 in the direction S2 increases by 14.45%, where 14.45%=(22.89−20)/20. The opening ratio of the opening region of the second sub-pixel 12 is lost by 4.35%, where 4.35%=(800−765.23)/800.

In scheme 2, if the opening region of the second sub-pixel 12 is formed by chamfering the circumscribed virtual parallelogram 30b of the second sub-pixel 12 with an inscribed circle of a radius of R (R is less than half of the side length La2 of the circumscribed virtual parallelogram 30 b) and R=9 μm, then a spacing Ba between the opening region of the second sub-pixel 12 and the circumscribed virtual parallelogram 30a of the first sub-pixel 11 in the direction S2 is 23.73 μm, and an opening region area of the second sub-pixel 12 is 751.38 μm², where 751.38 μm²=Sg−2*Sf, Sf=6.7 μm². Apparently, when the opening area of the sub-pixel is formed by chamfering the circumscribed virtual parallelogram 30b with R=9 μm, an opening ratio of the opening region of the first sub-pixel 11 and the second sub-pixel 12 in the direction S2 is lost by 6.07%, where 6.07%=(800−751.38)/800.

It can be seen that, compared with the scheme 1 (B1=20 μm and the opening area is 800 μm²), in the embodiment of the present disclosure, the sub-pixel spacing B2 is 22.89 μm, and the opening ratio is lost by 4.35%. Compared with the scheme 1, in the scheme 2, the sub-pixel spacing Ba is 23.73 μm, and the opening ratio is lost by 6.07%. Compared the embodiment of the present disclosure with the scheme 2, the opening region spacing of adjacent sub-pixel is lost, but the opening ratio is not lost much. In an embodiment, a gain of 22.5% caused by a decrease in the opening region spacing is lost, where 22.5%=(23.73−22.89)/(23.73−20), but compensation of 39.5% for the loss of the opening ratio is obtained, where 39.5%=(6.07%−4.35%)/4.35%. That is, compared with the scheme 2, in the embodiment of the present disclosure, a larger opening ratio compensation can be obtained with a smaller opening region spacing loss gain.

In an embodiment, a ratio of the first distance to the length of the first virtual side in the first sub-pixel is not equal to a ratio of the first distance to the length of the first virtual side in the second sub-pixel.

When the first sub-pixel 11 and the second sub-pixel 12 in the display panel are configured with different colors, an area of the first sub-pixel 11 and an area of the second sub-pixel 12 are generally different since the efficiency and life of light-emitting materials of different colors are different. Therefore, a length of the first virtual side in the first sub-pixel 11 is not equal to a length of the first virtual side in the second sub-pixel 12. When the first sub-pixel 11 and the second sub-pixel 12 are designed, a first distance in the first sub-pixel 11 may be equal to or not equal to a first distance in the second sub-pixel 12. Based on this, in the design of the sub-pixel, the ratio of the first distance to the length of the first virtual side in the first sub-pixel 11 is not equal to the ratio of the first distance to the length of the first virtual side in the second sub-pixel 12, and a dimension of the first distance to the first virtual side in each sub-pixel can be flexibly designed.

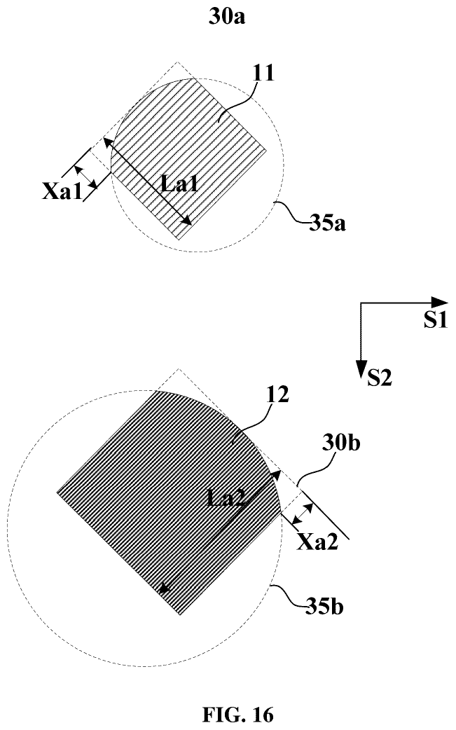

FIG. 16 is another schematic diagram of a first sub-pixel and a second sub-pixel adjacent to each other in a direction S2 according to an embodiment of the present disclosure. As shown in FIG. 16, in an embodiment, a first distance Xa1 in the first sub-pixel 11 may be equal to a first distance Xa2 in the second sub-pixel 12. Since a length La1 of the first virtual side in the first sub-pixel 11 is not equal to a length La2 of the first virtual side in the second sub-pixel 12, Xa1/La1 in the first sub-pixel 11 is not equal to Xa2/La2 in the second sub-pixel 12.

However, it should be understood that, in the case of the requirement of the product, the ratio of the first distance to the length of the first virtual side in the first sub-pixel may also be equal to the ratio of the first distance to the length of the first virtual side in the second sub-pixel.

In an embodiment, the first sub-pixel 11 is configured to be red, the second sub-pixel 12 is configured to be blue, and a ratio of the first distance Xa1 to the length La1 of the first virtual side in the first sub-pixel 11 is greater than a ratio of the first distance Xa2 to the length La2 of the first virtual side in the second sub-pixel 12.

In the embodiment of the present application, the first sub-pixel 11 is a red sub-pixel, and the second sub-pixel 12 is a blue sub-pixel. In the display panel, the difference of the light-emitting materials of the sub-pixels with different colors causes the light-emitting life to be different, where a life of the blue sub-pixel is shorter than a life of the red sub-pixel. To improve the life of the blue sub-pixel, an area of the blue sub-pixel is generally designed to be greater than an area of the red sub-pixel. Therefore, a length La1 of the first virtual side in the first sub-pixel 11 is less than a length La2 of the first virtual side in the second sub-pixel 12.

Referring to FIG. 16, in an embodiment, the first distance Xa1 in the first sub-pixel 11 may be equal to the first distance Xa2 in the second sub-pixel 12. Since the area of the red sub-pixel is smaller and the area of a blue sub-pixel is larger, a virtual circle 35a of the first sub-pixel 11 is less than a virtual circle 35b of the second sub-pixel 12. Correspondingly, an opening area of the first sub-pixel 11 is less than an opening area of the second sub-pixel 12. Therefore, the ratio of the first distance Xa1 to the length La1 of the first virtual side in the first sub-pixel 11 is greater than the ratio of the first distance Xa2 to the length La2 of the first virtual side in the second sub-pixel 12.

In an embodiment, a range of Xa1/La1 of the red sub-pixel is 5%˜30%, and exemplarily, Xa1/La1=23%. In an embodiment, a range of Xa2/La2 of the blue sub-pixel is 5%˜30%, and exemplarily, Xa2/La2=16%, but is not limited thereto.

In an embodiment, the first distance Xa1 in the first sub-pixel 11 is equal to the first distance Xa2 in the second sub-pixel 12. Since the area of the red sub-pixel is smaller and the area of the blue sub-pixel is larger, when Xa1 is equal to Xa2, the virtual circle 35a of the first sub-pixel 11 is less than the virtual circle 35b of the second sub-pixel 12, and correspondingly, the opening area of the first sub-pixel 11 is less than the opening area of the second sub-pixel 12.

In an embodiment, Xa=Xb. For the first sub-pixel 11, in an embodiment, a vertical distance Xa between an intersection point of the first side and the first sub-segment and the third virtual side is equal to a vertical distance Xb between an intersection point of the second side and the second sub-segment and the third virtual side. For the second sub-pixel 12, in an embodiment, the vertical distance Xa between the intersection point of the first side and the first sub-segment and the third virtual side is equal to the vertical distance Xb between the intersection point of the second side and the second sub-segment and the third virtual side.

It should be understood that for the first sub-pixel 11, Xa and Xb may be designed in a differentiated manner to adjust relevant parameters such as radians and lengths of the first sub-segment and the second sub-segment, and the Xa and the Xb are designed reasonably based on the display requirements; and Xa may be designed to be equal to Xb so that the radians, the lengths and the like of the first sub-segment and the second sub-segment are similar, which facilitates the design. Similarly, Xa and Xb of the second sub-pixel 12 may be designed in a differentiated manner, or Xa corresponding to the second sub-pixel 12 is designed to be equal to Xb.

Exemplarily, in the display panel of an electronic device such as a mobile phone, a La of the red sub-pixel may be designed to be 15.2 μm. On this basis, both Xa and Xb of the red sub-pixel may be designed to be 3.5 μm, a radius of a virtual circle of the red sub-pixel may be 10 μm, and a La of the blue sub-pixel may be designed to be 22.4 μm. On this basis, Xa and Xb of the blue sub-pixel may be designed to be 3.5 μm, and a radius of the virtual circle of the blue sub-pixel may be 19.67 μm.

In an embodiment, the first sub-segment is connected to the second sub-segment, a connection point between the first sub-segment and the second sub-segment is located on the third virtual side, and each of the first sub-segment and the second sub-segment is a straight line segment.

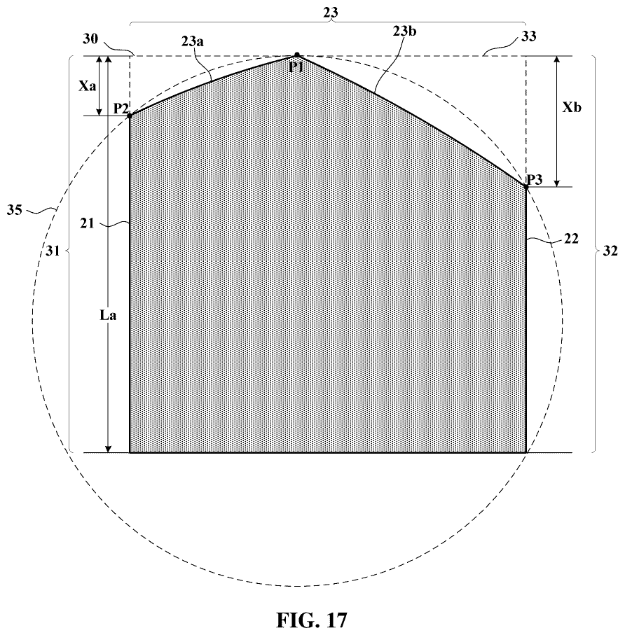

FIG. 17 is a schematic diagram of another sub-pixel according to an embodiment of the present disclosure. As shown in FIG. 17, the third side 23 of the sub-pixel includes only a first sub-segment 23a and a second sub-segment 23b, and each of the first sub-segment 23a and the second sub-segment 23b is a straight line segment. The first sub-segment 23a is connected to the second sub-segment 23b, and a connection point P1 of the first sub-segment 23a and the second sub-segment 23b is located on the third virtual side 33. The third side 23 of the sub-pixel includes two straight line segments. Therefore, a sub-segment (the first sub-segment 23a and the second sub-segment 23b) of the third side 23 of the sub-pixel is opposite to a top angle of an adjacent sub-pixel. With reference to the shape of the circumscribed virtual parallelogram 30, the sub-segment of the third side 23 may be considered as being formed by cutting two adjacent corners of the circumscribed virtual parallelogram 30 to form the third side 23 of the sub-pixel. For the first sub-pixel and the second sub-pixel adjacent to each other, a cut angle of the third side of the first sub-pixel may be opposite to a top angle of an adjacent second sub-pixel. On the basis of ensuring a relatively large opening ratio, a distance between the opening area of the first sub-pixel and the opening area of the adjacent second sub-pixel can be increased, the problem of sneaking light is improved, and thus the display effect is improved.

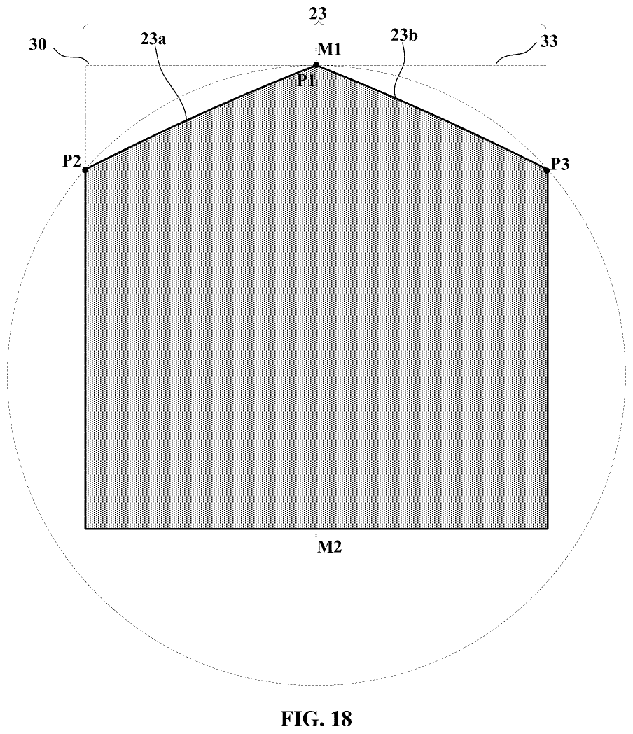

FIG. 18 is a schematic diagram of another sub-pixel according to an embodiment of the present disclosure. The difference from FIG. 17 is that P1 may overlap with the midpoint of the third virtual side 33, a symmetric axis M1-M2 of the circumscribed virtual parallelogram 30 passes through the midpoint of the third virtual side 33, and an opening shape of the sub-pixel may be symmetrical about the symmetric axis M1-M2.

In an embodiment, the third side further includes a third sub-segment connected to the first sub-segment and the second sub-segment on the same side of the first sub-segment and the second sub-segment, and the third sub-segment is a straight line segment and partially coincides with the third virtual side. In an embodiment, each of the first sub-segment and the second sub-segment is an arc segment. In an embodiment, a length of the first sub-segment is equal to a length of the second sub-segment.

FIG. 19 is a schematic diagram of another sub-pixel according to an embodiment of the present disclosure. As shown in FIG. 19, the third side 23 of the sub-pixel includes a first sub-segment 23a, a second sub-segment 23b, and a third sub-segment 23c that is connected to the first sub-segment 23a and the second sub-segment 23b, and the third sub-segment 23c is a straight line segment. In an embodiment, each of the first sub-segment 23a and the second sub-segment 23b is an arc segment. A point P21 is selected on the first virtual side 31 of the circumscribed virtual parallelogram 30, a point P24 is selected on the second virtual side 32 of the circumscribed virtual parallelogram 30, and points P22 and P23 are selected on the third virtual side 33 of the circumscribed virtual parallelogram 30. A unique virtual circle 35 may be determined according to the points P21, P22, P23, and P24. The arc segment of P21 to P22 on the circumference of the virtual circle 35 is determined as the first sub-segment 23a, the arc segment of P23 to P24 on the circumference of the virtual circle 35 is determined as the second sub-segment 23b, and the straight line segment of P22 to P23 is determined as the third sub-segment 23c, based on this, the third side 23 of the sub-pixel may be determined. The third sub-segment 23c is located on the third virtual side 23.

A radius of curvature of the first sub-segment 23a may be designed to be equal to a radius of curvature of the second sub-segment 23b, or the length of the arc segment of the first sub-segment 23a is designed to be equal to the length of the arc segment of the second sub-segment 23b, which is not limited thereto. According to the display requirements, curvature radiuses and arc segment lengths of the first sub-segment 23a and the second sub-segment 23b may be flexibly designed, and the curvature radius of the first sub-segment 23a and the curvature radius of the second sub-segment 23b may be equal or may be designed in a differentiated manner, and the arc segment length of the first sub-segment 23a and the arc segment length of the second sub-segment 23b may be equal or may be designed in a differentiated manner. The first sub-segment 23a and the second sub-segment 23b in the third side 23 are designed to be the arc segment, which facilitates increasing the opening ratio.

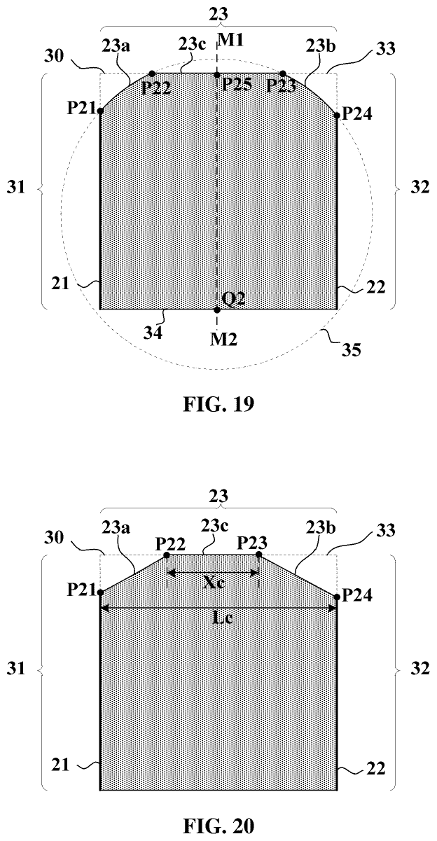

In an embodiment, each of the first sub-segment and the second sub-segment is a straight line segment. FIG. 20 is a schematic diagram of another sub-pixel according to an embodiment of the present disclosure. The difference from FIG. 19 is that, in FIG. 20, each of the first sub-segment 23a and the second sub-segment 23b is a straight line segment. A point P21 is selected on the first virtual side 31 of the circumscribed virtual parallelogram 30, a point P24 is selected on the second virtual side 32 of the circumscribed virtual parallelogram 30, and points P22 and P23 are selected on the third virtual side 33 of the circumscribed virtual parallelogram 30. A straight line segment of the points P21 to P22 is determined as the first sub-segment 23a, a straight line segment of the points P22 to P23 is determined as the third sub-segment 23c, and a straight line segment of the points P23 to P24 is determined as the second sub-segment 23b. Based on this, the third side 23 of the sub-pixel may be determined. The third sub-segment 23c is located on the third virtual side 23.

A straight line segment length of the first sub-segment 23a may be designed to be equal to a straight line segment length of the second sub-segment 23b, and/or an included angle between the first sub-segment 23a and the first side 21 and towards the second side 22 is designed to be equal to an included angle between the second sub-segment 23b and the second side 22 and towards the first side 21, which is not limited thereto. According to the display requirements, slopes and straight line segment lengths of the first sub-segment 23a and the second sub-segment 23b may be flexibly designed. The slope of the first sub-segment 23a and the slope of the second sub-segment 23b may be equal or may be designed in a differentiated manner, and the straight line segment length of the first sub-segment 23a and the straight line segment length of the second sub-segment 23b may be equal or may be designed in a differentiated manner.

In other embodiments, in an embodiment, any one of the first sub-segment or the second sub-segment may be an arc segment, and the other of the first sub-segment or the second sub-segment is a straight line segment.

The third sub-segment 23c partially coincides with the third virtual side 33. In an embodiment, all points of the third sub-segment 23c may be located on the third virtual side 33, so that a partial straight line segment of the third virtual side 33 completely coincides with the third sub-segment 23c, but is not limited thereto. With reference to the shape of the circumscribed virtual parallelogram 30, the first sub-segment 23a and the second sub-segment 23b of the third side 23 may be considered as being formed by performing chamfering or cutting on two adjacent corners of the circumscribed virtual parallelogram 30. On the basis of ensuring a relatively large opening ratio, the distance between the opening area of the first sub-pixel and the opening area of the adjacent second sub-pixel can be increased, the problem of sneaking light is improved, and thus the display effect is improved.

In an embodiment, the circumscribed virtual parallelogram includes a first virtual axis, a center of the circumscribed virtual parallelogram is located on the first virtual axis, the first virtual axis intersects with the third sub-segment, and a midpoint of the third sub-segment is not located on the first virtual axis.

FIG. 21 is a schematic diagram of another sub-pixel according to an embodiment of the present disclosure. As shown in FIG. 21, the circumscribed virtual parallelogram 30 of the sub-pixel includes a first virtual axis M1-M2, a midpoint Q1 of the third virtual side 23 and a midpoint Q2 of the fourth virtual side 34 are both located on the first virtual axis M1-M2, and a center Pa, that is, a geometric center of the circumscribed virtual parallelogram 30, is also located on the first virtual axis M1-M2. On this basis, the first virtual axis M1-M2 intersects with the third sub-segment 23c, and a midpoint P25 of the third sub-segment 23c is not located on the first virtual axis M1-M2. That is, the third sub-segment 23c is asymmetric about the first virtual axis M1-M2, and the first sub-segment 23a and the second sub-segment 23b that are connected to the third sub-segment 23c are located on two sides of the first virtual axis M1-M2. In this way, parameters such as a curvature radius, a slope, or a length of the first sub-segment 11d and the second sub-segment 11e may be flexibly designed.

In an embodiment, the circumscribed virtual parallelogram includes a first virtual axis, a center of the circumscribed virtual parallelogram is located on the first virtual axis, and the midpoint of the third sub-segment is located on the first virtual axis.

Referring to FIG. 19, the difference from FIG. 21 is that, in FIG. 19, the first virtual axis M1-M2 intersects with the third sub-segment 23c, and the midpoint P25 of the third sub-segment 23c is located on the first virtual axis M1-M2. If the shape of the circumscribed virtual parallelogram 30 is a square, then the third sub-segment 23c may be symmetrical about the first virtual axis M1-M2. In this case, the first sub-segment 23a and the second sub-segment 23b may also be symmetrical about the first virtual axis M1-M2, but are not limited thereto.

In an embodiment, the circumscribed virtual parallelogram includes a first virtual axis, a center of the circumscribed virtual parallelogram is located on the first virtual axis, the first virtual axis intersects with the third sub-segment, and the first sub-segment and the second sub-segment are symmetrical about the first virtual axis.

As shown in FIG. 19, the first sub-segment 23a and the second sub-segment 23b may form a symmetric structure about the first virtual axis M1-M2. Exemplarily, the first sub-segment 23a and the second sub-segment 23b may be the same arc segment and are symmetrically distributed on two sides of the first virtual axis M1-M2. However, this is not limited thereto, the first sub-segment and the second sub-segment may be the same straight line segment, and are symmetrically distributed on two sides of the first virtual axis.

Based on the structure of the sub-pixel described above, FIG. 22 is a schematic diagram of another display panel according to an embodiment of the present disclosure. As shown in FIG. 22, a shape of the first sub-pixel 11 is shown with reference to FIG. 19, and a shape of the second sub-pixel 12 is shown with reference to FIG. 19. The third side of any one of the first sub-pixel 11 or the second sub-pixel 12 includes a first sub-segment 23a, a second sub-segment 23b, and a third sub-segment 23c between the first sub-segment 23a and the second sub-segment 23b.

In an embodiment, Xc≤Lc/2, where Xc denotes a length of the third sub-segment, and Lc denotes a length of the third virtual side.

Referring to FIG. 20, a length of the third sub-segment 23c of the sub-pixel is Xc, a length of the third virtual side 33 of the circumscribed virtual parallelogram 30 of the sub-pixel is Lc, and 2*Xc is designed to be less than or equal to Lc. The length of the third sub-segment 23c is adjusted by reasonably selecting the points P22 and P23 on the third virtual side 33 of the circumscribed virtual parallelogram 30 so that the size of the virtual circle determined by the points P21, P22, P23 and P24 changes and further the opening ratio of the sub-pixel is adjusted.

In an embodiment, a ratio of the length of the third sub-segment to the length of the third virtual side is 0% to 50%. A length ratio of the third sub-segment to the corresponding third virtual side may be 0%, that is, the third side may include only the first sub-segment and the second sub-segment. The length ratio of the third sub-segment to the corresponding third virtual side may be greater than 0%. In this case, the third side further includes a third sub-segment located between the first sub-segment and the second sub-segment. The length of the third sub-segment and positions of the points P21, P22, P23, and P24 are properly designed, so that a size of a virtual circle determined by the points P21, P22, P23, and P24 changes, and further the opening ratio of the sub-pixel can be adjusted, whereby the effect of increasing the distance between the opening region of the first sub-pixel and the opening region of the adjacent second sub-pixel can be achieved on the basis of a relatively large opening ratio, thereby improving the display effect.

In an embodiment, a ratio of the length of the third sub-segment to the length of the third virtual side is 5% to 40%. If the length ratio of the third sub-segment to the corresponding third virtual side is greater than 0%, then the third side includes the third sub-segment. In this case, the third side is formed by performing cutting or chamfering on the sub-pixel, which ensures a relatively large opening ratio, and can also achieve the effect of increasing the distance between the opening region of the first sub-pixel and the opening region of the adjacent second sub-pixel.

In an embodiment, a ratio of the length of the third sub-segment to the length of the third virtual side in the first sub-pixel is not equal to a ratio of the length of the third sub-segment to the length of the third virtual side in the second sub-pixel.

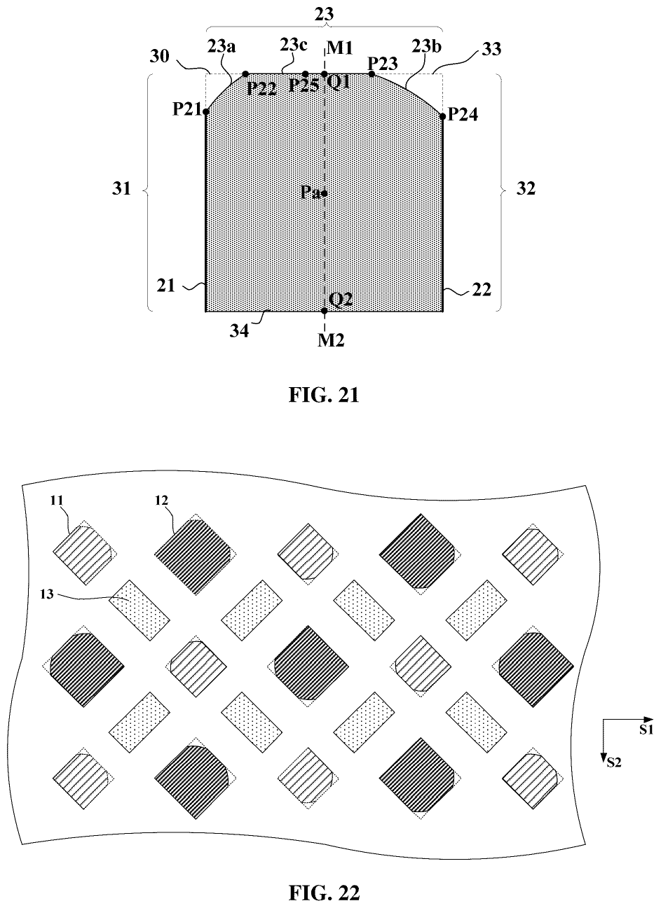

FIG. 23 is another schematic diagram of a first sub-pixel and a second sub-pixel adjacent to each other in a direction S2 according to an embodiment of the present disclosure. Referring to FIG. 23, Xc1/Lc1≠Xc2/Lc2 is designed, where Xc1 is a length of the third sub-segment of the first sub-pixel 11, Lc1 is a length of the third virtual side of the circumscribed virtual parallelogram 30a corresponding to the first sub-pixel 11, Xc2 is a length of the third sub-segment of the second sub-pixel 12, and Lc2 is a length of the third virtual side of the circumscribed virtual parallelogram 30b corresponding to the second sub-pixel 12. Dimensions of different sub-pixels in the display panel may be different. In an embodiment, the first sub-pixel 11 and the second sub-pixel 12 are sub-pixels with different colors. Therefore, the length Lc1 of the third virtual side of the circumscribed virtual parallelogram 30a corresponding to the first sub-pixel 11 may be different from the length Lc2 of the third virtual side of the circumscribed virtual parallelogram 30b corresponding to the second sub-pixel 12. A virtual circle radius corresponding to the first sub-pixel 11 is different from a virtual circle radius corresponding to the second sub-pixel 12. Correspondingly, an opening area of the first sub-pixel 11 is different from an opening area of the second sub-pixel 12, and Xc1/Lc1≠Xc2/Lc2.

In an embodiment, the first sub-pixel is configured to be red, the second sub-pixel is configured to be blue, and the ratio of the length of the third sub-segment to the length of the third virtual side in the first sub-pixel is less than the ratio of the length of the third sub-segment to the length of the third virtual side in the second sub-pixel.

Referring to FIG. 23, Xc1/Lc1<Xc2/Lc2 is designed. The display panel generally includes a blue sub-pixel and a red sub-pixel. A life of the blue sub-pixel is shorter than a life of the red sub-pixel. Therefore, an area of the blue sub-pixel is designed to be greater than an area of the red sub-pixel to compensate for the life difference. The first sub-pixel 11 is the red sub-pixel, the second sub-pixel 12 is the blue sub-pixel, and a dimension of the red sub-pixel is generally less than a dimension of the blue sub-pixel. Therefore, the length Lc1 of the third virtual side of the first sub-pixel 11 configured to be red is less than the length Lc2 of the third virtual side of the second sub-pixel 12 configured to be blue. When the first sub-pixel 11 and the second sub-pixel 12 are designed, the third sub-segment length Xc1 in the first sub-pixel 11 is equal to the third sub-segment length Xc2 in the second sub-pixel 12. Based on this, a ratio (Xc1/Lc1) of a length of the third sub-segment to a length of the third virtual side in the first sub-pixel 11 configured to be red is less than a ratio (Xc2/Lc2) of a length of the third sub-segment to a length of the third virtual side in the second sub-pixel 12. Exemplarily, Xc1/Lc1 of the first sub-pixel 11 configured to be red is equal to 26%, and Xc2/Lc2 of the second sub-pixel 12 configured to be blue is equal to 27%.

In an embodiment, the first sub-pixel, the second sub-pixel and the third sub-pixel are one of a red sub-pixel, a blue sub-pixel, and a green sub-pixel, respectively and are different from each other.

Referring to FIG. 1, in an embodiment, the first sub-pixel 11 is a red sub-pixel, the second sub-pixel 12 is a blue sub-pixel, and the third sub-pixel 13 is a green sub-pixel. Lines connecting the centers of gravity of two red sub-pixels and the centers of gravity of two blue sub-pixels arranged adjacent to each other in the 2*2 manner form a first virtual quadrilateral 14, and lines connecting the centers of gravity of four green sub-pixels arranged adjacent to each other in the 2*2 manner form a second virtual quadrilateral 15. For the first virtual quadrilateral 14, the green sub-pixel may be mixed with the adjacent red and blue sub-pixels in the first virtual quadrilateral 14 so as to improve the display effect.

In an embodiment, a center of gravity of the first virtual quadrilateral does not overlap with the center of gravity of the third sub-pixel located inside the first virtual quadrilateral.

Referring to FIG. 1, a center of gravity of the first virtual quadrilateral 14 is Pd, a center of gravity of the third sub-pixel 13 is Pb13, and the center of gravity of the first virtual quadrilateral 14 does not overlap with the center of gravity of the third sub-pixel 13 located inside the first virtual quadrilateral 14. The display panel has a color edge effect when displaying the image, that is, the edge of the display image tends to have a clear color stripe that deviates from the original image. In an embodiment, when the image edge includes the red sub-pixel and the blue sub-pixel arranged in sequence, the red sub-pixel and the blue sub-pixel are mixed to easily form a magenta color edge. When the image edge includes green sub-pixels arranged in sequence, a green color edge is easily formed.

In the embodiment of the present application, if the center of gravity Pd of the first virtual quadrilateral 14 does not overlap with the center of gravity Pb13 of the third sub-pixel 13 located inside the first virtual quadrilateral 14, then a position of each first sub-pixel 11 and a position of each second sub-pixel 12 at a vertex position of the first virtual quadrilateral 14 may be flexibly adjusted. When a display region edge includes the first sub-pixel 11 and the second sub-pixel 12 that are arranged alternately, a position of the first sub-pixel 11 and/or a position of the second sub-pixel 12 may be adjusted so that a center of gravity Pb11 of the first sub-pixel 11 and a center of gravity Pb12 of the second sub-pixel 12 in the display region edge are not located on one straight line, and a sensitivity of the human eye to a row (or a column) formed by the first sub-pixel 11 and the second sub-pixel 12 in the display region edge is reduced, thereby weakening the magenta color edge effect.

In an embodiment, a center of gravity of the second virtual quadrilateral does not overlap with the center of gravity of the first sub-pixel located inside the second virtual quadrilateral, or a center of gravity of the second virtual quadrilateral does not overlap with the center of gravity of the second sub-pixel located inside the second virtual quadrilateral.

Referring to FIG. 1, the center of gravity of the second virtual quadrilateral 15 is Pe, the center of gravity of the first sub-pixel 11 is Pb11, and the center of gravity of the second sub-pixel 12 is Pb12. When the sub-pixel located inside the second virtual quadrilateral 15 is the first sub-pixel 11, the center of gravity Pe of the second virtual quadrilateral 15 does not overlap with the center of gravity Pb11 of the first sub-pixel 11 located inside the second virtual quadrilateral 15. When the sub-pixel located inside the second virtual quadrilateral 15 is the second sub-pixel 12, the center of gravity Pe of the second virtual quadrilateral 15 does not overlap with the center of gravity Pb12 of the second sub-pixel 12 located inside the second virtual quadrilateral 15.

In the embodiment of the present application, if the center of gravity Pe of the second virtual quadrilateral 15 does not overlap with the center of gravity of the sub-pixel located inside the second virtual quadrilateral 15, then a position of each third sub-pixel 13 at a vertex position of the second virtual quadrilateral 15 may be flexibly adjusted. When the display region edge includes the third sub-pixel 13, a position of the third sub-pixel 13 may be adjusted, so that the third sub-pixel 13 of the display region edge is close to the first sub-pixel 11 and the second sub-pixel 12 adjacent to each other, which is conducive to the mixed display of the third sub-pixel 13 of the display region edge with the first sub-pixel 11 and the second sub-pixel 12 adjacent to each other, thereby weakening the green color edge effect of the third sub-pixel 13 in the display region edge. In addition, adjusting the position of the third sub-pixel 13 in the display region edge can also reduce a sensitivity of the human eye to a row (or a column) formed by the third sub-pixel 13 in the display region edge, thereby weakening the green color edge effect.

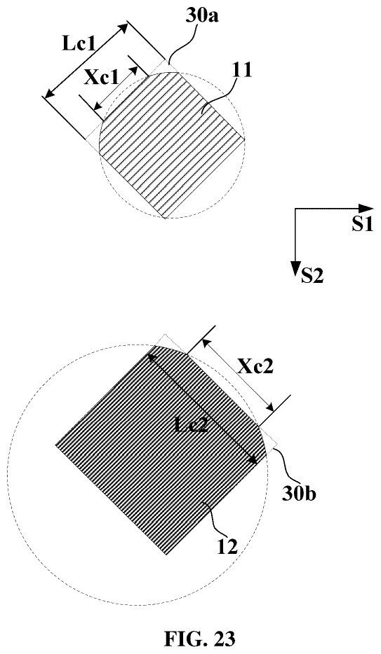

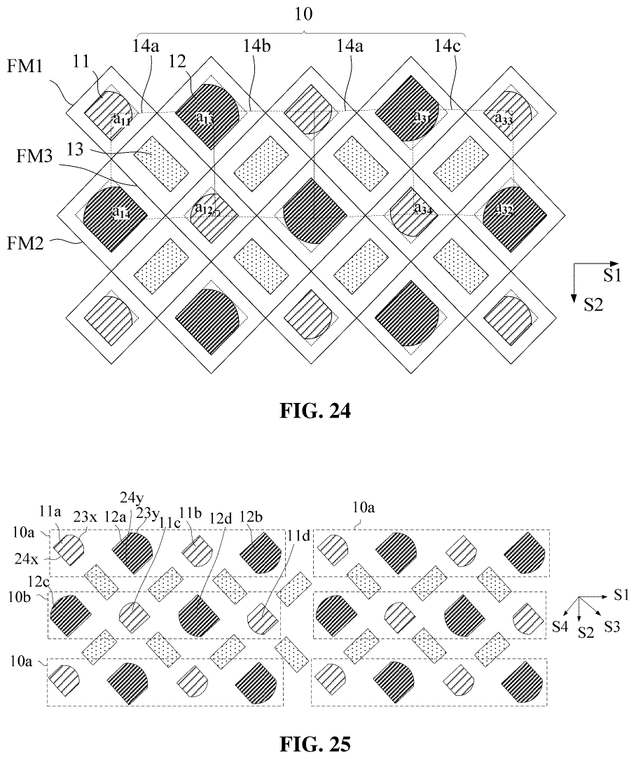

FIG. 24 is a schematic diagram of another display panel according to an embodiment of the present disclosure. As shown in FIG. 24, in an embodiment, the first sub-pixel 11 and the second sub-pixel 12 may be arranged alternately in the first direction S1 and the second direction S2, and the first direction S1 intersects with the second direction S2. The display panel further includes multiple first groups 10, the first group 10 includes four first virtual quadrilaterals 14 arranged in the first direction S1, and adjacent first virtual quadrilaterals 14 have a common edge. The four first virtual quadrilateral 14 in the first group 10 at least includes one of a first-type virtual quadrilateral 14a, a second-type virtual quadrilateral 14b, or a third-type virtual quadrilateral 14c. At least one interior angle of the first-type virtual quadrilateral 14a is not equal to 90°, and angles of two opposite interior angles of the first-type virtual quadrilateral 14a are not equal. At least one interior angle of the second-type virtual quadrilateral 14b is equal to 90°. At least one interior angle of the third-type virtual quadrilateral 14c is not equal to 90°, and angles of any two opposite interior angles of the third-type virtual quadrilateral 14c are equal. In an embodiment, the four first virtual quadrilateral 14 in the first group 10 includes two first-type virtual quadrilateral 14a, one second-type virtual quadrilateral 14b, and one third-type virtual quadrilateral 14c, and an arrangement order in the first direction S1 is the first-type virtual quadrilateral 14a, the second-type virtual quadrilateral 14b, the first-type virtual quadrilateral 14a, and the third-type virtual quadrilateral 14c.

It should be noted that referring to FIG. 5, in FIG. 24, a black solid frame FM1 represents a setting range of a light-emitting layer of the first sub-pixel 11, a black solid frame FM2 represents a setting range of a light-emitting layer of the second sub-pixel 12, and a black solid frame FM3 represents a setting range of a light-emitting layer of the first sub-pixel 13. To highlight the opening conditions of different sub-pixels, the setting range of the light-emitting layer of the sub-pixel is shown by using the black solid frame. It should be understood that light-emitting layers of different colors of adjacent sub-pixels may partially overlap or may not overlap. FIG. 24 is only an example. The same reference numeral represents the same structure, and the description of the similar parts is omitted.

In the embodiment of the present application, the directions in which the first sub-pixel 11 and the second sub-pixel 12 are arranged alternately include the first direction S1 and the second direction S2, the first direction S1 intersects with the second direction S2, and an included angle between the first direction S1 and the second direction S2 may be equal to 90° or may not be equal to 90°. In the direction S1, the first sub-pixel 11 and the second sub-pixel 12 are arranged alternately; and in the direction S2, the first sub-pixel 11 and the second sub-pixel 12 are arranged alternately.

Sub-pixels of the display panel are divided into multiple first groups 10. The first group 10 specifically includes five first sub-pixels 11 and five second sub-pixels 12, and the ten sub-pixels are arranged in a 2*5 manner. In an embodiment, the ten sub-pixels of the first group 10 constitute four first virtual quadrilaterals 14 arranged in sequence in the direction S1, and two adjacent first virtual quadrilateral 14 share one first sub-pixel 11 and a second sub-pixel 12 together. Therefore, the two adjacent first virtual quadrilaterals 14 have a common edge.

The four first virtual quadrilaterals 14 in the first group 10 may be at least one of the first-type virtual quadrilateral 14a, the second-type virtual quadrilateral 14b, or the third-type virtual quadrilateral 14c according to the shape. Exemplarily, the four first virtual quadrilaterals 14 in the first group 10 may be the same, or may be all the first-type virtual quadrilateral 14a, or the second-type virtual quadrilateral 14b, or the third-type virtual quadrilateral 14c. The four first virtual quadrilaterals 14 in the first group 10 may also be different, and may be at least two of the first-type virtual quadrilateral 14a, the second-type virtual quadrilateral 14b, and the third-type virtual quadrilateral 14c. It should be noted that, since a shape, an offset, and the like of the sub-pixel changes, two different first virtual quadrilaterals 14 in the first groups 10 may be different or may be the same.

In the first-type virtual quadrilateral 14a formed by arranging two first sub-pixels 11 and two second sub-pixels 12, at least one interior angle of the first-type virtual quadrilateral 14a is not equal to 90°, and angles of two opposite interior angles of the first-type virtual quadrilateral 14a are not equal.

In the second-type virtual quadrilateral 14b formed by arranging two first sub-pixels 11 and two second sub-pixels 12, at least one interior angle of the second-type virtual quadrilateral 14b is equal to 90°, and angles of the two opposite interior angles of the second-type virtual quadrilateral 14b may be equal or not equal.

In the third-type virtual quadrilateral 14c formed by arranging two first sub-pixels 11 and two second sub-pixels 12, at least one interior angle of the third-type virtual quadrilateral 14c is not equal to 90°, and angles of any two opposite interior angles of the third-type virtual quadrilateral 14c are equal.

The four first virtual quadrilateral 14 in the first group 10 includes two first-type virtual quadrilateral 14a, one second-type virtual quadrilateral 14b, and one third-type virtual quadrilateral 14c, and the arrangement order in the first direction S1 is the first-type virtual quadrilateral 14a, the second-type virtual quadrilateral 14b, the first-type virtual quadrilateral 14a, and the third-type virtual quadrilateral 14c. However, it should be understood that, after positions of the first sub-pixel 11, the second sub-pixel 12 and the third sub-pixel 13 are offset and adjusted, a type and/or sorting of the first virtual quadrilateral 14 in the first group 10 may also be correspondingly changed, and a specific example is not further provided.

As described above, the two first sub-pixels 11 and the two second sub-pixels 12 form one first virtual quadrilateral 14, and when positions of the at least one first sub-pixel 11 and/or the at least one second sub-pixel 12 are offset, types of the formed first virtual quadrilateral 14 are different. Positions of the first sub-pixel 11 and/or the second sub-pixel 12 are adjusted to form different types of first virtual quadrilaterals 14. In the different types of first virtual quadrilaterals 14, the color mixing effects of the third sub-pixel 13, the first sub-pixel 11 adjacent to the third sub-pixel 13 and the second sub-pixel 12 adjacent to the third sub-pixel 13 are different. Therefore, the positions of the first sub-pixel 11 and/or the second sub-pixel 12 are adjusted so as to facilitate adjusting the color mixing effect, improve the color deviation, and thus improve the display effect. In particular, for a condition that the first sub-pixel 11 and the second sub-pixel 12 are located on the display region edge, the positions of the first sub-pixel 11 and/or the second sub-pixel 12 may be adjusted so as to weaken the color edge phenomenon of the display region edge.

It should be noted that, two first-type virtual quadrilaterals 14a in the first group 10 may overlap in a plane in at least one manner such as rotation, translation, or mirroring. Exemplarily, the two first-type virtual quadrilaterals 14a in the first group 10 may overlap in a plane in a manner of rotation and translation. For example, after a first first-type virtual quadrilateral 14a rotates 180° clockwise, the first first-type virtual quadrilateral 14a translates in the direction S1, so that the first first-type virtual quadrilateral 14a may overlap with a second first-type virtual quadrilateral 14a.

In other embodiments, the two first-type virtual quadrilaterals 14a in the first group 10 may overlap in a plane in a manner of mirroring and translation. For example, after the first first-type virtual quadrilateral 14a is mirror-inverted with the direction S2 as an axis, the first first-type virtual quadrilateral 14a translates in the direction S1, so that the first first-type virtual quadrilateral 14a may overlap with the second first-type virtual quadrilateral 14a.

As shown in FIG. 24, in an embodiment, in the first-type virtual quadrilateral 14a, |α₁₁-90°|≤5°, α₁₂-90°|≤5°, |α₁₃-90°|≤5°, |α₁₄-90°|≤5°, where α₁₁ is an angle of an interior angle at which a first one of the first vertex is located, α₁₂ is an angle of an interior angle at which a second one of the first vertex is located, α₁₃ is an angle of an interior angle at which a first one of the second vertex is located, and α₁₄ is an angle of an interior angle at which a second one of the second vertex is located; and in the third-type virtual quadrilateral 14c, |α₃₁-90°|≤6°, |α₃₂-90°|≤6°, |α₃₃-90°|≤6°, |α₃₄-90°|≤6°, where α₃₁ is an angle of an interior angle at which a first one of the first vertex is located, α₃₂ is an angle of an interior angle at which a second one of the first vertex is located, α₃₃ is an angle of an interior angle at which a first one of the second vertex is located, and α₃₄ is an angle of an interior angle at which a second one of the second vertex is located. In an embodiment, in the first-type virtual quadrilateral 14a, |α₁₁-90°|≤2°, |α₁₂-90°|≤2°, |α₁₃-90°|≤2°, |α₁₄-90°|≤2°; and in the third-type virtual quadrilateral 14c, |α₃₁-90°|≤3°, |α₃₂-90°|≤3°, |α₃₃-90°|≤3°, |α₃₄-90°|≤3°. In an embodiment, in the first-type virtual quadrilateral 14a, 89°<α₁₁<90°, 89°<α₁₂<90°, 90°<α₁₃<91°, 90°<α₁₄<91°; and in the third-type virtual quadrilateral 14c, 88°<α₃₁<90°, 88°<α₃₂<90°, 90°<α₃₃<92°, 90°<α₃₄<92°.

In the embodiment of the present application, at least one interior angle of the first-type virtual quadrilateral 14a is not equal to 90°, and angles of two opposite interior angles are not equal. A shape of the first-type virtual quadrilateral 14a may be a nearly parallelogram but not the parallelogram. In an embodiment, angles of the two relative interior angles α₁₁ and α₁₂ are not equal, angles of the two relative interior angles α₁₃ and α₁₄ are not equal, at least one of α₁₁, α₁₂, α₁₃ or α₁₄ is not equal to 90°, and in an embodiment, α₁₁, α₁₂, α₁₃ and α₁₄ are not equal to 90°.

An angle range of α₁₁ satisfies 85°≤α_{11≤95}°, for example, may be 85°, 86°, 87°, 88°, 92°, 93° and the like. In an embodiment, the angle range of an satisfies 88°≤α₁₁≤92°, for example, may be 88.5, 89.2°, 90.4°, 91°, 91.8° and the like. In an embodiment, the angle range of α₁₁ satisfies 89°≤α≤90°, for example, may be 89.39° or 89.31°.

An angle range of α₁₂ satisfies 85°≤α_{12≤95}°, for example, may be 85°, 86°, 89°, 90°, 92°, 93° and the like. In an embodiment, the angle range of α₁₂ satisfies 88°≤α_{12≤92}°, for example, may be 88.7°, 89.0°, 90.9°, 91°, 91.9° and the like. In an embodiment, the angle range of α₁₂ satisfies 89°≤α₁₂≤90°, for example, may be 89.34°, 89.41° and the like. In addition, angles of an and α₁₂ are not equal.

An angle range of α₁₃ satisfies 85°≤α_{13≤95}°, for example, may be 85°, 86°, 89°, 90°, 92°, 93° and the like. In an embodiment, the angle range of α₁₃ satisfies 88°≤α₁₃≤92°, for example, may be 88.7°, 89.0°, 90.9°, 91°, 91.9° and the like. In an embodiment, the angle range of α₁₃ satisfies 90°≤α₁₃≤91°, for example, may be 90.61°, 90.69° and the like.

An angle range of α₁₄ satisfies 85°≤α_{14≤95}°, for example, may be 85°, 86°, 89°, 90°, 92°, 93° and the like. In an embodiment, the angle range of α₁₄ satisfies 88°≤α14≤92°, for example, may be 88.7°, 89.0°, 90.9°, 91, 91.9° and the like. In an embodiment, the angle range of α₁₄ satisfies 90°≤α₁₄≤91°, for example, may be 90.59°, 90.66° and the like. In addition, angles of α₁₃ and α₁₄ are not equal.

At least one interior angle of the third-type virtual quadrilateral 14c is not equal to 90°, angles of any two opposite interior angles are equal, and a shape of the third-type virtual quadrilateral 14c may be a rhombus. In an embodiment, angles of the two opposite interior angles, i.e., α₃₁ and α₃₂ are equal, and angles of the two opposite interior angles, i.e., α₃₃ and α₃₄ are equal. At least one of α₃₁, α₃₂, α₃₃ or α₃₄ is not equal to 90°, and in an embodiment, α₃₁, α₃₂, α₃₃ and α₃₄ are all not equal to 90°.

An angle range of α₃₁ satisfies 84°≤ α₃₁≤96°, for example, may be 84°, 86°, 87°, 88°, 92°, 96° and the like. In an embodiment, the angle range of α₃₁ satisfies 87°≤α₃₁≤93°, for example, may be 87.5°, 89.2°, 90.4°, 91°, 92.8° and the like. In an embodiment, the angle range of α₃₁ satisfies 88°≤α₃₁≤90°, for example, may be 88.8°, 88.65° and the like.

An angle range of α₃₂ satisfies 84°≤ α₃₂≤96°, for example, may be 84°, 86°, 89°, 90°, 92°, 96° and the like. Optional, the angle range of α₃₂ satisfies 87°≤α₃₂≤93°, for example, may be 87.7°, 89.0°, 90.9°, 91°, 92.9° and the like. In an embodiment, the angle range of α₃₂ satisfies 88°≤ α₃₂≤90°, for example, may be 88.8°, 88.65° and the like. In addition, angles of α₃₁ and α₃₂ are equal.

An angle range of α₃₃ satisfies 84°≤α₃₃≤96°, for example, may be 85°, 86°, 89°, 90°, 92°, 93° and the like. In an embodiment, an angle range of α₃₃ satisfies 87°≤α₃₃≤93°, for example, may be 88.7°, 89.0°, 90.9°, 91°, 91.9° and the like. In an embodiment, an angle range of α₃₃ satisfies 90°≤ α_{33≤92}°, for example, may be 91.2°, 91.35° and the like.

An angle range of α₃₄ satisfies 84°≤α₃₄≤96°, for example, may be 85°, 86°, 89°, 90°, 92°, 93° and the like. In an embodiment, the angle range of α₃₄ satisfies 87°≤α₃₄≤93°, for example, may be 88.7°, 89.0°, 90.9°, 91°, 91.9° and the like. In an embodiment, the angle range of α₃₄ satisfies 90°≤α₃₄≤92°, for example, may be 91.2°, 91.35° and the like. In addition, angles of α₃₃ and α₃₄ are equal.

At least one interior angle of the second-type virtual quadrilateral 14b is equal to 90°, and a shape of the second-type virtual quadrilateral 14b may be a square or nearly a square. In an embodiment, each interior angle of the second-type virtual quadrilateral 14b is 90°.

The arrangement manner of the sub-pixel described above is adopted, it can be ensured that each sub-pixel has a better arrangement, and no obvious hollow region exists. Therefore, a clear spacing gap can be effectively avoided, the space waste can be avoided, and the display effect of the display panel can be ensured. In addition, the arrangement manner of the sub-pixel described above is adopted, the positions of the first sub-pixel 11 and/or the second sub-pixel 12 are adjusted, so that the positions of the third sub-pixel 13 and the first sub-pixel 11 and the second sub-pixel 12 adjacent to each other in the first virtual quadrilateral 14 change, thereby adjusting the color mixing effect of the third sub-pixel 13, the first sub-pixel 11 adjacent to the third sub-pixel 13 and the second sub-pixel 12 adjacent to the third sub-pixel 13. Therefore, the adjustment of the positions of the first sub-pixel 11 and/or the second sub-pixel 12 facilitates adjusting the color mixing effect, improves the color deviation, and improves the display effect. In particular, for a condition that the first sub-pixel 11 and the second sub-pixel 12 are located at the display region edge, the positions of the first sub-pixel 11 and/or the second sub-pixel 12 are adjusted so as to weaken the color edge phenomenon of the display region edge.

In an embodiment, each of the first sub-pixel and the second sub-pixel further includes a fourth side opposite to the third side, and the fourth side is connected to the first side and the second side on the same side of the first side and the second side; the first sub-pixel and the second sub-pixel are arranged alternately in the first direction and the second direction, and the first direction intersects with the second direction; the first sub-pixel and the third sub-pixel are arranged alternately in a third direction and a fourth direction, the second sub-pixel and the third sub-pixel are arranged alternately in the third direction and the fourth direction, and the third direction intersects with the fourth direction; the third direction intersects with the first direction and the second direction, separately, and the fourth direction intersects with the first direction and the second direction, separately; the first sub-pixel includes a first first sub-pixel, a second first sub-pixel, a third first sub-pixel and a fourth first sub-pixel, the second sub-pixel includes a first second sub-pixel, a second second sub-pixel, a third second sub-pixel and a fourth second sub-pixel, the first first sub-pixel, the first second sub-pixel, the second first sub-pixel and the second second sub-pixel are arranged in the first direction to form a first sub-group, the third second sub-pixel, the third first sub-pixel, the fourth second sub-pixel and the fourth first sub-pixel are arranged in the first direction to form a second sub-group, and the first sub-group and the second sub-pixel are adjacent in the second direction; in the first first sub-pixel, the third side and the fourth side are arranged in the fourth direction, and a shortest distance between the third side and the first second sub-pixel is less than a shortest distance between the fourth side and the first second sub-pixel; in the first second sub-pixel, the third side and the fourth side are arranged in the fourth direction, and a shortest distance between the third side and the second first sub-pixel is less than a shortest distance between the fourth side and the second first sub-pixel; in the second first sub-pixel, the third side and the fourth side are arranged in the third direction, and a shortest distance between the third side and the second second sub-pixel is less than a shortest distance between the fourth side and the second second sub-pixel; in the second second sub-pixel, the third side and the fourth side are arranged in the third direction, and the shortest distance between the third side and the second first sub-pixel is greater than the shortest distance between the fourth side and the second first sub-pixel; in the third second sub-pixel, the third side and the fourth side are arranged in the third direction, and a shortest distance between the third side and the third first sub-pixel is greater than a shortest distance between the fourth side and the third first sub-pixel; in the third first sub-pixel, the third side and the fourth side are arranged in the third direction, and a shortest distance between the third side and the fourth second sub-pixel is greater than a shortest distance between the fourth side and the fourth second sub-pixel; in the fourth second sub-pixel, the third side and the fourth side are arranged in the fourth direction, and a shortest distance between the third side and the fourth first sub-pixel is greater than a shortest distance between the fourth side and the fourth first sub-pixel; and in the fourth first sub-pixel, the third side and the fourth side are arranged in the fourth direction, and the shortest distance between the third side and the fourth second sub-pixel is less than the shortest distance between the fourth side and the fourth second sub-pixel.

As shown in FIG. 2, the sub-pixel may be independently selected by the first sub-pixel and the second sub-pixel. The sub-pixel includes a fourth side 24 opposite to the third side 23, and the fourth side 24 is connected to the first side 21 and the second side 22 on the same side of the first side 21 and the second side 22. The circumscribed virtual parallelogram 30 corresponding to the sub-pixel includes a fourth virtual side 34, and the fourth virtual side 34 is connected to the first virtual side 31 and the second virtual side 32b on the same side of the first virtual side 31 and the second virtual side 32. It should be understood that it is only one case that the fourth edge of the sub-pixel coincides with the fourth virtual edge corresponding to the sub-pixel, and in essence, the fourth edge of the sub-pixel satisfies that at least one point thereof is located on the corresponding fourth virtual edge.

FIG. 25 is a schematic diagram of another display panel according to an embodiment of the present disclosure. As shown in FIG. 25, the display panel further includes a direction S3 and a direction S4, the direction S1 intersect with the direction S2, the direction S3 intersects with the direction S4, and the direction S1, the direction S2, the direction S3 and the direction S4 are all different. The third side of the first sub-pixel 11 is labeled as 23x, and the fourth side of the first sub-pixel 11 is labeled as 24x. The third side of the second sub-pixel 12 is labeled as 23y, and the fourth side of the second sub-pixel 12 is labeled as 24y.

In the first sub-pixel 11, orientations of third sides of any two of the first first sub-pixel 11a, the second first sub-pixel 11b, the third first sub-pixel 11c, and the fourth first sub-pixel 11d are different. In an embodiment, a direction in which the fourth side 24x is directed toward the third side 23x in the first first sub-pixel 11a is parallel to the direction S4 and is opposite to the direction S4, a direction in which the fourth side 24x is directed toward the third side 23x in the second first sub-pixel 11b is parallel to the direction S3 and is the same as the direction S3, a direction in which the fourth side 24x is directed toward the third side 23x in the third first sub-pixel 11c is parallel to the direction S3 and is opposite to the direction S3, and a direction in which the fourth side 24x is directed toward the third side 23x in the fourth first sub-pixel 11d is parallel to the direction S4 and is the same as the direction S4.

In the second sub-pixel 12, orientations of third sides of any two of the first second sub-pixel 12a, the second second sub-pixel 12b, the third second sub-pixel 12c, and the fourth second sub-pixel 12d are different. In an embodiment, a direction in which the fourth side 24y is directed toward the third side 23y in the first second sub-pixel 12a is parallel to the direction S4 and is opposite to the direction S4, a direction in which the fourth side 24y is directed toward the third side 23y in the second second sub-pixel 12b is parallel to the direction S3 and is the same as the direction S3, a direction in which the fourth side 24y is directed toward the third side 23y in the third second sub-pixel 12c is parallel to the direction S3 and is opposite to the direction S3, and a direction in which the fourth side 24y is directed toward the third side 23y in the fourth second sub-pixel 12d is parallel to the direction S4 and is the same as the direction S4.

The first sub-group 10a includes two first sub-pixels 11 and two second sub-pixels 12, and the first sub-pixel 11 and the second sub-pixel 12 are arranged alternately in the direction S1. The four sub-pixels are specifically the first first sub-pixels 11a, the first second sub-pixels 12a, the second first sub-pixels 11b, and the second second sub-pixel 12b. In an embodiment, the multiple first sub-groups 10a are arranged in sequence in the direction S1.

The second sub-group 10b includes two second sub-pixels 12 and two first sub-pixels 11, and the second sub-pixel 12 and the first sub-pixel 11 are arranged alternately in the direction S1. The four sub-pixels are specifically the third second sub-pixel 12c, the third first sub-pixel 11c, the fourth second sub-pixel 12d, and the fourth first sub-pixel 11d. In an embodiment, the multiple second sub-groups 10b are arranged in sequence in the direction S1.

The first sub-group 10a and the second sub-group 10b are adjacent in the direction S2. In an embodiment, the first sub-group 10a and the second sub-group 10b may be arranged alternately in the direction S2.

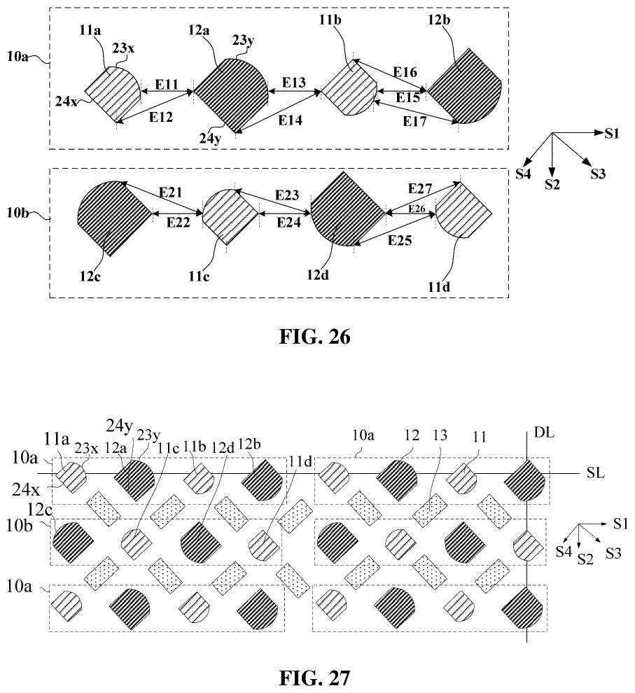

FIG. 26 is a schematic diagram of a first sub-group and a second sub-group adjacent to each other in FIG. 25. As shown in FIG. 26, in the first first sub-pixel 11a, the third side 23x and the fourth side 24x are arranged in the direction S4, and the shortest distance E11 between the third side 23x and the first second sub-pixel 12a is less than the shortest distance E12 between the fourth side 24x and the first second sub-pixel 12a.

In the first second sub-pixel 12a, the third side 23y and the fourth side 24y are arranged in the direction S4, and the shortest distance E13 between the third side 23y and the second first sub-pixel 11b is less than the shortest distance E14 between the fourth side 24y and the second first sub-pixel 11b.

In the second first sub-pixel 11b, the third side 23x and the fourth side 24x are arranged in the direction S3, and the shortest distance E15 between the third side 23x and the second second sub-pixel 12b is less than the shortest distance E16 between the fourth side 24x and the second second sub-pixel 12b.

In the second second sub-pixel 12b, the third side 23y and the fourth side 24y are arranged in the direction S3, and the shortest distance E17 between the third side 23y and the second first sub-pixel 11b is greater than the shortest distance E15 between the fourth side 24y and the second first sub-pixel 11b.

In the third second sub-pixel 12c, the third side 23y and the fourth side 24y are arranged in the direction S3, and the shortest distance E21 between the third side 23y and the third first sub-pixel 11c is greater than the shortest distance E22 between the fourth side 24y and the third first sub-pixel 11c.

In the third first sub-pixel 11c, the third side 23x and the fourth side 24x are arranged in the direction S3, and the shortest distance E23 between the third side 23x and the fourth second sub-pixel 12d is greater than the shortest distance E24 between the fourth side 24x and the fourth second sub-pixel 12d.

In the fourth second sub-pixel 12d, the third side 23y and the fourth side 24y are arranged in the direction S4, and the shortest distance E25 between the third side 23y and the fourth first sub-pixel 11d is greater than the shortest distance E26 between the fourth side 24y and the fourth first sub-pixel 11d.

In the fourth first sub-pixel 11d, the third side 23x and the fourth side 24x are arranged in the direction S4, and the shortest distance E26 between the third side 23x and the fourth second sub-pixel 12d is less than the shortest distance E27 between the fourth side 24x and the fourth second sub-pixel 12d.

It should be noted that, for any two sub-pixels that the third side and the fourth side are arranged in the direction S4, a direction in which the fourth side is directed toward the third side may be the same as or may be opposite to the direction S4. Exemplarily, the direction in which the fourth side 24x is directed toward the third side 23x in the first first sub-pixel 11a is opposite to the direction S4, the direction in which the fourth side 24y is directed toward the third side 23y in the first second sub-pixel 12a is opposite to the direction S4, and the direction in which the fourth side 24y is directed toward the third side 23y in the fourth second sub-pixel 12d is the same as the direction S4, which is not limited thereto. Similarly, for any two sub-pixels that the third side and the fourth side are arranged in the direction S3, a direction in which the fourth side is directed toward the third side may be the same as or may be opposite to a direction in the direction S3.

FIG. 27 is a schematic diagram of another display panel according to an embodiment of the present disclosure. As shown in FIG. 27, in an embodiment, the display panel further includes multiple scan lines SL and multiple data lines DL which are disposed in a crossed manner. The first direction S1 is parallel to an extension direction of the scan line SL, and the second direction S2 is parallel to an extension direction of the data line DL. FIG. 27 shows only one scan line SL and one data line DL. It should be understood that one scan line SL is used to drive corresponding at least one row of multiple sub-pixels, and one data line DL is used to provide a data signal for corresponding at least one column of multiple sub-pixels. FIG. 27 shows that one signal line overlaps with opening regions of multiple sub-pixels in a corresponding one row/column. Its purpose is only to represent that a signal transmission exists between the signal line and a corresponding sub-pixel. During the actual panel cabling, the signal line may or may not overlap with the opening region of the sub-pixel in the thickness direction of the display panel.

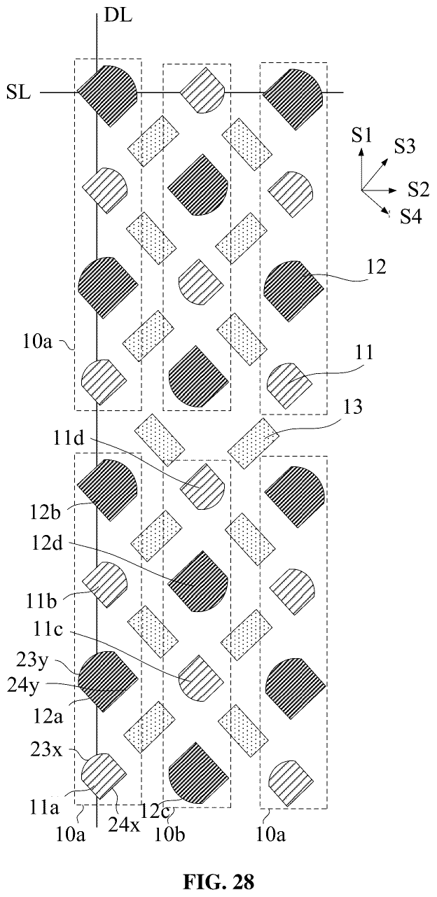

FIG. 28 is a schematic diagram of another display panel according to an embodiment of the present disclosure. As shown in FIG. 28, in an embodiment, the display panel further includes multiple scan lines SL and multiple data lines DL which are disposed in a crossed manner. Different from FIG. 27, in FIG. 28, the first direction S1 is parallel to the extension direction of the data line DL, and the second direction S2 is parallel to the extension direction of the scan line SL.

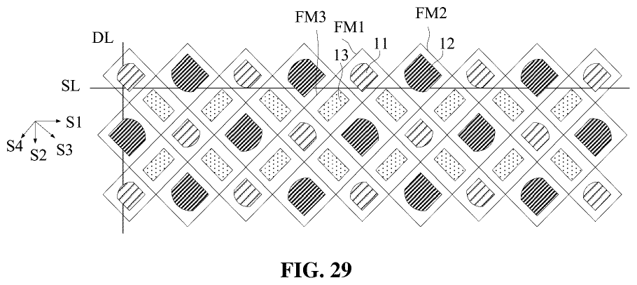

FIG. 29 is a schematic diagram of another display panel according to an embodiment of the present disclosure. As shown in FIG. 29, the first direction S1 is parallel to the extension direction of the scan line SL, the second direction S2 is parallel to the extension direction of the data line DL, and the layout of the sub-pixels shown in FIG. 29 is different from that shown in FIG. 27. FIG. 30 is a schematic diagram of another display panel according to an embodiment of the present disclosure. As shown in FIG. 30, the second direction S2 is parallel to the extension direction of the scan line SL, the first direction S1 is parallel to the extension direction of the data line DL, and the layout of the sub-pixels shown in FIG. 30 is different from that shown in FIG. 28.

It should be noted that the first direction and the second direction may be other directions. In an embodiment, the non-display region of the display panel includes a display chip. The second direction may be a direction in which a center of the display panel is directed toward a center of the display chip, and the first direction intersects with the second direction, for example, the second direction is perpendicular to the first direction, which is not specifically limited.

In an embodiment, at least one of the first sub-pixel or the second sub-pixel further includes a fourth side opposite to the third side, the fourth side is connected to the first side and the second side on the same side of the first side and the second side, the fourth side includes a fourth sub-segment and a fifth sub-segment, and the fourth sub-segment is connected to the first side and the fifth sub-segment is connected to the second side. The circumscribed virtual parallelogram further includes a fourth virtual side, the fourth virtual side is connected to the first virtual side and the second virtual side on the same side of the first virtual side and the second virtual side, and at least one point of the fourth side is located on the fourth virtual side; 0.05*La≤Xd≤0.3*La, where Xd is a third distance denoting a vertical distance between an intersection point of the first side and the fourth sub-segment and the fourth virtual side. In an embodiment, 0.05*Lb≤Xe≤0.3*Lb, where Xe is a fourth distance denoting a vertical distance between an intersection point of the second side and the fifth sub-segment and the fourth virtual side.

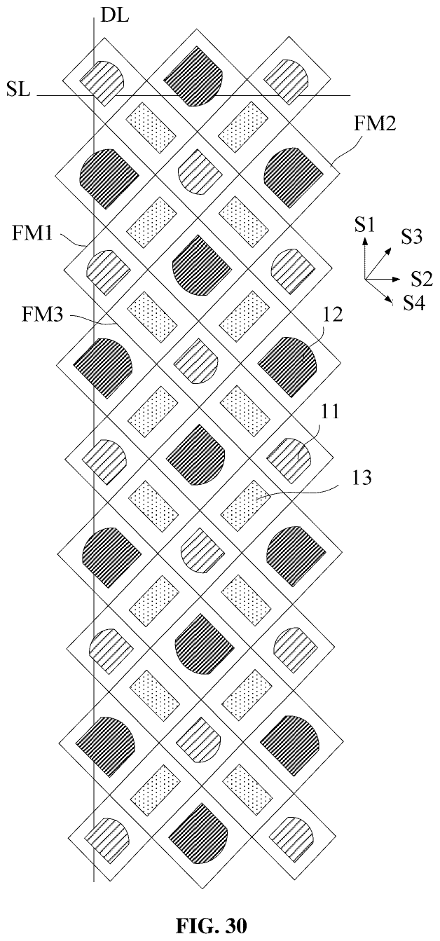

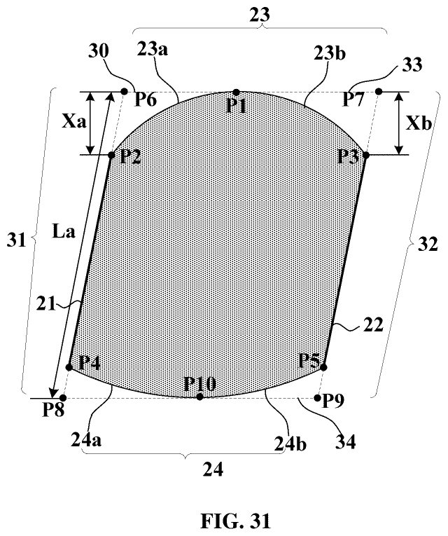

FIG. 31 is a schematic diagram of another sub-pixel according to an embodiment of the present disclosure. The first sub-pixel and the second sub-pixel may independently select the sub-pixel. As shown in FIG. 31, the sub-pixel further includes a fourth side 24. The closed region surrounded by the clockwise connection of the first side 21, the third side 23, the second side 22, and the fourth side 24 constitutes the opening region of the sub-pixel. The fourth side 24 may be a straight line segment shown in FIG. 2, or may also be formed by connecting multiple sub-segments shown in FIG. 31.

As shown in FIG. 31, the fourth side 24 at least includes a fourth sub-segment 24a and a fifth sub-segment 24b. The fourth sub-segment 24a is connected to the first side 21, and an intersection point between the fourth sub-segment 24a and the first side 21 is P4. The fifth sub-segment 24b is connected to the second side 22, and an intersection point between the fifth sub-segment 24b and the second side 22 is P5. The circumscribed virtual parallelogram 30 further includes a fourth virtual side 34 parallel to the third virtual side 33, and at least one point of the fourth side 24 is located on the fourth virtual side 34. In an embodiment, a midpoint P10 of the fourth side 24 is located on the fourth virtual side 34, and the point P10 is a connection point between the fourth sub-segment 24a and the fifth sub-segment 24b. In other embodiments, the fourth side may further include one or more sub-segments connected between the fourth sub-segment and the fifth sub-segment. Based on this, one sub-segment of the fourth side may overlap with a local line segment of the fourth virtual side, but is not limited thereto.

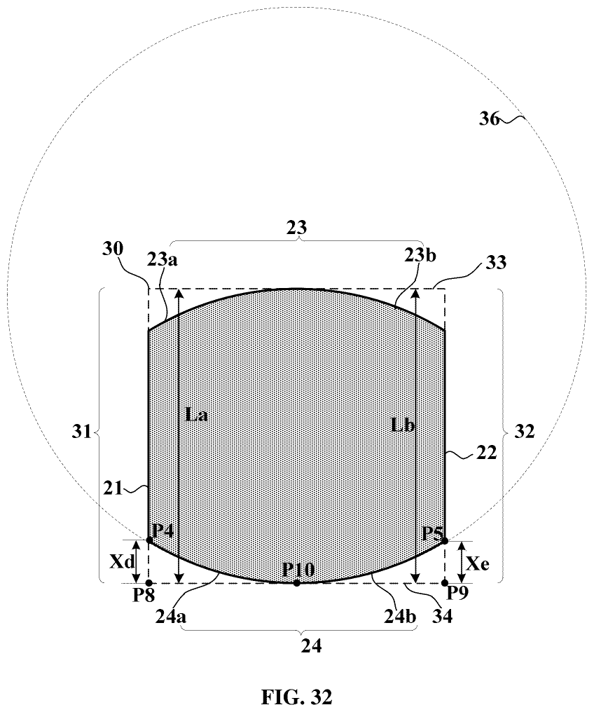

FIG. 32 is a schematic diagram of another sub-pixel according to an embodiment of the present disclosure. The first sub-pixel and the second sub-pixel may independently select the sub-pixel. As shown in FIG. 32, in an embodiment, the circumscribed virtual parallelogram 30 is a square. The fourth side 24 includes a fourth sub-segment 24a and a fifth sub-segment 24b, and a connection point of the fourth sub-segment 24a and the fifth sub-segment 24b is P10. The circumscribed virtual parallelogram 30 includes a fourth virtual side 34, and a point P10 of the fourth side 24 is located on the fourth virtual side 34.

As shown in FIG. 32, a vertical distance between an intersection point P4 of the first side 21 and the fourth sub-segment 24a and the fourth virtual side 34 is the third distance Xd, and Xd satisfies 0.05*La≤Xd≤0.3*La. A vertical distance between an intersection point P5 of the second side 22 and the fifth sub-segment 24b and the fourth virtual side 34 is the fourth distance Xe, and Xe satisfies 0.05*Lb≤Xe≤0.3*Lb. A ratio of Xd/La is relatively large, and/or a ratio of Xe/Lb is relatively large, which may impair the opening ratio of the sub-pixel. The ratio of Xd/La and the ratio of Xe/Lb are limited to the above-described ranges, so that the opening ratio of the sub-pixel can be ensured to be relatively large, and meanwhile, a distance between the fourth side 24 and the adjacent sub-pixel can be increased, which helps to reduce the problem of sneaking light and improve the display effect.

As shown in FIG. 32, in an embodiment, the fourth sub-segment 24a is connected to the fifth sub-segment 24b, and each of the fourth sub-segment 24a and the fifth sub-segment 24b is an arc segment.

As shown in FIG. 32, in an embodiment, the fourth sub-segment 24a and the fifth sub-segment 24b are located on a circumference of the same virtual circle 36. In other embodiments, at least two of the first sub-segment (reference numeral 23a), the second sub-segment (reference numeral 23b), the fourth sub-segment (reference numeral 24a), and the fifth sub-segment (reference numeral 24b) are arc segments, and the at least two arc segments may be located on a circumference of the same virtual circle.

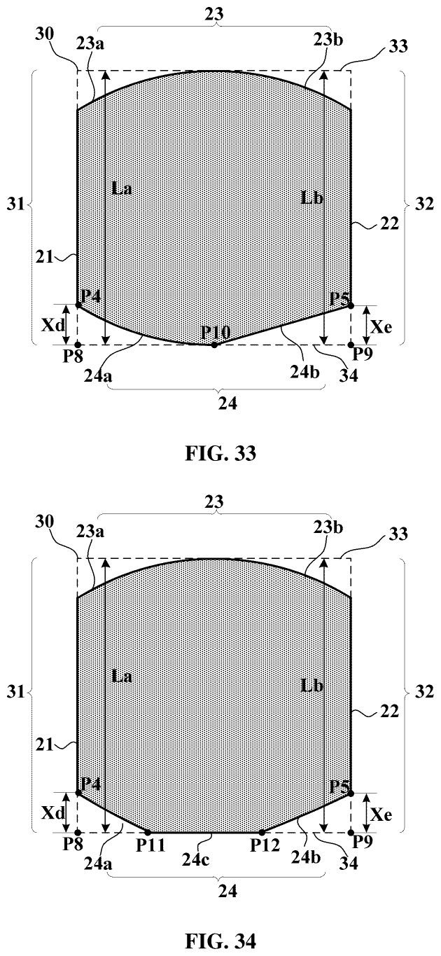

FIG. 33 is a schematic diagram of another sub-pixel according to an embodiment of the present disclosure. The first sub-pixel and the second sub-pixel may independently select the sub-pixel. As shown in FIG. 33, in an embodiment, the fourth sub-segment 24a is an arc segment, and the fifth sub-segment 24b is a straight line segment.

FIG. 34 is a schematic diagram of another sub-pixel according to an embodiment of the present disclosure. The first sub-pixel and the second sub-pixel may independently select this sub-pixel. As shown in FIG. 34, in an embodiment, the fourth side 24 further includes a sixth sub-segment 24c connected to the fourth sub-segment 24a and the fifth sub-segment 24b on the same side of the fourth sub-segment 24a and the fifth sub-segment 24b, where the sixth sub-segment 24c is a straight line segment, the fourth sub-segment 24a is a straight line segment, and the fifth sub-segment 24b is a straight line segment. In other embodiments, the fourth sub-segment is an arc segment. Alternatively, in an embodiment, the fifth sub-segment is an arc segment. Alternatively, in an embodiment, the fourth side may be formed by four or more sub-segments, which is not specifically limited. Any sub-segment may be an arc segment or a straight line segment.

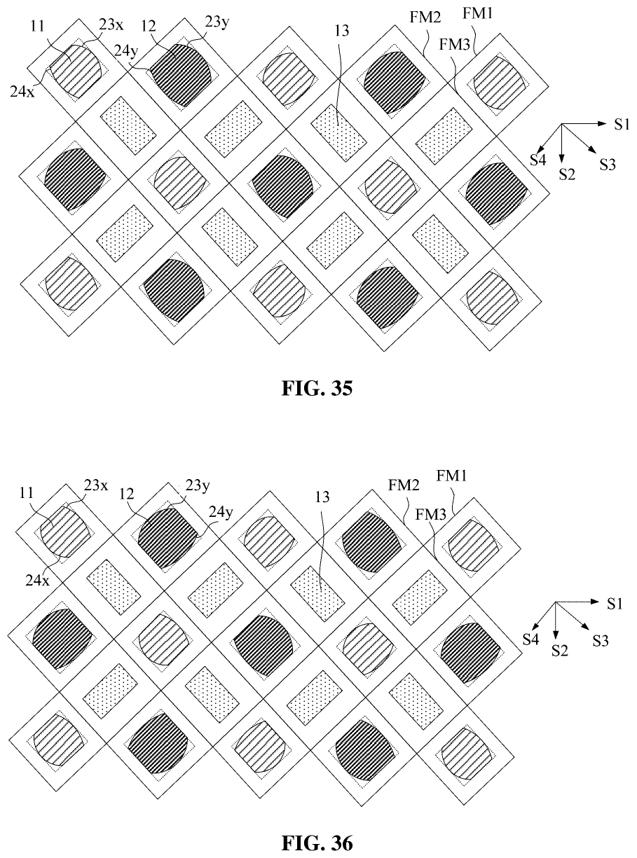

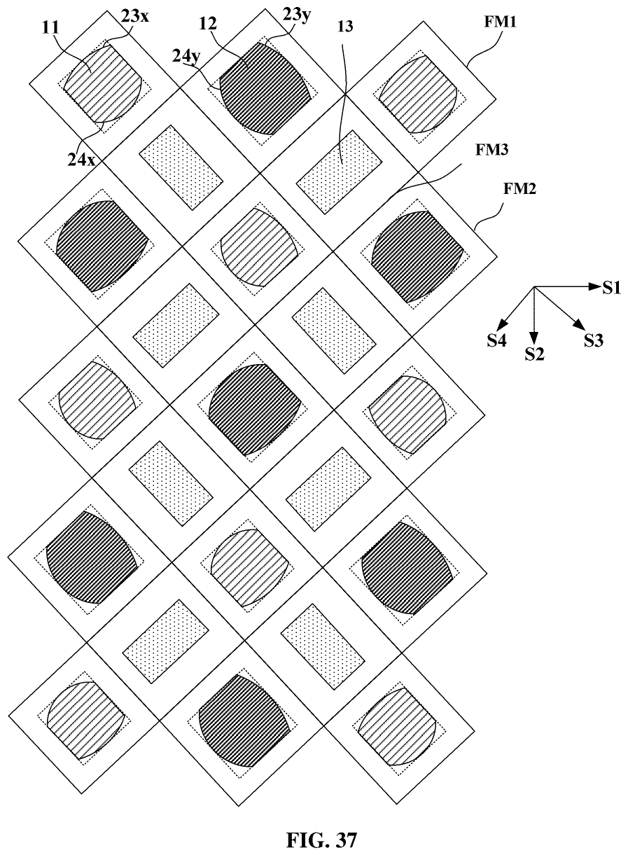

Based on the above-described structures of the first sub-pixel and the second sub-pixel, FIG. 35 is a schematic diagram of another display panel according to an embodiment of the present disclosure. As shown in FIG. 35, a third side 23x of the first sub-pixel 11 is formed by connecting two arc segments, and a fourth side 24x of the first sub-pixel 11 is formed by connecting two arc segments. A third side 23y of the second sub-pixel 12 is formed by connecting two arc segments, and a fourth side 24y of the second sub-pixel 12 is formed by connecting two arc segments. FIG. 36 is a schematic diagram of another display panel according to an embodiment of the present disclosure. A pixel arrangement manner in FIG. 36 is different from that shown in FIG. 35. FIG. 37 is a schematic diagram of another display panel according to an embodiment of the present disclosure. A pixel arrangement manner in FIG. 37 is different from those in FIG. 36 and FIG. 35. FIG. 38 is a schematic diagram of another display panel according to an embodiment of the present disclosure. A pixel arrangement manner in FIG. 38 is different from those shown in FIG. 35 to FIG. 37.

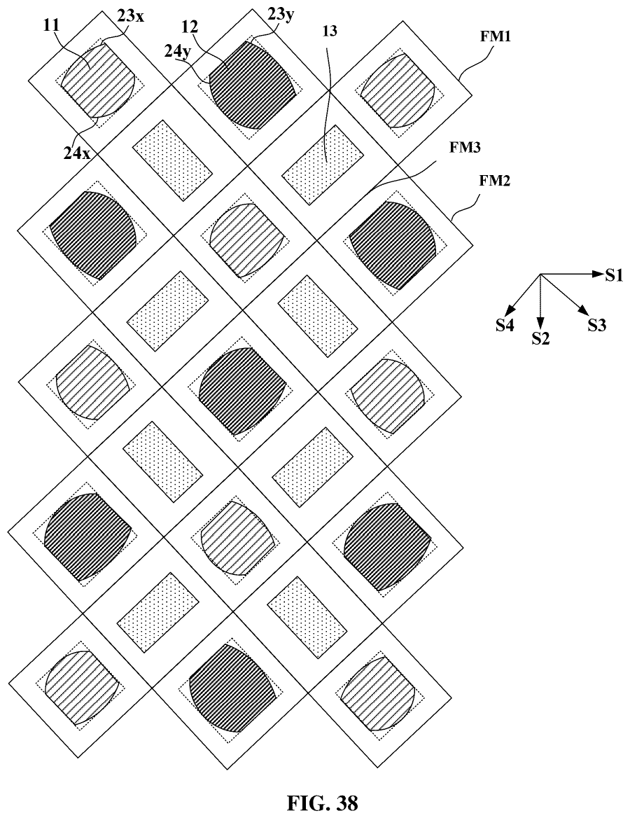

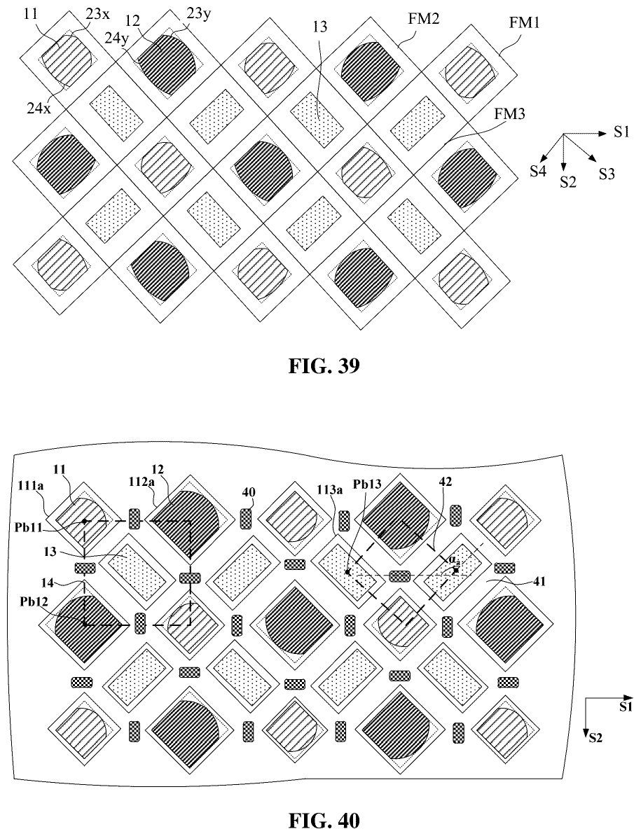

FIG. 39 is a schematic diagram of another display panel according to an embodiment of the present disclosure. As shown in FIG. 39, the third side 23x of the first sub-pixel 11 is formed by connecting two arc segments and one straight line segment, where the straight line segment is located between the two arc segments, and the fourth side 24x of the first sub-pixel 11 is formed by connecting two arc segments. The third side 23y of the second sub-pixel 12 is formed by connecting two arc segments, and the fourth side 24y of the second sub-pixel 12 is formed by connecting two arc segments.

Based on the above-described structures of the first sub-pixel and the second sub-pixel, the pixel arrangement of the display panel is not limited to those shown in FIG. 35 to FIG. 39.

For any one pixel arrangement in FIG. 35 to FIG. 39, a line connecting a center of gravity of the first sub-pixels 11 and a center of gravity of the second sub-pixel 12 satisfies any one of the following conditions, where the first sub-pixels 11 and the second sub-pixel 12 are adjacent to each other: (1) the connection line intersects with the third side 23x of the first sub-pixel 11, and intersects with the third side 23y of the second sub-pixel 12; (2) the connection line intersects with the third side 23x of the first sub-pixel 11, and intersects with the fourth side 24y of the second sub-pixel 12; (3) the connection line intersects with the fourth side 24x of the first sub-pixel 11, and intersects with the third side 23y of the second sub-pixel 12; and (4) the connection line intersects with the fourth side 24x of the first sub-pixel 11, and intersects with the fourth side 24y of the second sub-pixel 12.

In an embodiment, the display panel further includes multiple support posts. In the thickness direction of the display panel, the support post overlaps with at least one virtual side of the first virtual quadrilateral, and a virtual side of the at least one virtual side intersects with the third side of at least one of the first sub-pixel or the second sub-pixel.

FIG. 40 is a schematic diagram of another display panel according to an embodiment of the present disclosure. As shown in FIG. 40, the display panel further includes multiple support posts 40, and the support posts 40 are located in a non-opening region 41. In an embodiment, with reference to FIGS. 4 and 40, a pixel opening corresponding to the sub-pixel includes a lower opening and an upper opening. In this case, the non-opening region 41 may be understood as a pixel defining layer region other than the upper opening region of the pixel defining layer 110, where a region defined in 111a represents an upper opening region of the first sub-pixel 11, a region defined in 112a represents an upper opening region of the second sub-pixel 12, and a region defined in 113a represents an upper opening region of the third sub-pixel 13. The non-opening region 41 is provided with multiple support posts 40. The support post 40 is configured to support the display panel in the thickness direction, and when the display panel is an organic light-emitting display panel, the support post 40 may be further configured to support the mask in an evaporation process. A projection of the structure of the support post 40 in the thickness direction of the display panel is a rounded rectangle, but is not limited thereto.

A center of gravity of the first sub-pixel 11 is Pb11, a center of gravity of the second sub-pixel 12 is Pb12, and a center of gravity of the third sub-pixel 13 is Pb13. FIG. 40 shows only centers of gravity of some sub-pixels. Lines connecting centers of gravity of the two first sub-pixels 11 and centers of gravity of the two second sub-pixels 12 form the first virtual quadrilateral 14. The non-opening region 41 is provided with multiple support posts 40, and at least one support post 40 overlaps with at least one virtual side of the first virtual quadrilateral 14 in the thickness direction of the display panel. A virtual side of the first virtual quadrilateral 14 intersects with the third side of one of the first sub-pixel 11 or the second sub-pixel 12. Compared with the circumscribed virtual parallelogram of the sub-pixel as the opening region, in the embodiment of the present disclosure, a distance between the opening region of the first sub-pixel 11 and the opening region of the second sub-pixel 12 is relatively large, therefore, sufficient space can be used to dispose the support post 40, and the sufficient distance can be kept between the support post 40 and the opening region of the sub-pixel.

If the positioning of the support post is too close to the opening of the sub-pixel, the support post is extruded by a mask or other tools in the manufacturing process, and may easily fall into the opening region of the sub-pixel to form the display dark spot, which affects the yield. In particular, the current display panel pursues the high PPI, since the dimension of the support post cannot be compressed to the utmost extent to ensure the density of the support post, the low yield of the panel is caused.

In the embodiment of the present application, the distance between the opening region of the first sub-pixel 11 and the opening region of the second sub-pixel 12 at the position of the virtual side is relatively large, and the positioning space of the support post 40 increases, so that the positioning of the support post 40 can be controlled to be away from the opening region of the sub-pixel. In this way, while the density of the support post is ensured, the risk that the support post 40 falls into the opening region of the sub-pixel can be further reduced, and thus the manufacturing yield and the display effect can be improved. In addition, the dimension of the support post 40 can be further increased to a certain extent so as to ensure the support effect.

As shown in FIG. 40, in an embodiment, one first sub-pixel 11, one second sub-pixel 12, and two third sub-pixels 13 may form a third virtual quadrilateral 42. Centers of gravity Pb13 of the two third sub-pixels 13 are located at two opposite vertices of the third virtual quadrilateral 42, respectively, and a center of gravity Pb11 of the first sub-pixel 11 and a center of gravity Pb12 of the second sub-pixel 12 are located at another two opposite vertices of the third virtual quadrilateral 42, respectively. An included angle range between the extension direction of the third sub-pixel 13 and the extension direction of the support post 40 and towards the second sub-pixel 12 is αₐ, and 130°≤αₐ≤140°.

In the embodiment of the present application, a projection of the structure of the support post 40 in the thickness direction of the display panel is a rounded rectangle, and the rounded rectangle includes long sides and short sides, where a length of the long side is greater than a length of the short side, the extension direction of the support post 40 is parallel to the long side of the rounded rectangle, and a dimension of the support post 40 in a direction of the long side of the rounded rectangle is greater than a dimension of the support column 40 in a direction of the short side of the rounded rectangle. A projection of the structure of the third sub-pixel 13 in the thickness direction of the display panel is generally approximately rectangle, a length of the long side of the rectangle is greater than a length of the short side of the rectangle, the extension direction of the third sub-pixel 13 is parallel to the long side of the rectangle, and a dimension of the third sub-pixel 13 in a direction of the long side of the rectangle is greater than a dimension of the third sub-pixel 13 in a direction of the short side of the rectangle. An included angle between the extension direction of the third sub-pixel 13 and the extension direction of the adjacent support post 40 is da, and da satisfies 130°≤αₐ≤140°. For example, da may be a 130°, a 135°, a 139° and the like. In an embodiment, αₐ=135°.

Based on this, an extension direction of a long axis of the support post 40 is directed toward the third sub-pixel 13, and the direction of the short side (perpendicular to the extension direction of the support post 40) of the support post 40 is directed toward the first sub-pixel 11 and the second sub-pixel 12. After the support post 40 is disposed in a non-opening region between the first sub-pixel 11 and the second sub-pixel 12, the support post 40 may have a relatively larger spacing from the opening region of the first sub-pixel 11, so as to reduce the risk that the support post approaches the first sub-pixel and falls into the opening region of the first sub-pixel. The support post 40 may also have a relatively larger spacing from the opening region of the second sub-pixel 12, so that the risk that the support post approaches the second sub-pixel and falls into the opening region of the second sub-pixel can be reduced, and thus the production yield and the display effect can be improved.

In addition, in the high PPI, a spacing between opening regions of adjacent sub-pixels is relatively small. To ensure the support effect of the support post, the dimension of the support post cannot be compressed to the utmost extent. An opening region spacing between the first sub-pixel 11 and the second sub-pixel 12 adjacent to each other is relatively small at the high PPI. If the extension direction of the long axis of the support post 40 is directed toward the first sub-pixel 11 and the second sub-pixel 12, then the risk that the support post 40 falls into the opening region is relatively large. If the opening region spacing between the first sub-pixel 11 and the second sub-pixel 12 is increased to reduce the risk that the support post 40 falls into the opening region, then the opening ratios of the first sub-pixel 11 and the second sub-pixel 12 are reduced, and the PPI is further reduced. Therefore, an extension direction of a short axis of the support post 40 is directed toward the first sub-pixel 11 and the second sub-pixel 12, and does not need to sacrifice the opening ratio of the first sub-pixel 11 and the second sub-pixel 12, which helps the display panel to implement the high PPI.

It should be noted that if the projection of the structure of the support post in the thickness direction of the display panel is a regular shape, then the extension direction of the support post is parallel to a long axis of a projection shape of the support post; if the projection of the structure of the support post in the thickness direction of the display panel is an irregular shape, then the extension direction of the support post is parallel to the longest side of the projection shape of the support post.

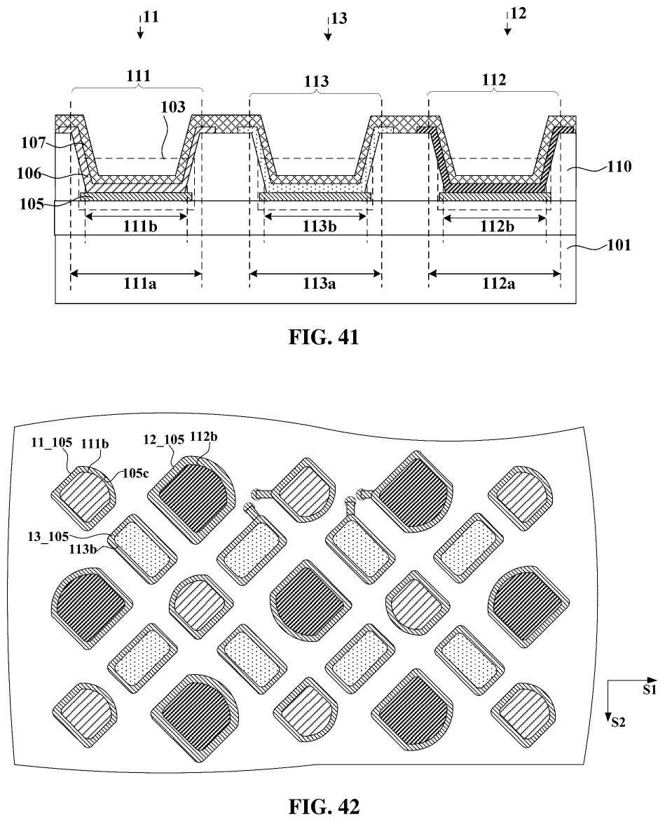

FIG. 41 is a schematic diagram of another display panel according to an embodiment of the present disclosure. As shown in FIG. 41, in an embodiment, the display panel includes a substrate 101, and a pixel defining layer 110 and multiple light-emitting elements 103 located on a side of the substrate 101, where the pixel defining layer 110 includes multiple pixel openings, and the light-emitting element 103 includes a first electrode 105, a second electrode 107, and a light-emitting layer 106 located between the first electrode 105 and the second electrode 107. The light-emitting element 103 includes a first sub-pixel 11, a second sub-pixel 12, and a third sub-pixel 13. In at least one of the first sub-pixel 11 or the second sub-pixel 12, a shape of the first electrode 105 is approximately the same as a shape of a pixel opening corresponding to the first electrode 105. FIG. 42 is a schematic diagram of a first electrode and a pixel opening in FIG. 41. It should be understood that, multiple different film layers are provided between the substrate 101 and the pixel defining layer 102, such as multiple metal layers, interlayer insulating layers, buffer layers, dielectric layers, and planarization layers. The structure of the film layers between the substrate 101 and the pixel defining layer 102 is not specifically described herein. The substrate 101 may be considered as a set of multi-film layer structures that drive the light-emitting element 103 to work.

In the embodiment of the present application, a thin film transistor array (not shown) is disposed on the substrate 101 of the display panel. The pixel defining layer 110 is an insulating layer, and is specifically located on a side of the substrate 101. The pixel defining layer 110 has multiple pixel openings. A region corresponding to a lower opening in the pixel opening is a light-emitting region of the sub-pixel, and a region other than the pixel opening of the pixel defining layer 110 is a non-opening region that may be used to dispose the support post.

The pixel defining layer 110 and the multiple light-emitting elements 103 are located on the same side of the substrate 101. The first electrode 105 in the light-emitting element 103 may be an anode, and the second electrode 107 in the light-emitting element 103 may be a cathode, but is not limited thereto. In other embodiments, a position of the anode and a position of the cathode are not limited thereto. The light-emitting layer 106 is located between the first electrode 105 and the second electrode 107. The light-emitting layer 106 of the first sub-pixel 11 may be configured to include a red light-emitting material, the light-emitting layer 106 of the second sub-pixel 12 may be configured to include a blue light-emitting material, and the light-emitting layer 106 of the third sub-pixel 13 may be configured to include a green light-emitting material, but is not limited thereto.

It should be understood that a first function layer may be disposed between the first electrode 105 and the light-emitting layer 106 in the light-emitting element 103, and a second function layer may be disposed between the second electrode 107 and the light-emitting layer 106 in the light-emitting element 103. If the first electrode 105 is an anode and the second electrode 107 is a cathode, then the first function layer may include a hole injection layer and a hole transport layer, and the second function layer may include an electron transport layer and a hole blocking layer. The film layer structure of the display panel further includes a protective layer on a side of the second electrode 107 facing away from the first electrode 105, and the like. Details are not specifically shown and described again.

With reference to FIGS. 41 and 42, the shape of the first electrode 105 is approximately the same as the shape of the pixel opening corresponding to the first electrode 105.

In an embodiment, a shape of the first electrode 105 of the first sub-pixel 11 is approximately the same as an opening shape of the first sub-pixel 11, that is, the shape of the first electrode 105 is designed so that the opening of the first sub-pixel 11 satisfies the requirement. An opening corresponding to the first sub-pixel 11 is the pixel opening 111, where the pixel opening 111 includes a lower opening region 111b (light-emitting region) and an upper opening area 111a, and a dimension of the upper opening 111a is greater than a dimension of the lower opening 111b, but a contour of the upper opening 111b is approximately the same as a contour of the lower opening 111b. In order to prevent the silver metal in the first electrode 105 (typically, indium tin oxide-silver-indium tin oxide (ITO-Ag-ITO) structure) from being corroded and further damaging the first electrode 105, generally, the area of the first electrode 105 is set to be greater than the lower opening region 111b, but the outline of the first electrode 105 is approximately the same as the outline of the lower opening region 111b. For example, the first electrode 105 of the first sub-pixel 11 includes a third sub-side 105c corresponding to the third side of the first sub-pixel 11. A shape, a radian, and the like of the third sub-side 105c may be approximately the same as the third side of the first sub-pixel 11, and a third side of the opening of the first sub-pixel 11 subsequently formed satisfies the design requirement.

Similarly, the shape of the first electrode 105 of the second sub-pixel 12 is basically the same as the shape of the opening of the second sub-pixel 12. An opening corresponding to the second sub-pixel 12 is a pixel opening 112, where the pixel opening 112 includes a lower opening region 112b (light-emitting region) and an upper opening area 112a, and a dimension of the upper opening 112a is greater than a dimension of the lower opening 112b, but a contour of the upper opening 112a is approximately the same as a contour of the lower opening 112b. The shape of the first electrode 105 of the second sub-pixel 12 is approximately the same as the shape of the lower opening region 112b of the corresponding pixel opening 112.

Similarly, the shape of the first electrode 105 of the third sub-pixel 13 is approximately the same as the shape of the opening of the third sub-pixel 13. An opening corresponding to the third sub-pixel 13 is a pixel opening 113, where the pixel opening 113 includes a lower opening region 113b (light-emitting region) and an upper opening region 113a, and a dimension of the upper opening 113a is greater than a dimension of the lower opening 113b, but a contour of the upper opening 113a is approximately the same as a contour of the lower opening 113b. The shape of the first electrode 105 of the third sub-pixel 13 is approximately the same as the shape of the lower opening region 113b of the corresponding pixel opening 113. It should be noted that in FIG. 42, an opening corresponding to the third sub-pixel 13 is a rounded rectangle, that is, a regular shape defined in the foregoing, where a center of the opening coincides with a center of gravity of the opening.

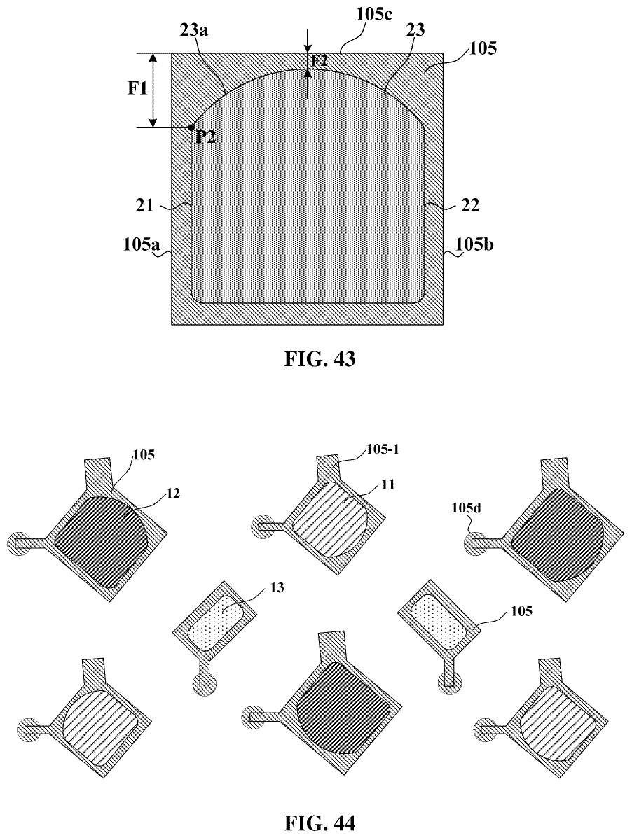

To improve the screen-to-body ratio of the display panel, an optical collection element (a machine that works by using an optical signal, such as a camera or a fingerprint recognition sensor) is generally disposed at a position overlapping with the display region. Since the first electrode 105 is generally opaque to light, in the embodiment of the present disclosure, the shape of the first electrode 105 is set to be approximately the same as a shape of a corresponding pixel opening (lower opening region), so that more light may be transmitted through the display panel, thereby improving the transmittance of the display panel and ensuring the collection effect of the optical signal. In addition, the shape of the first electrode 105 is approximately the same as the shape of the corresponding pixel opening, that is, the first electrode may include a curve side, as shown in FIG. 43. When the optical collection element is disposed at a position overlapping with the display region, the boundary line between the first electrode 105 being opaque to light and the surrounding light-transmitting region is one arc line, and the arc line is equivalent to being formed by multiple straight lines extending in different directions, so that the light energy is distributed in multiple different directions, thereby weakening the diffraction phenomenon and improving the collection effect of the optical signal.

The shape of the first electrode is designed so that the corresponding pixel opening satisfies the requirement. In FIG. 42, a connection via of the first electrode 105 of one first sub-pixel 11, connection vias of the first electrodes 105 of two third sub-pixels 13, and a connection via of the first electrode 105 of one second sub-pixel 12 are shown. In the direction S2, connecting vias of the first electrodes 105 of the first sub-pixel 11 and the third sub-pixel 13 adjacent to each other may be adjacently disposed; and in the direction S2, connection vias of the first electrodes 105 of the second sub-pixel 12 and the third sub-pixel 13 adjacent to each other may be adjacently disposed.

It should be noted that, a rounded corner is naturally formed at a right angle position of the lower opening region of the sub-pixel based on an external factor such as an apparatus or a process. A radius of the rounded corner caused by the process is generally about 1 micron to 3 micron, and the formation of the rounded corner is described in detail in the subsequent embodiment. In this embodiment, a shape of the first electrode 105 is approximately the same as a shape of a corresponding pixel opening. In this case, the first electrode 105 may also be designed according to a rounded corner of the lower opening region of the sub-pixel, that is, the right angle position of the first electrode 105 is chamfered to form the rounded corner, and the shape of the first electrode 105 may be a rounded rectangle.

In an embodiment, the display panel includes a substrate, a pixel defining layer and multiple light-emitting elements located on a side of the substrate. The pixel defining layer includes multiple pixel openings, and the light-emitting element includes a first electrode, a second electrode, and a light-emitting layer located between the first electrode and the second electrode; where each of the multiple light-emitting elements includes the first sub-pixel, the second sub-pixel and the third sub-pixel; in at least one of the first sub-pixel or the second sub-pixel, the first electrode includes a first sub-side corresponding to the first side, a second sub-side corresponding to the second side, and a third sub-side corresponding to the third side, and the third sub-side is connected to the first sub-side and the second sub-side on the same side of the first sub-side and the second sub-side; and a vertical distance between an intersection point of the first side and the first sub-segment and the third sub-side is F1, and the shortest distance between the third side and the third sub-side is F2, and 2≤F1/F2≤8.

FIG. 43 is a schematic diagram of another sub-pixel according to an embodiment of the present disclosure. The first sub-pixel and the second sub-pixel may independently select the sub-pixel. As shown in FIG. 43, the first electrode 105 of the sub-pixel includes the first sub-side 105a corresponding to the first side 21, the second sub-side 105b corresponding to the second side 22, and the third sub-side 105c corresponding to the third side 23. The third sub-side 105c is located on the same side of the first sub-side 105a and the second sub-side 105b, and is connected to the first sub-side 105a and the second sub-side 105b. Each of the first sub-side 105a, the second sub-side 105b, and the third sub-side 105c may be a straight line segment, but is not limited thereto. The third sub-side may also be an arc segment.

A vertical distance between an intersection point P2 of the first side 21 and the first sub-segment 23a and the third sub-side 105c is F1, the shortest distance between the third side 23 and the third sub-side 105c is F2, F1 and F2 satisfy 2≤F1/F2≤8, that is, a dimension of the first electrode 105 of the sub-pixel is greater than a dimension of an opening region of the sub-pixel, and a shape (or a contour) of the first electrode 105 is different from a shape (or a contour) of the opening region of the sub-pixel. In addition, when the third sub-side 105c of the first electrode 105 is a straight line segment, it is equivalent that the first electrode 105 is not chamfered.

FIG. 44 is a schematic diagram of another display panel according to an embodiment of the present disclosure. As shown in FIG. 44, a third side of the opening region of the first sub-pixel 11 may be formed by connecting multiple sub-segments, a shape of the first electrode 105 of the first sub-pixel 11 may be a nearly rectangular shape, and the first electrode 105 is connected to a corresponding signal line by using a via 105d. A third side of the opening region of the second sub-pixel 12 may be formed by connecting multiple sub-segments, and a shape of the first electrode 105 of the second sub-pixel 12 may be a nearly rectangular shape, and the first electrode 105 is connected to a corresponding signal line by using a via. A shape of the opening region of the third sub-pixel 13 may be a rectangle, a shape of the first electrode 105 of the third sub-pixel 13 may be a nearly rectangular shape, and the first electrode 105 is connected to a corresponding signal line by using a via. In the thickness direction of the display panel, an opening region of the sub-pixel is located in a shape of a corresponding first electrode. The first electrode may be an anode of the light-emitting element.

The display panel generally includes a pixel circuit arranged in an array. The pixel circuit includes a metal connection portion connected to different positions, and the metal connection portion is located in a fixed position in the pixel circuit. Therefore, an array arrangement manner of the metal connection portion is the same as an array arrangement manner of the pixel circuit. On this basis, since a first electrode (such as, an anode) corresponding to the same row of pixel circuits is not arranged in a row (or a column) in a row (or a column) direction, areas of metal connection portions covered by different first electrodes may be different, so that coupling capacitors at a node (such as, a node connected to a gate of a drive transistor) in the pixel circuit are different. An area of the first electrode 105 is disposed to be greater than the lower opening region 111b, and F1 and F2 satisfy 2≤F1/F2≤8, or further, the first electrode 105 further includes a protruding portion 105-1, and the protruding portion 105-1 may at least partially overlap with the metal connection portion in the thickness direction of the display panel, so that the difference of the overlapping areas of the metal connection portions and the first electrodes 105 in different pixel circuits can be reduced; therefore, the difference of the coupling capacitances caused by the difference of the overlapping areas is reduced, thereby improving the problem of dark fringes caused by uneven light-emitting brightness and improving the quality of the display screen.

In an embodiment, the display panel includes a substrate, and a pixel defining layer and multiple light-emitting elements located on a side of the substrate. The pixel defining layer includes multiple pixel openings, and the light-emitting element includes a first electrode, a second electrode, and a light-emitting layer between the first electrode and the second electrode; where the light-emitting element includes the first sub-pixel, the second sub-pixel and the third sub-pixel; and in at least one of the first sub-pixel or the second sub-pixel, and a shape of the light-emitting layer is approximately the same as a shape of a corresponding pixel opening of the multiple pixel openings.

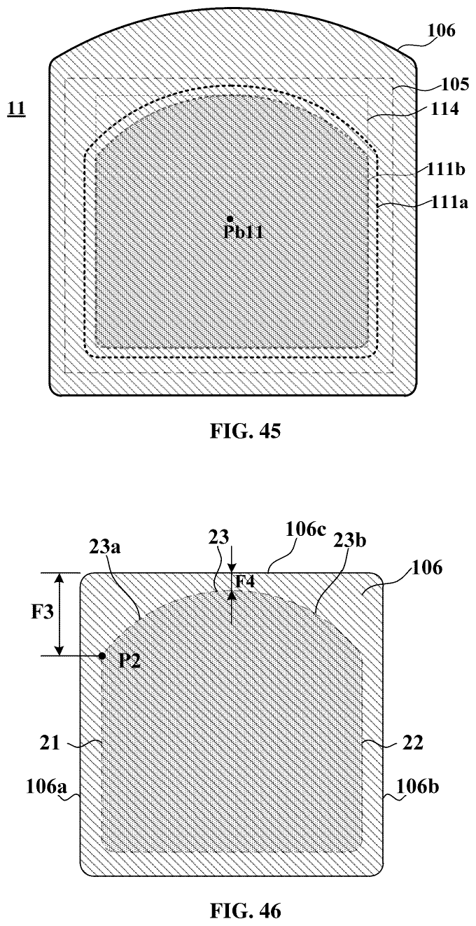

FIG. 45 is a schematic diagram of another sub-pixel according to an embodiment of the present disclosure. The first sub-pixel and the second sub-pixel may independently select the sub-pixel. As shown in FIG. 45, that the sub-pixel is the first sub-pixel 11 is used as an example, a shape of the light-emitting layer 106 of the first sub-pixel 11 is approximately the same as a shape of the lower opening region 111b of the first sub-pixel 11. In an embodiment, after the first electrode 105 of the light-emitting element is formed, the pixel defining layer is formed, and then an opening of the pixel defining layer is formed. One side of a shape of the lower opening region 111b of the first sub-pixel 11 is formed by connecting multiple sub-segments, and then the light-emitting layer 106 is evaporated. The light-emitting layer 106 is formed by evaporation of a fine metal mask (FMM), and the fine metal mask is generally large in dimension and cannot be integrally formed, and is usually prepared by using a strip-shaped mask (FMM sheet, also referred to as mask strip) process, where each mask is provided with a mask opening region, and the mask opening region is provided with a mask opening for evaporation. A shape of the light-emitting layer is approximately the same as a shape of a corresponding pixel opening. That is, if one side of the lower opening region is a straight line segment, then a side of the light-emitting layer corresponding to the side is also a straight line segment. If one side of the lower opening region is an arc segment, then a side of the light-emitting layer corresponding to the side is also an arc segment. In other words, at different positions, minimum spacings between the lower opening regions and the light-emitting layers are approximately equal (a difference value is within ±20%). A shape of the light-emitting layer is approximately the same as a shape of a corresponding pixel opening, which is equivalent to that the opening shape of the mask opening is approximately the same as the opening shape of the lower opening region 111b. In the manufacturing process of the display panel, an appropriate mask opening needs to be selected according to the shape and the dimension of the light-emitting layer. When the light-emitting layer that needs to be evaporated and plated is a rectangular or rounded rectangular, the mask opening may be a rectangular or rounded rectangular. Due to a process condition problem, when the mask opening is a rectangle, a shape of an actually formed light-emitting layer may be a rounded rectangle.

However, the mask plate may be deformed due to the wrinkle generated in processes such as mask stretching and welding, which results in an alignment deviation between the mask opening and the pixel opening of the pixel definition layer, thereby directly affecting the position accuracy of the evaporated sub-pixel, and causing abnormal display problems such as color spots and color deviation. The shape of the light-emitting layer is set to be approximately the same as the shape of a corresponding pixel opening, which can increase the width of the rib of the mask plate as far as possible, so that the mask plate is prevented from being deformed when being used, thereby ensuring the alignment precision during evaporation, and improving the product yield and the display effect.

It should be understood that mask openings of the first sub-pixel, the second sub-pixel and the third sub-pixel do not overlap when the light-emitting layer is evaporated. However, in an actual product, light-emitting layer materials of sub-pixels of different colors may overlap in the non-opening region due to the limitation of the process condition.

Regardless of how the lower opening region of the sub-pixel changes, an area of the light-emitting layer is greater than an area of the lower opening region of the sub-pixel, and the light-emitting layer needs to completely cover the lower opening region of the sub-pixel. In addition, the area of the first electrode is generally greater than the area of the lower opening region of the sub-pixel.

In an embodiment, the display panel includes a substrate, a pixel defining layer and multiple light-emitting elements located on a side of the substrate, where the pixel defining layer includes multiple pixel openings, and the light-emitting element includes a first electrode, a second electrode, and a light-emitting layer between the first electrode and the second electrode; where the light-emitting element includes the first sub-pixel, the second sub-pixel and the third sub-pixel; in at least one of the first sub-pixel or the second sub-pixel, each of the multiple light-emitting elements includes a first boundary corresponding to the first side, a second boundary corresponding to the second side, and a third boundary corresponding to the third side, and the third boundary is connected to the first boundary and the second boundary on the same side of the first boundary and the second boundary; and a vertical distance between an intersection point of the first side and the first sub-segment and the third boundary is F3, and the shortest distance between the third side and the third boundary is F4, and 1≤F3/F4≤4.

FIG. 46 is a schematic diagram of another sub-pixel according to an embodiment of the present disclosure. The first sub-pixel and the second sub-pixel may independently select the sub-pixel. As shown in FIG. 46, the light-emitting layer 106 of the sub-pixel includes a first boundary 106a corresponding to the first side 21, a second boundary 106b corresponding to the second side 22, and a third boundary 106c corresponding to the third side 23, where the third boundary 106c is connected to the first boundary 106a and the second boundary 106b on the same side of the first boundary 106a and the second boundary 106b. A vertical distance between an intersection point P2 of the first side 21 and the first sub-segment 23a and the third boundary 106c is F3, and the shortest distance between the third side 23 and the third boundary 106c is F4, and 1 ≤F3/F4≤4. The first boundary 106a, the second boundary 106b, and the third boundary 106c may all be straight line segments, but are not limited thereto. The third boundary may also be an arc segment and the like.

The evaporation process is that an evaporation material is placed in a vacuum environment, and the evaporation material is evaporated or sublimated by heating, molecules of the evaporated evaporation material are attached to the to-be-evaporated plate through the mask opening. However, due to the temperature rise of the environment, different expansion rates exist between the mask and the substrate having the first electrode and the pixel defining layer mounted thereon, thereby resulting in a deviation between the evaporation material and the opening of the pixel defining layer that the evaporation material is supposed to cover in some regions after evaporation. In the embodiment of the present disclosure, an evaporation area of the light-emitting layer 106 of the sub-pixel is greater than the opening shape of the sub-pixel, a vertical distance between an intersection point P2 of the first side 21 and the first sub-segment 23a and the third boundary 106c is F3, and the shortest distance between the third side 23 and the third boundary 106c is F4, and F3 and F4 satisfy 1≤F3/F4≤4, so that it is ensured that the opening of the pixel defining layer may be covered by corresponding evaporation materials, moreover, the color mixing problem caused by the overlapping of two kinds of light-emitting materials in the same pixel opening due to excessive mask opening and positional deviation can be avoided simultaneously, so as to improve the product yield and the display effect.

It should be noted that a shape of the pixel opening of the pixel defining layer may be different from a shape of the light-emitting layer. Therefore, a center of gravity of the pixel opening of the pixel defining layer may not coincide with a center of gravity of a corresponding light-emitting layer.

In the manufacturing process of the display panel, an appropriate mask opening needs to be selected according to the shape and the dimension of the light-emitting layer. When the light-emitting layer that needs to be evaporated is a rectangular or rounded rectangular, the mask opening may be a rectangular or rounded rectangular. Due to the process condition problem, when the mask opening is a rectangle, a shape of an actually formed light-emitting layer may be a rounded rectangle. Regardless of how the lower opening region of the sub-pixel changes, an area of the light-emitting layer is greater than an area of the lower opening region of the sub-pixel, and the light-emitting layer needs to completely cover the lower opening region of the sub-pixel.

In an embodiment, each of the first sub-pixel and the second sub-pixel further includes a fourth side opposite to the third side, and the fourth side is connected to the first side and the second side on the same side of the first side and the second side; each of the first sub-pixel and the second sub-pixel further includes a first arc segment and a second arc segment, the first arc segment is connected to the first side and the fourth side, and the second arc segment is connected to the second side and the fourth side; and a radius of a virtual circle corresponding to the first arc segment is Rb, where Rb≤3 μm, and a radius of a virtual circle corresponding to the second arc segment is Rc, where Rc≤3 μm.

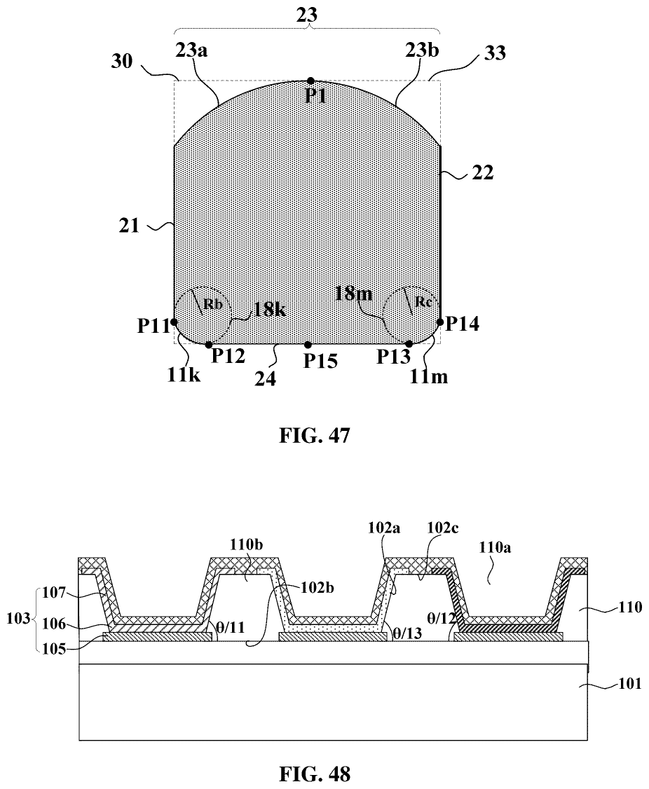

FIG. 47 is a schematic diagram of another sub-pixel according to an embodiment of the present disclosure. The first sub-pixel and the second sub-pixel may independently select the sub-pixel. As shown in FIG. 47, the sub-pixel further includes a fourth side 24 opposite to the third side 23, and the fourth side 24 is connected to the first side 21 and the second side 22 on the same side of the first side 21 and the second side 22. The sub-pixel further includes a first arc segment 11k and a second arc segment 11m, the first arc segment 11k is connected to the first side 21 and the fourth side 24, and the second arc segment 11m is connected to the second side 22 and the fourth side 24. A radius of a virtual circle 18k corresponding to the first arc segment 11k is Rb, where Rb≤3 μm, and a radius of a virtual circle 18m corresponding to the second arc segment 11m is Rc, where Rc≤3 μm.

In an embodiment, one inscribed circle 18k of the sub-pixel may be roughly determined according to the endpoint P11 of the first side 21 and the endpoint P12 of the fourth side 24, and an arc of the points P11 to P12 of the inscribed circle 18k is determined as a first arc segment 11k connected to the first side 21 and the fourth side 24. At the beginning of design, the first side 21 and the fourth side 24 may intersect at a right-angle vertex (as shown in FIG. 2). However, for the reason of the process manufacturing condition, the first side 21 and the fourth side 24 are connected by using the first arc segment 11k. A radius of the virtual circle 18k is Rb, where Rb≤ 3 μm, for example, Rb is 1 μm, 1.9 μm, 2.8 μm and the like. If the radius Rb of the virtual circle 18k is equal to 0, then the first side 21 of the straight line segment is directly connected to the fourth side 24 of the straight line segment.

One inscribed circle 18m of the sub-pixel may be determined according to the endpoint P14 of the second side 22 and the endpoint P13 of the fourth side 24, and an arc of the points P13 to P14 of the inscribed circle 18m is determined as a second arc segment 11m connected to the second side 22 and the fourth side 24. At the beginning of design, the second side 22 and the fourth side 24 may intersect at a right-angle vertex (as shown in FIG. 2). However, for the reason of the process manufacturing condition, the second side 22 and the fourth side 24 are connected by using the second arc segment 11m. A radius of the virtual circle 18m is Rc, where Rc≤3 μm, for example, Rc is 1 μm, 1.9 μm, 2.8 μm and the like. If the radius Rc of the virtual circle 18m is equal to 0, then the second side 22 of the straight line segment is directly connected to the fourth side 24 of the straight line segment.

The radius Rc of the virtual circle 18m may be equal to or different from the radius Rb of the virtual circle 18k.

It should be noted that the first arc segment and the second arc segment of the sub-pixel are merely an example. In practice, the first arc segment and the second arc segment may not be formed by direct chamfering, but a rounded corner naturally formed at a right-angled position of the sub-pixel opening based on external factors such as an apparatus and a process, and the radius of the rounded corner caused by the process is generally about 1 micrometer to 3 micrometer.

FIG. 48 is a schematic diagram of another display panel according to an embodiment of the present disclosure. As shown in FIG. 48, in an embodiment, the display panel includes a substrate 101, a pixel defining layer 110 and multiple light-emitting elements 103 located on a side of the substrate 101. The pixel defining layer 110 includes a pixel opening 110a and a bank portion 110b, and the pixel opening 110a is provided with a light-emitting element 103. The bank portion 110b includes a side surface 102a and a bottom surface 102b on a side of the substrate 101, and an included angle θ formed between the side surface 102a and the bottom surface 102b is an acute angle. The included angle θ varies according to a position.

In the embodiment of the present application, the pixel defining layer 110 includes multiple pixel openings 110a and a bank portion 110b. For one pixel opening 110a, the bank portion 110b surrounds the pixel opening 110a. In the thickness direction of the display panel, the pixel opening 110a includes an upper opening and a lower opening, and the light-emitting layer 106 at least partially covers the lower opening of the pixel opening 110a. A cross-sectional shape of the pixel opening 110a in the thickness direction of the display panel is an inverted trapezoid, that is, the upper opening of the pixel opening 110a is greater than the lower opening of the pixel opening 110a.

The bank portion 110b includes the top surface 102c, the bottom surface 102b, and the side surface 102a that is connected to the top surface 102c and the bottom surface 102b. Based on the inverted trapezoid shape of the pixel opening 110a, a cross-sectional shape of the bank portion 110b in the thickness direction of the display panel is a positive trapezoid shape. Therefore, an angle θ between the side surface 102a of the bank portion 110b and the bottom surface 102b of the bank portion 110b is an acute angle.

It should be noted that FIG. 48 is a schematic diagram in which the side surface 102a is approximately a plane. In some embodiments, the side surface 102a may be a curve surface. When the side surface 102a is a curve surface, the maximum included angle formed between the side surface 102a and the bottom surface 102b and towards the inside of the bank portion 110b is the foregoing included angle θ. It should be understood that, for a point on the curve surface, the included angle formed between the tangent of this point and the bottom surface 102b and towards the inside of the bank portion 110b is an included angle between the side surface 102a and the bottom surface 102b at this position.

It should be understood that the sub-pixel includes multiple sides, each side includes multiple points, and included angles formed between the side surface 102a and the bottom surface 102b are not completely equal at each point. The reason is that when the opening of the pixel defining layer is formed, the exposure display operation needs to be performed by using the mask. During the exposure, the light forms interference fringes. When the light passes through the center position of the straight side of the mask, the formed interference fringes are sparse, and a corresponding exposure amount is the least. However, the closer to the intersection position of the two sides, the denser the interference fringes formed, and the larger the corresponding exposure amount. The larger the exposure amount, the less the residue such as photoresist at the corresponding position, and the more the pixel defining layer is etched during development, the larger the included angle (the maximum included angle formed between the side surface 102a and the bottom surface 102b and towards the inside of the bank portion 110 b) of the formed pixel defining layer; conversely, the smaller the included angle of the formed pixel definition layer.

It should be understood that included angles of the pixel defining layer corresponding to the first sub-pixel 11, the second sub-pixel 12, and the third sub-pixel 13 at the same position (for example, a midpoint of the third side 23) may also be different.

The inventors have found that the included angle of the pixel defining layer will affect the light emission efficiency of the display panel and the light emission amount at different viewing angles. Furthermore, under the large viewing angle, the pixel definition layer has different degrees of influence on brightness attenuation of light with different wavelengths, thereby causing different degrees of attenuation of the brightness of light of two colors with the change of viewing angle. In an embodiment, the degree of attenuation of the brightness of light with a long wavelength is greater than the degree of attenuation of the brightness of light with a short wavelength, thereby finally resulting in a color deviation of an image displayed by the display panel under the large viewing angle. Therefore, with regard to sub-pixels of the same color and/or sub-pixels of different colors, the included angle θ is set differently according to different positions, which can flexibly adjust the light emission amount of the display panel at a frontal viewing angle and a large viewing angle, and the color deviation condition.

In an embodiment, the included angle θ includes an included angle θa corresponding to the first side and an included angle θb corresponding to the third side, where θb≥θa.

With reference to FIG. 2 and FIG. 48, a region surrounded by the first side 21, the second side 22, the third side 23, and the fourth side 24 of the sub-pixel is the lower opening of the sub-pixel. Therefore, an edge of the bottom surface 102b of the bank portion 110b overlaps with the first side 21, the second side 22, the third side 23, and the fourth side 24 of the sub-pixel. The first side 21 of the sub-pixel is a straight line segment, and θa is an included angle of the first side corresponding to the side surface 102a of the bank portion 110b and the bottom surface 102b of the bank portion 110b. The third side 23 of the sub-pixel includes multiple sub-segments, and θb is an included angle of the third side 23 corresponding to the side surface 102a of the bank portion 110b and the bottom surface 102b of the bank portion 110b. The θb is designed to be greater than or equal to θa.

The first sub-pixel 11 is used as an example. In an embodiment, the larger the curvature of the side of the first sub-pixel 11, the greater the included angle between the side surface 102a of the bank portion 110b and the side of the first sub-pixel 11. In the first sub-pixel 11, the first side 21 is a straight line segment, and the third side 23 is formed by connecting multiple sub-segments. Compared with the first side 21, the third side 23 has a relatively large curvature. The included angle θb corresponding to the side surface 102a of the bank portion 110b of the first sub-pixel 11 and the third side 23 is greater than the included angle θa corresponding to the side surface 102a of the bank portion 110b of the first sub-pixel 11 and the first side. Since interference fringes formed when light passes through a side position with a relatively large curvature of the mask are relatively dense, a corresponding exposure amount is relatively large. The larger the exposure amount, the less the residue such as photoresist at the corresponding position, and the more the pixel defining layer is etched during development, the larger the included angle of the formed pixel defining layer.

In an embodiment, with reference to FIGS. 47 and 48, the third side 23 is an arc side, the fourth side 24 is a straight side, an included angle corresponding to the side surface 102a and the bottom surface 102b at the midpoint P1 of the third side 23 is θ1, the included angle corresponding to the side surface 102a and the bottom surface 102b at the midpoint P15 of the fourth side 24 is θ2, the included angle corresponding to the side surface 102a and the bottom surface 102b at the midpoint of the first sub-segment 23a is θ3, the included angle corresponding to the side surface 102a and the bottom surface 102b at the midpoint of the second sub-segment 23b is θ4, the included angle corresponding to the side surface 102a and the bottom surface 102b at the midpoint of the first arc segment 11k is θ5, and the included angle corresponding to the side surface 102a and the bottom surface 102b at the midpoint of the second arc segment 11m is θ6.

Within the range of process error and measurement error, θ1, θ2, θ3 and θ4 are approximately equal. θ5 and θ6 are approximately equal, and α5 is greater than θ1.

In an embodiment, the third side 23 is an arc side, and a radius of curvature corresponding to the third side 23 is relatively large. The first side 21, the second side 22, and the fourth side 24 are straight sides. In the existing apparatus and the process condition, when the pixel defining layer is exposed by using the mask, exposure amounts of the midpoint of the third side 23, the midpoint of the first side 21, the midpoint of the second side 22, and the midpoint of the fourth side 24 are approximately equal. Therefore, included angles of the pixel defining layer formed after the development etching process are approximately equal.

The fourth side 24 and the first side 21 (or the second side 22) may be directly connected to form a right angle as shown in FIG. 2. Alternatively, the fourth side 24 and the first side 21 (or the third side 23) may be connected through the first arc segment 11k (or the second arc segment 11m) to form a rounded (chamfered) angle shown in FIG. 47. It should be noted that, based on an external factor such as an apparatus or a process, even if an initial design angle is a right angle (a right angle corresponding to the point P4 and the point P5 in FIG. 2), the final formed angle may still be a rounded angle (positions corresponding to a first arc segment 11k and a second arc segment 11m in FIG. 47). Referring to FIGS. 2 and 47, in the existing apparatus and the process condition, when the pixel defining layer is exposed by the mask, interference fringes are generated by light passing through the mask. The closer to a junction of the fourth side 24 and the first side 21 (or the second side 22), the denser the interference fringes, the larger the exposure amount, the less residual such as photoresist at the corresponding position, and the more the pixel defining layer is etched during developing, the greater the included angle of the formed pixel defining layer. Therefore, finally, the included angle θ5 corresponding to the midpoint of the first arc segment 11k is greater than the included angle θ1 corresponding to the midpoint P1 of the third side 23.

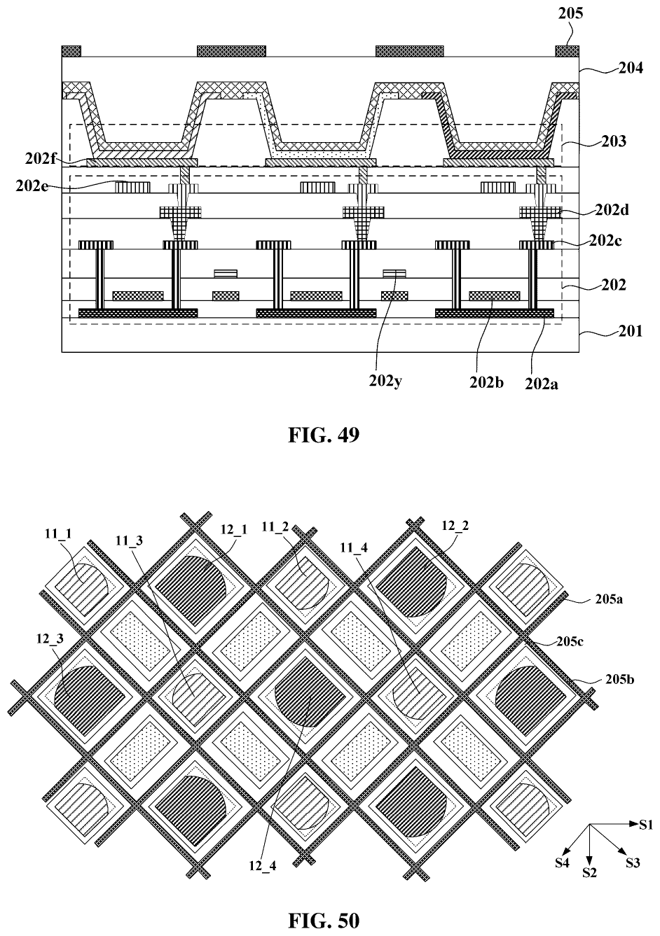

FIG. 49 is a schematic diagram of another display panel according to an embodiment of the present disclosure. FIG. 50 is a schematic diagram of a touch electrode layer in FIG. 49. As shown in FIGS. 49 and 50, in an embodiment, the display panel includes a substrate 201; and a thin film transistor array layer 202, an organic light-emitting device layer 203, a thin film encapsulation layer 204, and a touch electrode layer 205 which are located on a side of the substrate 201. The touch electrode layer 205 includes multiple metal wires, the multiple metal wires intersect to define multiple mesh holes 205c, and at least one mesh hole 205c surrounds at least one sub-pixel in a direction perpendicular to a plane where the substrate 201 is located.

In the embodiment of the present application, the display panel may be an organic light-emitting display panel.

The display panel includes the substrate 201, the thin film transistor array layer 202 is disposed on the substrate 201, the thin film transistor array layer 202 includes multiple thin film transistors, and the thin film transistor array layer 202 is used as a part of the pixel circuit structure to drive the display of the sub-pixel. The thin film transistor array layer 202 includes a poly layer 202a, a first metal layer 202b, a capacitor metal layer 202y, a second metal layer 202c, a third metal layer 202d, a fourth metal layer 202e, and a fifth metal layer 202f. The first metal layer 202b may be used as a gate metal layer, the second metal layer 202c may be used as a source/drain electrode metal layer, and the fifth metal layer 202f may be used as the pixel electrode, such as an anode.

The organic light-emitting device layer 203 is disposed on the side of the thin film transistor array layer 202 facing away from the substrate 201, and the organic light-emitting device layer 203 includes multiple organic light-emitting devices, where the organic light-emitting device includes a red organic light-emitting device, a green organic light-emitting device, and a blue organic light-emitting device. A light-emitting layer of the red organic light-emitting device includes a red organic light-emitting material, a light-emitting layer of the green organic light-emitting device includes a green organic light-emitting material, and a light-emitting layer of the blue organic light-emitting device includes a blue organic light-emitting material.

The thin film encapsulation layer 204 is disposed on the side of the organic light-emitting device layer 203 facing away from the substrate 201, and the thin film encapsulation layer 204 is configured to perform the encapsulation, so as to prevent external water vapor, impurities, and the like from entering the organic device layer 203.

The touch electrode layer 205 is disposed on the side of the thin film encapsulation layer 204 facing away from the substrate 201. The touch electrode layer 205 includes multiple metal wires, and an extension direction of the metal wire 205a intersects with an extension direction of the metal wire 205b. The metal wire 205a and the metal wire 205b may be disposed to be insulated from each other on the same layer, or the metal wire 205a and the metal wire 205b may be disposed to be insulated from each other in a stacked manner. The multiple metal wires 205a intersect with the multiple metal wires 205b. Multiple mesh holes 205c may be defined in the thickness direction of the display panel, and the thickness direction of the display panel is perpendicular to a plane where the substrate 201 is located. In a direction perpendicular to the plane where the substrate 201 is located, at least one mesh 205c surrounds at least one sub-pixel, then the touch electrode layer 205 located on the side of the organic light-emitting device layer 203 facing away from the substrate 201 does not block the sub-pixel, and does not affect the lighting of the sub-pixel.

In the embodiment of the present application, the touch electrode layer 205 is disposed on the side of the thin film encapsulation layer 204 facing away from the substrate 201. The first sub-pixel 11_1, the first sub-pixel 11_2, the first sub-pixel 11_3 and the first sub-pixel 11_4 are four adjacent first sub-pixels 11, and the four adjacent first sub-pixels 11 constitute the minimum repetition unit of the first sub-pixel. The second sub-pixel 12_1, the second sub-pixel 12_2, the second sub-pixel 12_3 and the second sub-pixel 12_4 are four adjacent second sub-pixels 12, and the four adjacent second sub-pixels 12 constitute the minimum repetition unit of the second sub-pixel.

Referring to FIGS. 2, 49 and 50, for the single first sub-pixel, the first sub-pixel 11_2 is used as an example. The minimum distance from a first sub-segment of the first sub-pixel 11_2 to an adjacent intersection point of the metal wires is equal to the minimum distance from a second sub-segment to an adjacent intersection point of the metal wires. Therefore, an angle of obstruction of the light emission at a corresponding position of the first sub-segment by the metal wire 205 is approximately the same as an angle of obstruction of the light emission at a corresponding position of the second sub-segment by the metal wire 205, so that no light emission differences exist. That is, when the first sub-pixel 11_2 is an axisymmetric design, distances from the corresponding positions of two symmetrical parts of the first sub-pixel 11_2 to the metal wires are equal. When the human eye observes the display panel from the fourth direction S4 and the direction opposite to the fourth direction S4, the observed sizes of the light-emitting regions of the first sub-pixel 11_2 are consistent, thereby reducing differences in display screen, improving the color deviation phenomenon, and improving the display quality. For the minimum repeating unit of the first sub-pixel, the minimum distance from the first side of the first sub-pixel 11_1 to an adjacent metal wire is equal to the minimum distance from the second side of the first sub-pixel 11_1 to the adjacent metal wire, the minimum distance from the first side of the first sub-pixel 11_2 to an adjacent metal wire is equal to the minimum distance from the second side of the first sub-pixel 11_2 to the adjacent metal wire, the minimum distance from the first side of the first sub-pixel 11_3 to an adjacent metal wire is equal to a minimum distance from the second side of the first sub-pixel 11_3 to the adjacent metal wire, and the minimum distance from the first side of the first sub-pixel 11_4 to an adjacent metal wire is equal to the minimum distance from the second side of the first sub-pixel 11_4 to the adjacent metal wire. The minimum distance from the third edge of the first sub-pixel 11_1 to an adjacent metal wire is greater than the minimum distance from the second edge of the first sub-pixel 11_1 to the adjacent metal wire, the minimum distance from the third edge of the first sub-pixel 11_2 to an adjacent metal wire is greater than the minimum distance from the second edge of the first sub-pixel 11_2 to the adjacent metal wire, the minimum distance from the third edge of the first sub-pixel 11_3 to an adjacent metal wire is greater than the minimum distance from the second edge of the first sub-pixel 11_3 to the adjacent metal wire, the minimum distance from the third edge of the first sub-pixel 11_4 to an adjacent metal wire is greater than the minimum distance from the second edge of the first sub-pixel 11_4 to the adjacent metal wire. In the embodiment of the present disclosure, in the minimum repeating unit of the first sub-pixel, protruding third sides of the four first sub-pixels are oriented differently on the plane, and when the human eye observes the display panel from the first direction to the fourth direction or a reverse direction thereof, the sizes of the observed light-emitting regions are consistent, thereby reducing the difference of the display screen, improving the color deviation phenomenon, and improving the display quality.

Similarly, referring to FIGS. 2, 49 and 50, for the single second sub-pixel, the second sub-pixel 12_2 is used as an example. The minimum distance from a first sub-segment of the second sub-pixel 12_2 to an adjacent intersection point of the metal wires is equal to the minimum distance from a second sub-segment and an adjacent intersection point of the metal wires. Therefore, an angle of obstruction of the light emission at a corresponding position of the first sub-segment by the metal wire 205 is approximately the same as an angle of obstruction of the light emission at a corresponding position of the second sub-segment by the metal wire 205, so that no light emission differences exist. That is, when the second sub-pixel 12_2 is an axisymmetric design, distances from the corresponding positions of two symmetrical parts of the second sub-pixel 12_2 to the metal wire are equal. When the human eye observes the display panel from the direction opposite to the fourth direction S4 and the fourth direction S4, the observed sizes of the light-emitting regions of the second sub-pixel 12_2 are consistent, thereby reducing differences in display images, improving the color deviation phenomenon, and improving the display quality. For the minimum repeating unit of the second sub-pixel, the minimum distance from the first side of the second sub-pixel 12_1 to an adjacent metal wire is equal to the minimum distance from the second side of the second sub-pixel 12_1 to the adjacent metal wire, the minimum distance from the first side of the second sub-pixel 12_2 to an adjacent metal wire is equal to the minimum distance from the second side of the second sub-pixel 12_2 to the adjacent metal wire, the minimum distance from the first side of the second sub-pixel 12_3 to an adjacent metal wire is equal to the minimum distance from the second side of the second sub-pixel 12_3 to the adjacent metal wire, and the minimum distance from the first side of the second sub-pixel 12_4 to an adjacent metal wire is equal to the minimum distance from the second side of the second sub-pixel 12_4 to the adjacent metal wire. The minimum distance from the third edge of the second sub-pixel 12_1 to an adjacent metal wire is greater than the minimum distance from the second edge of the second sub-pixel 12_1 to the adjacent metal wire, the minimum distance from the third edge of the second sub-pixel 12_2 to an adjacent metal wire is greater than the minimum distance from the second edge of the second sub-pixel 12_2 to the adjacent metal wire, the minimum distance from the third edge of the second sub-pixel 12_3 to an adjacent metal wire is greater than the minimum distance from the second edge of the second sub-pixel 12_3 to the adjacent metal wire, and the minimum distance from the third edge of the second sub-pixel 12_4 to an adjacent metal wire is greater than the minimum distance from the second edge of the second sub-pixel 12_4 to the adjacent metal wire. In the embodiment of the present disclosure, in the minimum repeating unit of the second sub-pixel, protruding third sides of the four second sub-pixels are oriented differently on the plane, and when the human eye observes the display panel from the first direction to the fourth direction or a reverse direction thereof, the sizes of the observed light-emitting regions are consistent, thereby reducing the difference in display screen, improving the color deviation phenomenon, and improving the display quality.

It should be noted that the structure of the touch electrode layer is not limited to the illustration. In other embodiments, the touch electrode layer may be a single-layer metal layer or a transparent conductive layer, for example, the transparent conductive layer may include a transparent conductive oxide ITO, but it is not limited thereto. Alternatively, the touch electrode layer may be a metal layer with a multi-layer structure, and the metal layer may have a three-layer structure of titanium/aluminum/titanium. The structure of the touch electrode layer is not specifically limited.

As described above, the touch electrode layer 205 is located above a side of the thin film encapsulation layer 204 facing away from the substrate 201. An external touch control structure is not required to be disposed, which is conducive to the development of thin and narrow-frame display panels, is also conducive to being applied to a foldable display panel, and has more advantages in cost.

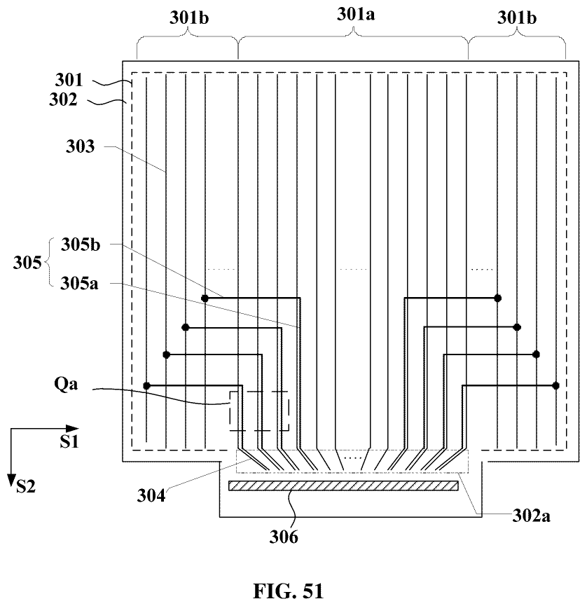

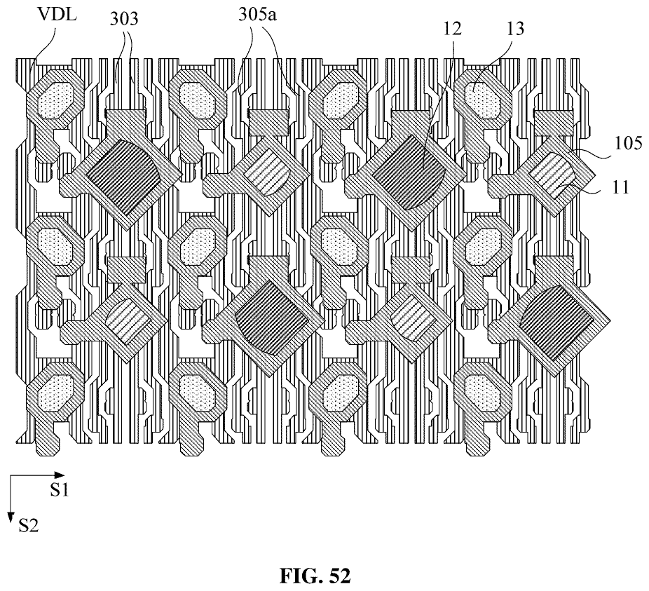

FIG. 51 is a schematic diagram of another display panel according to an embodiment of the present disclosure. FIG. 52 is a partial enlarged schematic diagram of a region Qa in FIG. 51. Referring to FIGS. 48, 51 and 52, in an embodiment, the display panel includes a display region 301 and a non-display region 302 that at least partially surrounds the display region 301. The display region 301 includes multiple data lines 303 arranged in the first direction S1 and extending in the second direction S2, and the first direction S1 intersects with the second direction S2. The display region 301 further includes a substrate 101, a pixel defining layer 110 and multiple light-emitting elements 103 located on a side of the substrate 101. The pixel defining layer 110 includes multiple pixel openings 110a, and the light-emitting element 103 includes a first electrode 105, a second electrode 107, and a light-emitting layer 106 located between the first electrode 105 and the second electrode 107. In a direction perpendicular to the plane where the substrate 101 is located, both the first electrode 105 of the first sub-pixel 11 and the first electrode 105 of the second sub-pixel 12 overlap with two data lines 303.

In the embodiment of the present application, the display panel includes the display region 301 and the non-display region 302. Multiple sub-pixels are disposed in the display region 301, and are at least multiple first sub-pixels 11, multiple second sub-pixels 12, and multiple third sub-pixels 13. A driver circuit structure is disposed in the non-display region 302, and is configured to drive the display of the sub-pixel in the display region 301.

The display region 301 includes multiple data lines 303 arranged in the first direction S1 and extending in the second direction S2. One data line 303 is electrically connected to the sub-pixels with the same color in a column and provides a data signal for the sub-pixels with the same color in the column. The column is parallel to the direction S2 herein.

As described above, in the first direction S1, the first sub-pixels 11 and the second sub-pixels 12 are arranged alternately. In addition, in the second direction S2, the first sub-pixel 11 and the second sub-pixel 12 are arranged alternately. For the first sub-pixel 11 and the second sub-pixel 12 that are located in the same column, one data line 303 may simultaneously provide a data signal for the first sub-pixel 11 and the second sub-pixel 12 in the column. In addition, in the direction perpendicular to the plane where the substrate is located, the first electrode 105 of the first sub-pixel 11 at least partially overlaps with the two data lines 303, and the first electrode 105 of the second sub-pixel 12 at least partially overlaps with the two data lines 303, that is, both a light-emitting region of the first sub-pixel 11 and a light-emitting region of the second sub-pixel 12 overlap with the two data lines 303. This design helps ensure the flatness and symmetry of the first electrode 105 of the first sub-pixel 11 and the first electrode 105 of the second sub-pixel 12, improves the viewing angle color deviation of the first sub-pixel 11 and the second sub-pixel 12, and improves the display effect.

For one column of third sub-pixels 13, one data line 303 is electrically connected to a corresponding column of third sub-pixels 13, and provides a data signal for the column of third sub-pixels 13. In addition, in the direction perpendicular to the plane where the substrate is located, the first electrode 105 of the third sub-pixel 13 at least partially overlaps with a power supply voltage line VDL, that is, the light-emitting region of the third sub-pixel 13 overlaps with the power supply voltage line VDL. In this design, the flatness design of the first electrode 105 can be ensured, which helps to ensure that the light emitted from the pixel has a balanced optical path, avoid the deviation of brightness or chromaticity, and ensure the display effect of the display panel.

The display region 301 further includes another line structure such as a scan line, where the scan line is used to provide a scan signal for a row of sub-pixels, but it is not limited thereto. For another structure in the display panel, details are not described herein.

As shown in FIGS. 51 and 52, in an embodiment, the non-display region 302 includes a fan-out region 302a located on a side of the display region 301 in the second direction S2, the display region 301 includes a first display region 301a and a second display region 301b, and the second display region 301b is located on at least one side of the first display region 301a in the first direction S1. The fan-out region 302a includes multiple fan-out wires 304, and each of the first display region 301a and the second display region 301b include multiple data lines 303. The data line 303 is connected to a respective one of the fan-out wires 304, and the data line 303 of the second display region 301b is connected to a respective one of the fan-out wires 304 through a connection wire 305. The connection wire 305 is located in the display region 301, and includes a first connection line segment 305a extending in the second direction S2 and a second connection line segment 305b extending in the first direction S1. In the direction perpendicular to the plane where the substrate is located, both the first electrode of the first sub-pixel 11 and the first electrode of the second sub-pixel 12 further overlap with two first connection line segments.

In the embodiment of the present application, the non-display region 302 includes the fan-out region 302a, and the fan-out region 302a is located on a lower side of the display region 301 in the drawings. The display region 301 includes a first display region 301a and a second display region 301b, and the second display region 301b is located on a left side of the first display region 301a in the drawings, but is not limited thereto. The display region 301 may include one or more second display regions 301b. The drawings show two second display regions 301b.

The fan-out region 302a includes multiple fan-out wires 304, the display region 301 includes multiple data lines 303, and the data line 303 is connected to a respective one of the fan-out wires 304. As shown in the drawings, multiple line segments connected to the data lines 303 in the fan-out region 302a are fan-out wires 304.

The non-display region 302 further includes a source driver circuit 306, the fan-out wires 304 are connected to the source driver circuit 306, and the source driver circuit 306 provides a data signal to the data lines 303 in the display region 301 by using the fan-out wires 304.

In an embodiment, the first display region 301a includes multiple sub-pixels and multiple data lines 303 that drive the multiple sub-pixels, and the second display region 301b also includes multiple sub-pixels and multiple data lines 303 that drive the multiple sub-pixels. Each data line 303 located in the second display region 301b is connected to one connection wire 305, and each data line 303 in the second display region 301b is connected to the fan-out wire 304 in the non-display region 302 through the connection wire 305 located in the display region 301.

The connection wire 305 includes a first connection line segment 305a extending in the second direction S2 and a second connection line segment 305b extending in the first direction S1. In the direction perpendicular to the plane where the substrate is located, both the first electrode 105 of the first sub-pixel 11 and the first electrode 105 of the second sub-pixel 12 overlap with two first connection line segments 305a.

Each data line 303 in the second display region 301b is led out the display region 301 through the connection wire 305. To reduce an occupation area of the connection wire 305 corresponding to the data line 303 in the second display region 301b, the connection wire 305 may be designed to include multiple sub-segments. In an embodiment, the connection wire 305 includes a first connection line segment 305a extending in the second direction S2 and a second connection line segment 305b extending in the first direction S1, and the first connection line segment 305a is connected to the second connection line segment 305b. The first connection line segment 305a extends from the display region 301 to the non-display region 302. Therefore, a wiring position of the first connection line segment 305a may overlap with the sub-pixel of the first display region 301a.

In the second direction S2, the first sub-pixel 11 and the second sub-pixel 12 are arranged alternately. In the direction perpendicular to the plane where the substrate is located, both the first electrode 105 of the first sub-pixel 11 and the first electrode 105 of the second sub-pixel 12 overlap with the two first connection line segments 305a, thereby reducing the display region space occupied by the connection wire 305 and facilitating the high PPI design. Moreover, the flatness design and symmetry of the first electrode 105 may be further ensured, so as to ensure that the light emitted from the pixel has a balanced optical path, avoid the deviation of brightness or chromaticity, and ensure the display effect of the display panel.

Based on the same invention concept, an embodiment of the present disclosure further provides a display device, and the display device includes any display panel provided in the foregoing implementation manner.

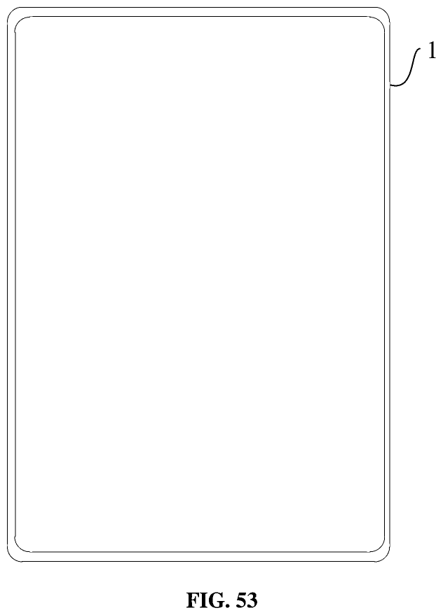

FIG. 53 is a schematic diagram of a display device according to an embodiment of the present disclosure. As shown in FIG. 53, the display device 1 includes a display panel. The display device 1 also has the beneficial effects of the display panel in the foregoing implementation manners. The same point may be understood with reference to the above explanation of the display panel, and will not be repeated hereinafter.

The display device 1 provided in the embodiment of the present application may be the mobile phone shown in FIG. 53, or may be any electronic product that has the display function, including but not limited to the following categories: a television, a notebook computer, a desktop display, a tablet computer, a digital camera, a smart band, smart glasses, an in-vehicle display, an industrial control apparatus, a medical display screen, a touch interaction terminal and the like. This is not specifically limited in the embodiments of the present application.

An embodiment of the present disclosure further provides a display panel, where the display panel includes multiple sub-pixels, and the multiple sub-pixels include a first sub-pixel, a second sub-pixel and a third sub-pixel. Two first sub-pixels and two second sub-pixels form a first virtual quadrilateral, a center of gravity of the first sub-pixel is located at a first vertex of the first virtual quadrilateral, a center of gravity of the second sub-pixel is located at a second vertex of the first virtual quadrilateral, the first vertex and the second vertex in the first virtual quadrilateral are alternately disposed at intervals, and the third sub-pixel is located inside the first virtual quadrilateral. Four third sub-pixels form a second virtual quadrilateral, a center of gravity of the third sub-pixel is located at a vertex of the second virtual quadrilateral, and the first sub-pixel or the second sub-pixel is located inside the second virtual quadrilateral. Each of the first sub-pixel and the second sub-pixel include a first side, a second side and a third side, where the first side and the second side are parallel to each other, the third side is connected to the first side and the second side on the same side of the first side and the second side, the third side includes a first sub-segment and a second sub-segment, the first sub-segment is connected to the first side, and the second sub-segment is connected to the second side, the maximum included angle between the first side and the first sub-segment and towards the second side is α_{b1}, and the maximum included angle between the second side and the second sub-segment and towards the first side is α_{b2}, where 90°<α_{b1}<180°, and 90°<α_{b2}<180°.

Referring to FIG. 1A, the display panel includes multiple sub-pixels, and the multiple sub-pixels include the first sub-pixel 11, the second sub-pixel 12 and the third sub-pixel 13. The two first sub-pixels 11 and the two second sub-pixels 12 form the first virtual quadrilateral 14, where the center of gravity Pb11 of the first sub-pixel 11 is located at a first vertex of the first virtual quadrilateral 14, the center of gravity Pb12 of the second sub-pixel 12 is located at a second vertex of the first virtual quadrilateral 14, the first vertex and the second vertex in the first virtual quadrilateral 14 are alternately disposed at intervals, and the third sub-pixel 13 is located inside the first virtual quadrilateral 14. Four third sub-pixels 13 form the second virtual quadrilateral 15, the center of gravity Pb13 of the third sub-pixel 13 is located at a vertex of the second virtual quadrilateral 15, the first sub-pixel 11 or the second sub-pixel 12 is located inside the second virtual quadrilateral 15, and each of the first sub-pixel 11 and the second sub-pixel 12 include the first side, the second side and the third side, where the first side and the second side are parallel to each other, the third side is connected to the first side and the second side on the same side of the first side and the second side.

Referring to FIG. 2, the first sub-pixel 11 includes the first side 21 and the second side 22 that are parallel to each other and the third side 23 that is connected to the first side 21 and the second side 22 on the same side of the first side 21 and the second side 22, and the first sub-pixel 11 further includes a fourth side 24. The third side 23 includes a first sub-segment 23a and a second sub-segment 23b, the first sub-segment 23a is connected to the first side 21, and the second sub-segment 23b is connected to the second side 22. Each of the first side 21 and the second side 22 is a straight line segment. The third side 23 may include only the first sub-segment 23a and the second sub-segment 23b, and the fourth side 24 may be a straight line segment, but is not limited thereto.

In other embodiments, in an embodiment, the third side is formed by connecting three or more sub-segments, that is, the third side includes a first sub-segment, a second sub-segment, and multiple sub-segments connected between the first sub-segment and the second sub-segment.

Alternatively, the fourth side is also formed by connecting two or more sub-segments. For any one of the third side or the fourth side, any one sub-segment thereof may be an arc segment or a straight line segment.

The maximum included angle between the first side 21 and the first sub-segment 23a and towards the second side 22 is α_{b11}, and the maximum included angle between the second side 22 and the second sub-segment 23b and towards the first side 21 is α_{b12}, where 90°<α_{b11}<180°, and 90°<α_{b12}<180°. That is, two adjacent vertices of the circumscribed virtual parallelogram 30a of the first sub-pixel 11 are cut. In this way, the third side 23 of the first sub-pixel 11 is formed, so that an inner included angle α_{b11} between the third side 23 and the first side 21 is not equal to a right angle, and an inner included angle α_{b12} between the third side 23 and the second side 22 is not equal to a right angle. In an embodiment, an inner included angle α_{b11} between the third side 23 and the first side 21 is greater than 90° and less than 180°, and an inner included angle α_{b12} between the third side 23 and the second side 22 is greater than 90° and less than 180°.

It should be understood that a shape of the first sub-pixel 11 may be the same as or different from a shape of the second sub-pixel 1. In this case, α_{b11} of the first sub-pixel 11 and α_{b11} of the second sub-pixel 12 may be the same or different, and α_{b12} of the first sub-pixel 11 and α_{b12} of the second sub-pixel 1 may be the same or different.

Therefore, referring to FIGS. 1A, 1B, 1C and 19, compared with the related art, the total opening ratio (an opening area) of the display panel can be improved by means of the pixel design in the embodiment of the present application of the present application. In addition, related process parameters (for example, minimum opening spacing between adjacent sub-pixels and FMM rib) in the present application are equal to or superior to those in the related art. That is, in a case where it is ensured that a minimum opening spacing and a FMM rib width between adjacent sub-pixels are consistent with or still have the design redundancy in the related art, the total opening ratio of the present application is greater, and the display effect and the display quality are better.

In the embodiment of the present application, the above-described design of the first sub-pixel 11 and the second sub-pixel 12 is adopted, in a case where the above-described design is consistent with an existing related process parameter (for example, a minimum opening spacing between adjacent sub-pixels, and a FMM rib), the opening ratio of the first sub-pixel and the opening ratio of the second sub-pixel may be increased, an overall opening ratio of the display panel may be improved, and thus the display effect is improved. In addition, compared with the related art, if the total opening ratio of the display panel is kept unchanged, then in the present application, a distance between the opening regions of the first sub-pixel and the second sub-pixel adjacent to each other may be further increased, so that a lateral distance between the first sub-pixel and the second sub-pixel adjacent to each other increases, thereby reducing the leakage current between the first sub-pixel and the second sub-pixel adjacent to each other, and improving the problem of sneaking light of the pixel and improving the display effect.

In an embodiment, each of the first sub-pixel and the second sub-pixel include a corresponding circumscribed virtual parallelogram, where the circumscribed virtual parallelogram includes a first virtual quasi-side, a second virtual side, and a third virtual side that is connected to the first virtual side and the second virtual side on the same side of the first virtual side and the second virtual side, the first virtual side partially coincides with the first side, the second virtual side partially coincides with the second side, and at least one point of the third side is located on the third virtual side. In the thickness direction of the display panel, the first sub-pixel is located within the circumscribed virtual parallelogram corresponding to the first sub-pixel, and the second sub-pixel is located within the circumscribed virtual parallelogram corresponding to the second sub-pixel. In a direction in which the first sub-pixel and the second sub-pixel are arranged alternately, a line connecting a center of the circumscribed virtual parallelogram corresponding to the first sub-pixel and a center of the circumscribed virtual parallelogram corresponding to the second sub-pixel at least intersect with a third side of one of the first sub-pixel or the second sub-pixel.

Referring to FIGS. 1 and 2, the first sub-pixel 11 includes a corresponding circumscribed virtual parallelogram. In FIG. 1, a circumscribed virtual parallelogram corresponding to the first sub-pixel 11 is labeled as 30a, and in the thickness direction of the display panel, the first sub-pixel 11 is located in the circumscribed virtual parallelogram 30a corresponding to the first sub-pixel 11. The second sub-pixel 12 includes a corresponding circumscribed virtual parallelogram. In FIG. 1A, a circumscribed virtual parallelogram corresponding to the second sub-pixel 12 is labeled as 30b. The second sub-pixel 12 is located in the circumscribed virtual parallelogram 30b corresponding to the second sub-pixel 12 in the thickness direction of the display panel.

Referring to FIG. 2, for the sub-pixel and the circumscribed virtual parallelogram 30 corresponding to the sub-pixel, the circumscribed virtual parallelogram 30 includes a first virtual side 31 and a second virtual side 32 that are disposed in parallel, and a third virtual side 33 and a fourth virtual side 34 that are disposed in parallel. The first virtual side 31 partially coincides with the first side 21, where at least one point of the first side 21 is located on the first virtual side 31, and other points of the first side 21 are located on the first virtual side 31 or are located in the circumscribed virtual parallelogram 30. The second virtual side 32 partially coincides with the second side 22, where at least one point of the second side 22 is located on the second virtual side 32, and other points of the second side 22 are located on the second virtual side 32 or are located in the circumscribed virtual parallelogram 30. At least one point of the third side 23 is located on the third virtual side 33, and other points of the third side 23 are located on the third virtual side 33 or are located in the circumscribed virtual parallelogram 30. At least one point of the fourth side 24 is located on the fourth virtual side 34, and other points of the fourth side 24 are located on the fourth virtual side 34 or are located in the circumscribed virtual parallelogram 30.

In the direction S1, the first sub-pixel 11 and the second sub-pixel 12 adjacent to each other satisfy at least one of the following conditions: (1) a line Pa11-Pa12 connecting the center of the circumscribed virtual parallelogram 30a corresponding to the first sub-pixel 11 and the center of the circumscribed virtual parallelogram 30b corresponding to the second sub-pixel 12 intersects with the third side of the first sub-pixel 11; or (2) a line Pa11-Pa12 connecting the center of the circumscribed virtual parallelogram 30a corresponding to the first sub-pixel 11 and a center of the circumscribed virtual parallelogram 30b corresponding to the second sub-pixel 12 intersects with the third side of the second sub-pixel 12. A center of gravity of the first sub-pixel 11 is Pb11, and a center of gravity of the second sub-pixel 12 is Pb12.

In the direction S2, the first sub-pixel 11 and the second sub-pixel 12 adjacent to each other satisfy at least one of the following conditions: (1) a line Pa11-Pa12 connecting the center of the circumscribed virtual parallelogram 30a corresponding to the first sub-pixel 11 and the center of the circumscribed virtual parallelogram 30b corresponding to the second sub-pixel 12 intersects with the third side of the first sub-pixel 11; or (2) a line Pa11-Pa12 connecting the center of the circumscribed virtual parallelogram 30a corresponding to the first sub-pixel 11 and a center of the circumscribed virtual parallelogram 30b corresponding to the second sub-pixel 12 intersects with the third side of the second sub-pixel 12.

In an embodiment, the shape of the circumscribed virtual parallelogram is a rectangle, a square, or a rhombus.

In the embodiment of the present application, the shape of the circumscribed virtual parallelogram may be a parallelogram with none of the interior angles equal to 90°. Alternatively, the shape of the circumscribed virtual parallelogram may be a rectangle or a square with all interior angles equal to 90°. Alternatively, the shape of the circumscribed virtual parallelogram may be a rhombus with at least one interior angle not equal to 90°. This is not limited thereto.

The shape of the circumscribed virtual parallelogram corresponding to the first sub-pixel may be the same as or different from the shape of the circumscribed virtual parallelogram corresponding to the second sub-pixel. The same described herein means that virtual shapes of the two sub-pixels may be completely coincided in a moving manner such as translation, rotation, and mirroring. Correspondingly, the difference described herein refers to a difference in sides, interior angles, and the like of virtual shapes of two sub-pixels.

In an embodiment, the first sub-segment is connected to the second sub-segment, a connection point of the first sub-segment and the second sub-segment is located on the third virtual side, the third virtual side is tangent to the third side at the connection point, and each of the first sub-segment and the second sub-segment is an arc segment.

Referring to FIG. 2, the third side 23 of the sub-pixel includes only a first sub-segment 23a and a second sub-segment 23b, the third side 23 and the third virtual side 33 are tangent to a connection point P1 of the first sub-segment 23a and the second sub-segment 23b, and each of the first sub-segment 23a and the second sub-segment 23b is an arc segment. In other embodiments, in an embodiment, each of the first sub-segment and the second sub-segment is the straight line segment, or one of the first sub-segment and the second sub-segment is an arc segment and the other of the first sub-segment or the second sub-segment is a straight line segment.

In an embodiment, the first sub-segment and the second sub-segment are located in the circumference of the same virtual circle. In an embodiment, 0.5*La≤Ra≤1.5*La, where Ra denotes a radius of the virtual circle, and La denotes a length of the first virtual side.

As shown in FIG. 10, a point P2 is selected on the first virtual side 31 of the circumscribed virtual parallelogram 30, a point P3 is selected on the second virtual side 32, a point P1 is selected on the third virtual side 33, and a unique virtual circle 35 may be determined according to the points P2, P3, and P1. An arc segment of P2 to P1 on the circumference of the virtual circle 35 is determined as the first sub-segment 23a, and an arc segment of P3 to P1 on the circumference of the virtual circle 35 is determined as the second sub-segment 23b. Based on this, the third side 23 of the sub-pixel may be determined.

If the radius Ra of the virtual circle 35 is less than 0.5*La, then the first sub-segment 23a and the second sub-segment 23b cannot be simultaneously obtained by using the same virtual circle, that is, the first sub-segment 23a and the second sub-segment 23b cannot be located on a circumference of the same virtual circle. The radius Ra of the virtual circle 35 should be less than or equal to 1.5*La to ensure the opening region spacing between adjacent sub-pixels, thereby effectively reducing the leakage current and weakening the problem of sneaking light.

In an embodiment, 0.05*La≤Xa≤0.3*La, where Xa is a first distance denoting a vertical distance between an intersection point of the first side and the first sub-segment and the third virtual side, and La denotes a length of the first virtual side. In an embodiment, 0.05*Lb≤ Xb≤0.3*Lb, where Xb is a second distance denoting a vertical distance between an intersection point of the second side and the second sub-segment and the third virtual side, and Lb denotes a length of the second virtual side. In an embodiment, Xa=Xb.

In the embodiment of the present application, Xa and Xb in the sub-pixels may be properly designed for any one of the first sub-pixel and the second sub-pixel. A differentiated design may be used, that is, the vertical distance Xa between the intersection point of the first side and the first sub-segment and the third virtual side is not equal to the vertical distance Xb between the intersection point of the second side and the second sub-segment and the third virtual side. In other exemplary embodiments, Xa=Xb.

In an embodiment, the first sub-segment is connected to the second sub-segment, a connection point between the first sub-segment and the second sub-segment is located on the third virtual side, and each of the first sub-segment and the second sub-segment is a straight line segment. In an embodiment, the third side further includes a third sub-segment located on the same side of the first sub-segment and the second sub-segment, and the third sub-segment is a straight line segment and partially coincides with the third virtual side. In an embodiment, each of the first sub-segment and the second sub-segment is an arc segment.

In the sub-pixels, each of the first sub-segment and the second sub-segment may be a straight line segment, the first sub-segment is connected to the second sub-segment, and in this case, the third side includes the first sub-segment and the second sub-segment. Alternatively, in the sub-pixels, the first sub-segment and the second sub-segment are connected through the third sub-segment, and the third sub-segment is a straight line segment and coincides with a partial line segment of the third virtual side. In this case, the third side includes the first sub-segment, the third sub-segment and the second sub-segment.

It should be understood that the third side of the sub-pixel may be formed by connecting two or more sub-segments, and any one sub-segment in the third side may be a straight line segment or an arc segment.

In an embodiment, a ratio of the length of the third sub-segment to the length of the third virtual side is 5% to 40%. If the ratio of the length of the third sub-segment to the length of the third virtual side is too large, such as 70%, then the included angle between the first sub-segment and the first side and towards the second side is larger and/or the included angle between the second sub-segment and the second side and towards the first side is larger, the distance of the opening region between the first sub-pixel and the second sub-pixel adjacent to each other decreases, and the improvement effect on the problem of sneaking light is not obvious. Therefore, the ratio of the length of the third sub-segment to the length of the third virtual side is limited to 5% to 40%, which not only ensures the relatively large opening ratio, but also increases the distance of the opening region between the first sub-pixel and the second sub-pixel adjacent to each other, thereby improving the problem of sneaking light.

In an embodiment, the first sub-pixel, the second sub-pixel and the third sub-pixel are one of a red sub-pixel, a blue sub-pixel, and a green sub-pixel, respectively and are different from each other. For example, the first sub-pixel may be the red sub-pixel, the second sub-pixel is the blue sub-pixel, and the third sub-pixel is the green sub-pixel, but this is not limited thereto, and light-emitting colors of the first sub-pixel, the second sub-pixel and the third sub-pixel may be properly configured by those skilled in the art according to the product requirements.

Referring to FIGS. 2, 25 and 26, in an embodiment, each of the first sub-pixel 11 and the second sub-pixel 12 further includes a fourth side opposite to the third side, and the fourth side is connected to the first side and the second side on the same side of the first side and the second side. The first sub-pixel 11 and the second sub-pixel 12 are arranged alternately in the first direction S1 and the second direction S2, and the first direction S1 intersects with the second direction S2. The first sub-pixel 11 and the third sub-pixel 13 are arranged alternately in a third direction S3 and a fourth direction S4, the second sub-pixel 12 and the third sub-pixel 13 are arranged alternately in the third direction S3 and the fourth direction S4, and the third direction S3 intersects with the fourth direction S4. The third direction S3 intersects with the first direction S1 and the second direction S2, separately, and the fourth direction S4 intersects with the first direction S1 and the second direction S2, separately. The first sub-pixel 11 includes a first first sub-pixel 11a, a second first sub-pixel 11b, a third first sub-pixel 11c, and a fourth first sub-pixel 11d, the second sub-pixel 12 includes a first second sub-pixel 12a, a second second sub-pixel 12b, a third second sub-pixel 12c, and a fourth second sub-pixel 12d, the first first sub-pixel 11a, the first second sub-pixel 12a, the second first sub-pixel 11b, and the second second sub-pixel 12b are arranged in the first direction S1 to form a first sub-group 10a, the third second sub-pixel 12c, the third first sub-pixel 11c, the fourth second sub-pixel 12d, and the fourth first sub-pixel 11d are arranged in the first direction S1 to form a second sub-group 10b, and the first sub-pixel 10a and the second sub-pixel 11b are adjacent to each other. In the first first sub-pixel 11a, the third side 23x and the fourth side 24x are arranged in the fourth direction S4, and the shortest distance E11 between the third side 23x and the first second sub-pixel 12a is less than a shortest distance E12 between the fourth side 24x and the first second sub-pixel 12a. In the first second sub-pixel 12a, the third side 23y and the fourth side 24y are arranged in the fourth direction S4, and the shortest distance E13 between the third side 23y and the second first sub-pixel 11b is less than a shortest distance E14 between the fourth side 24y and the second first sub-pixel 11b. In the second first sub-pixel 11b, the third side 23x and the fourth side 24x are arranged in the third direction S3, and the shortest distance E15 between the third side 23x and the second second sub-pixel 12b is less than the shortest distance E16 between the fourth side 24x and the second second sub-pixel 12b. In the second second sub-pixel 12b, the third side 23y and the fourth side 24y are arranged in the third direction S3, and the shortest distance E17 between the third side 23y and the second first sub-pixel 11b is greater than the shortest distance E15 between the fourth side 24y and the second first sub-pixel 11b. In the third second sub-pixel 12c, the third side 23y and the fourth side 24y are arranged in a third direction S3, and the shortest distance E21 between the third side 23y and the third first sub-pixel 11c is greater than the shortest distance E22 between the fourth side 24y and the third first sub-pixel 11c. In the third first sub-pixel 11c, the third side 23x and the fourth side 24x are arranged in the third direction S3, and the shortest distance E23 between the third side 23x and the fourth sub-pixel 12d is greater than the shortest distance E24 between the fourth side 24x and the fourth sub-pixel 12d. In the fourth second sub-pixel 12d, the third side 23y and the fourth side 24y are arranged in the fourth direction S4, and the shortest distance E25 between the third side 23y and the fourth first sub-pixel 11d is greater than the shortest distance E26 between the fourth side 24y and the fourth first sub-pixel 11d. In the fourth first sub-pixel 11d, the third side 23x and the fourth side 24x are arranged in the fourth direction S4, and the shortest distance E26 between the third side 23x and the fourth second sub-pixel 12d is less than the shortest distance E27 between the fourth side 24x and the fourth second sub-pixel 12d.

In an embodiment, the display panel further includes multiple scan lines and multiple data lines that are disposed in a crossed manner. The first direction is parallel to an extension direction of the scan line, and the second direction is parallel to an extension direction of the data line. Referring to FIG. 27, a scan line SL and a data line DL are disposed in a crossed manner, the first direction S1 may be parallel to the extension direction of the scan line SL, and the second direction S2 is parallel to the extension direction of the data line DL.

In an embodiment, the display panel further includes multiple scan lines and multiple data lines that are disposed in a crossed manner. The first direction is parallel to an extension direction of the data line, and the second direction is parallel to an extension direction of the scan line. Referring to FIG. 28, a scan line SL and a data line DL are disposed in a crossed manner, the second direction S2 may be parallel to the extension direction of the scan line SL, and the first direction S1 is parallel to the extension direction of the data line DL.

As described above, the first sub-pixel 11 and the second sub-pixel 12 of the display panel are arranged according to the above-described design, so that the spacing of the opening region between the first sub-pixel 11 and the second sub-pixel 12 adjacent to each other can be increased, the problem of sneaking light on is improved, and thus the display effect is improved.

The above specific implementations should not be construed as limiting the scope of protection of the present disclosure. It should be understood by those skilled in the art that various modifications, combinations, sub-combinations and substitutions may be made according to design requirements and other factors. Any modification, equivalent replacement, and improvement made within the spirit and principle of the present disclosure should be included within the scope of protection of the present disclosure.

What is claimed is:

1. A display panel, comprising:
a plurality of sub-pixels comprising a first sub-pixel, a second sub-pixel and a third sub-pixel, wherein,
two first sub-pixels and two second sub-pixels form a first virtual quadrilateral, a center of gravity of the first sub-pixel is located at a first vertex of the first virtual quadrilateral, a center of gravity of the second sub-pixel is located at a second vertex of the first virtual quadrilateral, the first vertex and the second vertex in the first virtual quadrilateral are alternately disposed at intervals, and the third sub-pixel is located inside the first virtual quadrilateral;
four third sub-pixels form a second virtual quadrilateral, a center of gravity of the third sub-pixel is located at a vertex of the second virtual quadrilateral, and the first sub-pixel or the second sub-pixel is located inside the second virtual quadrilateral;
each of the first sub-pixel and the second sub-pixel comprises a first side, a second side and a third side, wherein the first side and the second side are parallel to each other, the third side is connected to the first side and the second side on a same side of the first side and the second side, the third side comprises a first sub-segment and a second sub-segment, the first sub-segment is connected to the first side, and the second sub-segment is connected to the second side;
each of the first sub-pixel and the second sub-pixel comprises a corresponding circumscribed virtual parallelogram, wherein the circumscribed virtual parallelogram comprises a first virtual side, a second virtual side and a third virtual side, the third virtual side is connected to the first virtual side and the second virtual side on a same side of the first virtual side and the second virtual side, the first virtual side partially coincides with the first side, the second virtual side partially coincides with the second side, and at least one point of the third side is located on the third virtual side; and in a thickness direction of the display panel, the first sub-pixel is located within the circumscribed virtual parallelogram corresponding to the first sub-pixel, and the second sub-pixel is located within the circumscribed virtual parallelogram corresponding to the second sub-pixel;
0.05*La≤Xa≤0.3*La, wherein Xa is a first distance denoting a vertical distance between an intersection point of the first side and the first sub-segment and the third virtual side, and La denotes a length of the first virtual side;
0.05*Lb≤Xb≤0.3*Lb, wherein Xb is a second distance denoting a vertical distance between an intersection point of the second side and the second sub-segment and the third virtual side, and Lb denotes a length of the second virtual side; and
in a direction in which the first sub-pixel and the second sub-pixel are arranged alternately, a line connecting a center of the circumscribed virtual parallelogram corresponding to the first sub-pixel and a center of the circumscribed virtual parallelogram corresponding to the second sub-pixel at least intersects with the third side of one of the first sub-pixel or the second sub-pixel.

2. The display panel of claim 1, wherein a shape of the circumscribed virtual parallelogram is a rectangle, a square, or a rhombus.

3. The display panel of claim 1, wherein in the direction in which the first sub-pixel and the second sub-pixel are arranged alternately, the line connecting the center of the circumscribed virtual parallelogram corresponding to the first sub-pixel and the center of the circumscribed virtual parallelogram corresponding to the second sub-pixel does not intersect with the second side.

4. The display panel of claim 1, wherein the first sub-segment is connected to the second sub-segment, a connection point of the first sub-segment and the second sub-segments is located on the third virtual side, the third virtual side is tangent to the third side at the connection point, and each of the first sub-segment and the second sub-segment is an arc segment.

5. The display panel of claim 4, wherein the first sub-segment and the second sub-segment are located on a circumference of a same virtual circle, and 0.5*La≤Ra≤1.5*La, and Ra denotes a radius of the virtual circle.

6. The display panel of claim 1, wherein a ratio of the first distance to the length of the first virtual side in the first sub-pixel is not equal to a ratio of the first distance to the length of the first virtual side in the second sub-pixel.

7. The display panel of claim 6, wherein the first sub-pixel is configured to be red, the second sub-pixel is configured to be blue, and the ratio of the first distance to the length of the first virtual side in the first sub-pixel is greater than the ratio of the first distance to the length of the first virtual side in the second sub-pixel.

8. The display panel of claim 1, wherein the first distance in the first sub-pixel is equal to the first distance in the second sub-pixel.

9. The display panel of claim 1, wherein Xa=Xb.

10. The display panel of claim 1, wherein the first sub-segment is connected to the second sub-segment, a connection point of the first sub-segment and the second sub-segment is located on the third virtual side, and each of the first sub-segment and the second sub-segment is a straight line segment.

11. The display panel of claim 1, wherein the third side further comprises a third sub-segment connected to the first sub-segment and the second sub-segment on a same side of the first sub-segment and the second sub-segment, and the third sub-segment is a straight line segment and partially coincides with the third virtual side.

12. The display panel of claim 11, wherein each of the first sub-segment and the second sub-segment is an arc segment, or each of the first sub-segment and the second sub-segment is a straight line segment.

13. The display panel of claim 11, wherein a length of the first sub-segment is equal to a length of the second sub-segment.

14. The display panel of claim 11, wherein the circumscribed virtual parallelogram comprises a first virtual axis, a center of the circumscribed virtual parallelogram is located on the first virtual axis, the first virtual axis intersects with the third sub-segment, and a midpoint of the third sub-segment is not located on the first virtual axis.

15. The display panel of claim 11, wherein the circumscribed virtual parallelogram comprises a first virtual axis, a center of the circumscribed virtual parallelogram is located on the first virtual axis, and a midpoint of the third sub-segment is located on the first virtual axis.

16. The display panel of claim 11, wherein the circumscribed virtual parallelogram comprises a first virtual axis, a center of the circumscribed virtual parallelogram is located on the first virtual axis, the first virtual axis intersects with the third sub-segment, and the first sub-segment and the second sub-segment are symmetrical about the first virtual axis.

17. The display panel of claim 11, wherein Xc≤Lc/2, Xc denotes a length of the third sub-segment, and Lc denotes a length of the third virtual side.

18. The display panel of claim 17, wherein a ratio of the length of the third sub-segment to the length of the third virtual side is 5% to 40%.

19. The display panel of claim 17, wherein a ratio of the length of the third sub-segment to the length of the third virtual side in the first sub-pixel is not equal to a ratio of the length of the third sub-segment to the length of the third virtual side in the second sub-pixel.

20. The display panel of claim 19, wherein the first sub-pixel is configured to be red, the second sub-pixel is configured to be blue, and the ratio of the length of the third sub-segment to the length of the third virtual side in the first sub-pixel is less than the ratio of the length of the third sub-segment to the length of the third virtual side in the second sub-pixel.

21. The display panel of claim 1, wherein the first sub-pixel, the second sub-pixel and the third sub-pixel are one of a red sub-pixel, a blue sub-pixel or a green sub-pixel, respectively, and are different.

22. The display panel of claim 1, wherein a center of gravity of the first virtual quadrilateral does not overlap with the center of gravity of the third sub-pixel located inside the first virtual quadrilateral.

23. The display panel of claim 1, wherein a center of gravity of the second virtual quadrilateral does not overlap with the center of gravity of the first sub-pixel located inside the second virtual quadrilateral; or
a center of gravity of the second virtual quadrilateral does not overlap with the center of gravity of the second sub-pixel located inside the second virtual quadrilateral.

24. The display panel of claim 1, wherein each of the first sub-pixel and the second sub-pixel further comprises a fourth side opposite to the third side, and the fourth side is connected to the first side and the second side on a same side of the first side and the second side;
the first sub-pixel and the second sub-pixel are arranged alternately in the first direction and the second direction, and the first direction intersects with the second direction;
the first sub-pixel and the third sub-pixel are arranged alternately in a third direction and a fourth direction, the second sub-pixel and the third sub-pixel are arranged alternately in the third direction and the fourth direction, and the third direction intersects with the fourth direction;
the third direction intersects with the first direction and the second direction, separately, and the fourth direction intersects with the first direction and the second direction, separately;
the first sub-pixel comprises a first first sub-pixel, a second first sub-pixel, a third first sub-pixel and a fourth first sub-pixel, the second sub-pixel comprises a first second sub-pixel, a second second sub-pixel, a third second sub-pixel and a fourth second sub-pixel, the first first sub-pixel, the first second sub-pixel, the second first sub-pixel and the second second sub-pixel are arranged in the first direction to form a first sub-group, the third second sub-pixel, the third first sub-pixel, the fourth second sub-pixel and the fourth first sub-pixel are arranged in the first direction to form a second sub-group, and the first sub-group and the second sub-pixel are adjacent in the second direction;
in the first first sub-pixel, the third side and the fourth side are arranged in the fourth direction, and a shortest distance between the third side and the first second sub-pixel is less than a shortest distance between the fourth side and the first second sub-pixel;
in the first second sub-pixel, the third side and the fourth side are arranged in the fourth direction, and a shortest distance between the third side and the second first sub-pixel is less than a shortest distance between the fourth side and the second first sub-pixel;
in the second first sub-pixel, the third side and the fourth side are arranged in the third direction, and a shortest distance between the third side and the second second sub-pixel is less than a shortest distance between the fourth side and the second second sub-pixel;
in the second second sub-pixel, the third side and the fourth side are arranged in the third direction, and the shortest distance between the third side and the second first sub-pixel is greater than the shortest distance between the fourth side and the second first sub-pixel;
in the third second sub-pixel, the third side and the fourth side are arranged in the third direction, and a shortest distance between the third side and the third first sub-pixel is greater than a shortest distance between the fourth side and the third first sub-pixel;
in the third first sub-pixel, the third side and the fourth side are arranged in the third direction, and a shortest distance between the third side and the fourth second sub-pixel is greater than a shortest distance between the fourth side and the fourth second sub-pixel;
in the fourth second sub-pixel, the third side and the fourth side are arranged in the fourth direction, and a shortest distance between the third side and the fourth first sub-pixel is greater than a shortest distance between the fourth side and the fourth first sub-pixel; and
in the fourth first sub-pixel, the third side and the fourth side are arranged in the fourth direction, and the shortest distance between the third side and the fourth second sub-pixel is less than the shortest distance between the fourth side and the fourth second sub-pixel.

25. The display panel of claim 24, further comprising: a plurality of scan lines and a plurality of data lines which are disposed in a crossed manner;
wherein the first direction is parallel to an extension direction of the plurality of scan lines, and the second direction is parallel to an extension direction of the plurality of data lines; or
the first direction is parallel to an extension direction of the plurality of data lines, and the second direction is parallel to an extension direction of the plurality of scan lines.

26. The display panel of claim 1, further comprising:
a plurality of support posts;
wherein in the thickness direction of the display panel, a support post of the plurality of support posts overlaps with at least one virtual side of the first virtual quadrilateral, and a virtual side of the at least one virtual side intersects with the third side of at least one of the first sub-pixel or the second sub-pixel;
wherein one first sub-pixel, one second sub-pixel and two third sub-pixels form a third virtual quadrilateral, centers of gravity of the two third sub-pixels are located at two opposite vertices of the third virtual quadrilateral, respectively, and the center of gravity of the first sub-pixel and the center of gravity of the second sub-pixel are located at another two opposite vertices of the third virtual quadrilateral, respectively; and
an included angle range between an extension direction of the third sub-pixel and an extension direction of a support post of the plurality of support posts and towards the second sub-pixel is αₐ, and 130°≤αₐ≤140°.

27. The display panel of claim 1, comprising:
a substrate; and
a pixel defining layer and a plurality of light-emitting elements located on a side of the substrate, wherein the pixel defining layer comprises a plurality of pixel openings, and a light-emitting element of the plurality of light-emitting elements comprises a first electrode, a second electrode, and a light-emitting layer located between the first electrode and the second electrode;
wherein the light-emitting element comprises the first sub-pixel, the second sub-pixel and the third sub-pixel;
in at least one of the first sub-pixel or the second sub-pixel, the first electrode comprises a first sub-side corresponding to the first side, a second sub-side corresponding to the second side, and a third sub-side corresponding to the third side, and the third sub-side is connected to the first sub-side and the second sub-side on a same side of the first sub-side and the second sub-side; and
a vertical distance between an intersection point of the first side and the first sub-segment and the third sub-side is F1, and a shortest distance between the third side and the third sub-side is F2, and 2≤F1/F2≤8.

28. The display panel of claim 1, comprising:
a substrate; and
a pixel defining layer and a plurality of light-emitting elements located on a side of the substrate, wherein the pixel defining layer comprises a plurality of pixel openings, and a light-emitting element of the plurality of light-emitting elements comprises a first electrode, a second electrode, and a light-emitting layer between the first electrode and the second electrode;
wherein the light-emitting element comprises the first sub-pixel, the second sub-pixel and the third sub-pixel;
in at least one of the first sub-pixel or the second sub-pixel, the light-emitting layer comprises a first boundary corresponding to the first side, a second boundary corresponding to the second side, and a third boundary corresponding to the third side, and the third boundary is connected to the first boundary and the second boundary on a same side of the first boundary and the second boundary; and
a vertical distance between an intersection point of the first side and the first sub-segment and the third boundary is F3, and a shortest distance between the third side and the third boundary is F4, and 1≤F3/F4≤4.

29. The display panel of claim 1, comprising:
a display region and a non-display region at least partially surrounding the display region;
wherein the display region comprises a plurality of data lines arranged in a first direction and extending in a second direction, and the first direction intersects with the second direction;
the display region further comprises a substrate, a pixel defining layer and a plurality of light-emitting elements located on a side of the substrate, wherein the pixel defining layer comprises a plurality of pixel openings, and a light-emitting element of the plurality of light-emitting elements comprises a first electrode, a second electrode, and a light-emitting layer located between the first electrode and the second electrode; and
in a direction perpendicular to the plane where the substrate is located, both the first electrode of the first sub-pixel and the first electrode of the second sub-pixel overlap with two data lines of the plurality of data lines.

30. The display panel of claim 29, wherein the non-display region comprises a fan-out region located on a side of the display region in the second direction, the display region comprises a first display region and a second display region, and the second display region is located on at least one side of the first display region in the first direction;
the fan-out region comprises a plurality of fan-out wires, and each of the first display region and the second display region comprises the plurality of data lines;
a data line of the plurality of data lines is connected to a fan-out wire of the plurality of fan-out wires, and the data line in the second display region is connected to the fan-out wire through a connection wire;
the connection wire is located in the display region and comprises a first connection line segment extending in the second direction and a second connection line segment extending in the first direction; and
in the direction perpendicular to the plane where the substrate is located, both the first electrode of the first sub-pixel and the first electrode of the second sub-pixel further overlap with two first connection line segments.

31. A display device, comprising a display panel, wherein the display panel comprises:
a plurality of sub-pixels comprising a first sub-pixel, a second sub-pixel and a third sub-pixel, wherein,
two first sub-pixels and two second sub-pixels form a first virtual quadrilateral, a center of gravity of the first sub-pixel is located at a first vertex of the first virtual quadrilateral, a center of gravity of the second sub-pixel is located at a second vertex of the first virtual quadrilateral, the first vertex and the second vertex in the first virtual quadrilateral are alternately disposed at intervals, and the third sub-pixel is located inside the first virtual quadrilateral;
four third sub-pixels form a second virtual quadrilateral, a center of gravity of the third sub-pixel is located at a vertex of the second virtual quadrilateral, and the first sub-pixel or the second sub-pixel is located inside the second virtual quadrilateral;
each of the first sub-pixel and the second sub-pixel comprises a first side, a second side and a third side, wherein the first side and the second side are parallel to each other, the third side is connected to the first side and the second side on a same side of the first side and the second side, the third side comprises a first sub-segment and a second sub-segment, the first sub-segment is connected to the first side, and the second sub-segment is connected to the second side;
each of the first sub-pixel and the second sub-pixel comprises a corresponding circumscribed virtual parallelogram, wherein the circumscribed virtual parallelogram comprises a first virtual side, a second virtual side and a third virtual side, the third virtual side is connected to the first virtual side and the second virtual side on a same side of the first virtual side and the second virtual side, the first virtual side partially coincides with the first side, the second virtual side partially coincides with the second side, and at least one point of the third side is located on the third virtual side; and in a thickness direction of the display panel, the first sub-pixel is located within the circumscribed virtual parallelogram corresponding to the first sub-pixel, and the second sub-pixel is located within the circumscribed virtual parallelogram corresponding to the second sub-pixel;
0.05*La≤Xa≤0.3*La, wherein Xa is a first distance denoting a vertical distance between an intersection point of the first side and the first sub-segment and the third virtual side, and La denotes a length of the first virtual side;
0.05*Lb≤Xb≤0.3*Lb, wherein Xb is a second distance denoting a vertical distance between an intersection point of the second side and the second sub-segment and the third virtual side, and Lb denotes a length of the second virtual side; and
in a direction in which the first sub-pixel and the second sub-pixel are arranged alternately, a line connecting a center of the circumscribed virtual parallelogram corresponding to the first sub-pixel and a center of the circumscribed virtual parallelogram corresponding to the second sub-pixel at least intersects with the third side of one of the first sub-pixel or the second sub-pixel.
